(19) United States
(12) Patent Application Publication
(10) Pub. No.: US 2014/0151706 A1
(43) Pub. Date: Jun. 5, 2014

(54) STRUCTURES INCORPORATING SILICON NANOPARTICLE INKS, DENSIFIED SILICON MATERIALS FROM NANOPARTICLE SILICON DEPOSITS AND CORRESPONDING METHODS

(71) Applicant: NanoGram Corporation, Milpitas, CA (US)

(72) Inventors: Guojun Liu, Suzhou (CN); Shivkumar Chiruvolu, San Jose, CA (US); Weidong Li, San Jose, CA (US); Uma Srinivasan, Mountain View, CA (US)

(73) Assignee: NanoGram Corporation, Milpitas, CA (US)

(21) Appl. No.: 14/175,561

(22) Filed: Feb. 7, 2014

Related U.S. Application Data
(62) Division of application No. 13/286,888, filed on Nov. 1, 2011.

(51) Int. Cl. H01L 29/04; H01L 21/02

(52) U.S. Cl. CPC H01L 29/04; H01L 21/02104
USPC 257/64; 438/488

(57) ABSTRACT

Silicon nanoparticle inks provide a basis for the formation of desirable materials. Specifically, composites have been formed in thin layers comprising silicon nanoparticles embedded in an amorphous silicon matrix, which can be formed at relatively low temperatures. The composite material can be heated to form a nanocrystalline material having crystals that are non-rod shaped. The nanocrystalline material can have desirable electrical conductive properties, and the materials can be formed with a high dopant level. Also, nanocrystalline silicon pellets can be formed from silicon nanoparticles deposited form an ink in which the pellets can be relatively dense although less dense than bulk silicon. The pellets can be formed from the application of pressure and heat to a silicon nanoparticle layer. The materials described herein can be effectively used for the formation of doped contacts for crystalline silicon solar cells, thin film silicon solar cells, electronic devices, such as printed electronics, and other useful products.

### CROSS REFERENCE TO RELATED APPLICATIONS

This application is a divisional of copending U.S. patent application Ser. No. 13/286,888 filed Nov. 1, 2011 to Liu et al., entitled “Structures Incorporating Silicon Nanoparticle Inks, Densified Silicon Materials from Nanoparticle Silicon Deposits and Corresponding Methods,” incorporated herein by reference.

### FIELD OF THE INVENTION

The invention relates to densified structures formed with nanoparticle elemental silicon inks, optionally with a dopant element. The invention also relates to crystalline silicon nanoparticles within an amorphous silicon matrix. The invention further related to methods for performing the densification as well as application of the densified structures as components in devices.

### BACKGROUND OF THE INVENTION

Silicon is a commonly used semiconductor material for commercial applications, and a majority of commercial electronic devices and solar cells are based on silicon. Most consumer electronics comprise silicon based circuits, and flat panel displays can comprise large area circuits to drive the display. Several solar cell designs based on silicon can be used, and most commercial solar cells are based on silicon. The formation of functional devices generally involves doping the silicon to control the electrical and conductive properties.

Photovoltaic cells are an important alternative energy source with growing global use. Generally, photovoltaic cells operate through the absorption of light to form electron-hole pairs within a semiconducting material. Oppositely doped regions within the photovoltaic cell provide a diode junction, which results in a voltage differential that can be used to drive a photocurrent. The photocurrent is available to perform useful work in an external circuit.

Solar cells based on crystalline silicon, which can be single crystalline or polycrystalline with large crystallite sizes generally on the order of a millimeter or greater, provide particular design considerations. For solar cells with crystalline silicon layers, localized doped contacts can be used to assist with the collection of the photocurrent. Current collectors generally are then in electrical contact with the doped contacts to provide for connection of the solar cell to an external circuit. Doped contacts with opposite dopant types can be placed on the front and back of the solar cell. In alternative designs, all of the doped silicon contacts of the solar cell are placed on the back side of the cell to form a back contact solar cell. With a back contact solar cell, the front, light receiving surface can be free of current collectors. Thin film solar cells can also be formed with amorphous silicon and/or microcrystalline silicon, which have greater light absorption than crystalline silicon. Thin film solar cells generally have alternating layers of silicon with different dopants.

For electronics applications, it is desirable to have a lower cost processing alternatives for less demanding applications. For example, for large area display applications, moderate resolution may be sufficient for appropriate components, such as transistor components. Thus, thin film transistors may provide alternatives to conventional processing of structures on single crystal silicon wafers.

### SUMMARY OF THE INVENTION

In a first aspect, the invention pertains to a structure comprising a substrate having a surface and a composite coating on at least a portion of the surface with an average thickness of no more than about 5 microns and comprising crystalline silicon nanoparticles with an average primary particle size of no more than about 100 nm and an amorphous silicon matrix around the crystalline silicon particles.

In a further aspect, the invention pertains to a structure comprising a substrate having a surface and a nano-crystalline coating of elemental silicon with a void volume of no more than about 5% and an average thickness of no more than about 10 microns. The average crystallite diameter can be no more than about 100 nm as determined by TEM analysis. Also, at least 90% of the crystallites can have a ratio of the longest length along a principle axis divided by the shortest length along a principle axis of no more than a factor of three.

In additional embodiments, the invention pertains to a structure comprising a substrate having a surface and a patterned nanocrystalline doped elemental silicon coating covering no more than about 75 percent of the surface with an average thickness of no more than about 10 microns and intrinsic elemental silicon coating effectively covering the remaining portions of the surface, wherein the doped nanocrystalline elemental silicon coating has an average dopant concentration of the coating is at least about 1×10¹⁹ atoms per cubic centimeter.

In other embodiments, the invention pertains to a silicon structure comprising a crystalline elemental silicon substrate and a coating over at least a portion of a surface of the substrate wherein the coating comprises doped nanocrystalline silicon having an average thickness of no more than about 10 microns and an average dopant concentration of at least about 5×10¹⁹ atm/cm³, wherein a dopant profile extends into the silicon substrate from the coating along a normal to the surface at a location of the coating with a dopant concentration of at least about 1×10¹⁹ atm/cm³ to a depth of at least about 0.5 microns.

In some embodiments, the invention pertains to a silicon structure comprising elemental silicon with a density from about 1 g/cm³ to about 2.1 g/cm³ and an XRD-based crystallite size from about 20 nm to about 200 nm.

Moreover, the invention pertains to a method for application of a silicon coating on a substrate in which the method comprises depositing an amorphous silicon matrix onto and into a particulate coating of crystalline silicon nanoparticles having an average primary particle size of no more than about 200 nm to form a composite with crystalline silicon nanoparticles embedded in an amorphous matrix. In general, the particulate coating has an average thickness of no more than about 5 microns.

Furthermore, the invention pertains to a method for the densification of a silicon nanoparticle ink deposit on at least a portion of a substrate surface in which the method comprises applying mechanical pressure to the deposited silicon nanoparticles and simultaneously and/or following application of pressure, heating the deposited silicon nanoparticles to a temperature of no more than about 1200° C. to sinter the particles into a densified layer.

### BRIEF DESCRIPTION OF THE DRAWINGS

FIG. 1 is a schematic view depicting an annealing process for a composite of crystalline silicon nanoparticles embedded in a matrix of amorphous silicon that is annealed to form a nanocrystalline material with the composite shown in the left frame and the nanocrystalline material shown in the right frame.

FIG. 2 is a schematic view of an oven for performing an anneal step for a silicon composite coated substrate.

FIG. 3 is a schematic diagram depicting a rapid thermal anneal of a coated wafer.

FIG. 4 is a front view of a photovoltaic cell with doped contacts along both the front and rear surfaces in which a current collector along a grid is shown.

FIG. 5 is a sectional side view of the photovoltaic cell of FIG. 4 taken along line 5-5.

FIG. 6 is a back view of a photovoltaic cell with back contacts of opposite polarity without any back sealing material blocking the view of the cell.

FIG. 7 is a sectional side view of the photovoltaic cell of FIG. 6 taken along line 7-7.

FIG. 8 is a schematic sectional view of an embodiment of a thin film solar cell comprising two photovoltaic elements.

FIG. 9 is a composite of SEM images of cross-sections of silicon composite coated wafers, the silicon composite comprising crystalline silicon nanoparticles embedded in an amorphous silicon matrix. The composite layers comprise intrinsic (upper left panel), n++ doped (upper right panel), p+ doped (lower left panel), or n+ doped (lower right panel) silicon particles, embedded in an undoped amorphous silicon matrix.

FIG. 10 is a graph containing vibrational Raman spectra of a composite layer comprising crystalline silicon nanoparticles embedded in an amorphous silicon matrix and of nanocrystalline silicon layers, formed by annealing composite layers.

FIG. 11 is a high resolution TEM image of a cross-section of a structure comprising a nanocrystalline silicon layer and an epitaxial layer on a crystalline silicon wafer. The nanocrystalline silicon layer and the epitaxial layer were formed by annealing a silicon composite comprising crystalline silicon nanoparticles embedded in an amorphous silicon matrix.

FIG. 12 is a high resolution TEM image of the cross-section of the structure displayed in FIG. 11, taken at higher magnification.

FIG. 13 is a composite of high resolution TEM images of the nanocrystalline silicon layer (left panel) and the epitaxial layer (right panel) of the structure displayed in FIG. 12.

FIG. 14A is a composite of SAED patterns obtained from the nanocrystalline silicon layer (top panel), the epitaxial layer (middle panel), and the wafer substrate (bottom panel) of the structure displayed in FIG. 12.

FIG. 14B is a graph displaying a plot of a GI XRD diffractogram data, obtained from a nanocrystalline layer, and fits to the GI XRD diffractogram data.

FIG. 15 is a SEM image of a cross-section of a structure comprising a nanocrystalline layer on a crystalline silicon wafer substrate, the nanocrystalline layer formed from a silicon composite comprising n++ doped silicon particles with an average primary particle diameter of 20 nm embedded in an amorphous silicon matrix. The composite was formed from a spin-on ink layer having a thickness of 0.25 μm.

FIG. 16A is a graph containing dopant profiles for structures comprising a nanocrystalline layer on substrate, the nanocrystalline layer formed by dopant drive-in at 950° C. (solid line) or at 1050° C. (dashed line) on corresponding structures comprising a composite layer on a substrate. The composite layers comprised n++ doped silicon particles with an average primary particle diameter of 20 nm.

FIG. 16B is a graph containing dopant profiles for structures comprising a nanocrystalline layer on a substrate, the nanocrystalline layer formed by dopant drive-in on corresponding structures comprising a composite layer on a substrate. The composite layer was formed from spin-on ink layer having a thickness of 0.5 μm (solid line) or of 1.0 μm (dashed line).

FIG. 17A is a SEM image of a cross-section of the structure displayed in FIG. 11.

FIG. 17B is a SEM image of a cross-section of the structure displayed in FIG. 17A, taken at higher magnification.

FIG. 18A is a SEM image of a cross-section of the structure displayed in FIG. 17A, taken at the same magnifications but after stain-etching.

FIG. 18B is a SEM image of a cross-section of the structure displayed in FIG. 17B, taken at the same magnification but after stain-etching.

FIG. 19A is a SEM image of a cross-section of a structure comprising a nanocrystalline silicon layer on a crystalline silicon wafer substrate, the nanocrystalline layer formed by dopant drive-in at 1050° C. on a corresponding structure comprising n++ doped crystalline silicon particles with an average primary particle size of 20 nm embedded in an amorphous silicon matrix.

FIG. 19B is a cross section of the structure displayed in FIG. 19A, taken at higher magnification.

FIG. 20A is a SEM image of a cross-section of the structure displayed in FIG. 19A, taken at lower magnification and after stain-etching.

FIG. 20B is a SEM image of the structure displayed in FIG. 19B, taken at the same magnification but after stain-etching.

FIG. 21A is a graph containing dopant profiles for structures comprising a silicon composite comprising silicon nanoparticles with an average primary particle diameter of 7 nm embedded in an amorphous silicon matrix before (dashed line) and after (solid line) dopant drive-in.

FIG. 21B is a SEM image showing a cross-section of the structure corresponding to the nanocrystalline layer formed after drive-in shown in FIG. 21A.

FIG. 22 is an SEM image of a cross-section of a structure comprising a nanocrystalline layer on a substrate, the nanocrystalline layer formed from a porous nanoparticle layer having a target average thickness of 0.25 μm.

FIG. 23 is an SEM image of a cross-section of the structure displayed in FIG. 22, taken at higher magnification.

FIG. 24 is a composite of SEM images, taken at different magnifications, of cross-sections of a structure comprising a nanocrystalline silicon layer on a crystalline silicon wafer. The nanocrystalline layer was formed by dopant drive-in on a corresponding composite layer comprising silicon nanoparticles having an average primary particle diameter of 20 nm and having an average thickness of 1 μm.

FIG. 25 is an SEM image of a cross-section of a structure comprising a nanocrystalline silicon layer on a crystalline silicon wafer. The nanocrystalline layer was formed by dopant drive-in on a corresponding composite comprising silicon nanoparticles having an average primary particle diameter of 7 nm and having a thickness of 0.5 μm.

FIG. 26A is a photographic image of a structure comprising a printed pattern having two bus bars and multiple fingers on a silicon wafer substrate, the patterned screen printed with a paste comprising silicon nanoparticles.

FIG. 26B is an SEM image of a cross section of the structure displayed in FIG. 27A.

FIG. 27 is an SEM image of a portion of the cross-section displayed in FIG. 27B, taken at higher magnification.

FIG. 28A is an SEM image of a cross-section of the structure displayed in FIG. 27, taken after stain-etching.

FIG. 28B is an SEM image of a cross-section of the structure displayed in FIG. 29A, taken at lower magnification.

FIG. 29 is a photographic image of a representative nanocrystalline silicon pellet in a die, taken after furnace treatment. The pellet was formed by pressing a crystalline silicon nanoparticle powder in a die and heat treating the pressed structure.

FIG. 30 is a high resolution TEM image of a cross-section of a nanocrystalline silicon pellet formed from a powder comprising n++ doped crystalline silicon particles having an average primary particle diameter of 20 nm that was pressed in a die and heat treated.

FIG. 31 is an ED pattern obtained from the nanocrystalline silicon pellet displayed in FIG. 30.

FIG. 32 is a composite of DFI images obtained from a nanocrystalline silicon pellet formed from a powder comprising n++ doped crystalline silicon particles having an average primary particle diameter of 20 nm that was pressed in a die and heat treated.

FIG. 33 is a plot of a crystallite size distribution obtained by DFI analysis on a nanocrystalline silicon pellet formed from a powder comprising n++ doped silicon particles having an average primary particle diameter of 20 nm that was pressed in a die and heat treated.

FIG. 34 is an SEM image of a cross-section of a nanocrystalline silicon pellet comprising a crystalline silicon wafer fragment. The nanocrystalline silicon pellet was formed by pressing, in a die, a silicon wafer fragment embedded in a powder comprising n++ doped silicon particles having an average primary particle diameter of 20 nm, and heat treating the pressed structure.

FIG. 35 is an SEM image of a cross-section of the nanocrystalline silicon pellet displayed in FIG. 34, taken at higher magnification.

FIG. 36 is an SEM image of a cross-section of a nanocrystalline silicon pellet formed from a powder comprising n++ doped silicon particles having an average primary particle size of 20 nm that was pressed in a die and heat treated.

FIG. 37 is an SEM image of a cross-section of the nanocrystalline silicon pellet displayed in FIG. 36, taken at higher magnification.

FIG. 38 is an SEM image of a cross-section of the nanocrystalline silicon pellet displayed in FIG. 37, taken at higher magnification.

FIG. 39 is an SEM image of a cross-section of a nanocrystalline silicon pellet formed from a powder comprising n++ doped silicon particles having an average primary particle diameter of 7 nm that was pressed in a die and heat treated.

FIG. 40 is an SEM image of a cross-section of the nanocrystalline silicon pellet displayed in FIG. 39, taken at higher magnification.

FIG. 41 is an SEM image of a cross-section of the nanocrystalline silicon pellet displayed in FIG. 40, taken at higher magnification.

FIG. 42 is an SEM image of a cross-section of the nanocrystalline silicon pellet displayed in FIG. 41, taken at higher magnification.

FIG. 43 is a graph displaying plots of diffractograms obtained from GI XRD analysis on two structures, each comprising a annealed nanocrystalline layers on a crystalline silicon substrate where the annealed nanocrystalline layers were formed from dopant drive-in on composite layers comprising 7 nm, n++ silicon nanoparticles embedded in an amorphous silicon matrix.

FIG. 44 is a high resolution TEM image of a cross-section of a structure corresponding to one of the diffractograms displayed in FIG. 43.

FIG. 45 is a high resolution TEM image of a different portion of the cross-section of the structure displayed in FIG. 44.

FIG. 46 is a high resolution TEM image of an annealed nanocrystalline layer portion of the structure displayed in FIG. 44.

FIG. 47 is a high resolution TEM image of a substrate portion of the structure displayed in FIG. 44.

### DETAILED DESCRIPTION OF THE INVENTION

High quality silicon nanoparticle inks, especially highly doped inks, provides the opportunity to form useful silicon structures through the deposition and consolidation of the as-deposited particles. In particular, in some embodiments, an amorphous silicon matrix is deposited in the presence of a silicon nanoparticle deposit formed with the ink to form a relatively dense composite material that can be used as the composite or further processed. In particular, a chemical vapor deposition process (CVD) can be used to deposit amorphous elemental silicon as a matrix surrounding the silicon nanoparticles to form a composite material. In some embodiments, the resulting composite may be useful as deposited, for example as a layer of a thin film solar cell. Also, the composite can be heat treated to form a nanocrystalline layer. The composite material if doped can be used to drive dopant into an underlying silicon substrate to form a junction interface with a desirable dopant profile. Similarly, the composite material can be annealed to form a nanocrystalline layer with little or no dopant drive-in into the substrate, which may be a semiconductor material or other material. In other embodiments, powder deposits of the particles from an ink can be physically compressed prior to and/or during a heating step to facilitate substantial densification and sintering without melting the particles. The resulting densified structures can be nanocrystalline with densities corresponding to low levels of porosity, although the densities are somewhat lower than the density of fully densified elemental silicon. For some applications, the nanoparticle deposits, a composite of silicon nanoparticles with an amorphous silicon matrix as well as densified forms of the silicon can be patterned. The consolidated silicon structures can be useful, for example, for the formation of solar cell junction contacts on single crystalline silicon substrates, components of thin film solar cells and/or electronic components, such as thin film transistors.

Desirable composites and other silicon structures are described herein based on the ability to deposit high quality silicon inks that can be deposited to form uniform particle deposits that can be subsequently processed into desirable structures. While the nanoparticles of the ink can be used in principle for the direct formation of device components, for some applications it is desirable to densify the initial silicon nanoparticles to form a structure that exhibits greater electrical conductivity and/or provides a desired degree of mechanical integrity. While the nanoparticles can be melted to solidify the deposited nanoparticles, for many applications it is desirable to not heat the structure to the high temperatures to melt the particles. As described herein, the densification can be performed at temperatures well below the silicon melting point so that energy consumption is reduced and the processing can be performed on substrates that cannot tolerate temperatures closer to the silicon melting point. While melting the particles can result in single crystal or at least very large crystallite sizes, for many applications a nanocrystalline or embedded nanocrystalline structure formed at lower temperatures can provide sufficient electrical conductivity and other suitable properties.

The nanoparticle inks provide a conveniently deliverable source of elemental silicon either for forming full layers or patterned layer/structures, optionally with a dopant, which can be present in the nanoparticles at very high concentrations. The ability to form nanoparticles with high dopant levels provides for the formation of structures with desired high levels of dopant at the localized positions. While the inks can be used as a dopant source with the transfer of dopant from the particles, it can be desirable for many applications to densify the nanoparticles, with or without dopants, to a sufficient degree to mechanically stabilize the deposited particles and/or to densify the particles sufficiently to provide for appropriate electrical conductivity through the structure formed from the nanoparticles.

Silicon inks are dispersions of silicon nanoparticles that can be used in a suitable deposition process. In general, any suitable source of quality silicon nanoparticle inks can be used. Highly uniform and highly doped silicon nanoparticles can be formed that are suitable for formation of high quality inks. For example, doped silicon nanoparticles can be formed using laser pyrolysis or with plasma synthesis approaches. The use of a radiofrequency plasma apparatus for the synthesis of silicon nanoparticles is described in published U.S. patent application 2009/0014423A to Li et al., entitled “Concentric Flow-Through Plasma Reactor and Methods Therefore,” incorporated herein by reference. Laser pyrolysis has been developed as a desirable source of highly doped silicon particles for the formation of silicon inks. The silicon particles can be synthesized with a nanoscale average particle size, e.g., less than 100 nanometer average particle diameter.

Laser pyrolysis uses an intense light beam to drive a reaction that can be designed to form highly uniform silicon particles with desirable characteristics. The particles are synthesized in a flow that initiates at a reactant nozzle and ends at a collection system. Dopant levels can be adjusted using dopant precursors within the reactant stream. Particle sizes can be adjusted by correspondingly adjusting the synthesis conditions. For the formation of high quality inks, it is generally desirable to synthesize nanoparticles having an average primary particle size of no more than about 100 nm. Laser pyrolysis can be used to form very uniform and pure particles, optionally with a desired dopant level. The uniform nanoparticles can be well dispersed in the inks at relatively high concentrations, and the properties of the inks can be controlled to be suitable for a selected delivery process.

In the laser pyrolysis process, to obtain incorporation of the dopant element into the product particles, the dopant elements can be delivered into the reactant stream as a suitable precursor composition along with the silicon precursor. In general, the reactant stream can comprise vapor precursors and/or aerosol precursors, although for silicon materials highly pure gaseous precursors can be useful. Laser pyrolysis can be used to form doped silicon particles with a wide range of selected dopants or combinations of dopants. Specifically, dopant levels of several atomic percent can be achieved. The ability to achieve high dopant levels make the corresponding inks particularly desirable for applications where dopants are transferred to a semiconducting material or for the formation of devices with these high dopant levels. The high dopant levels can be achieved while also having control of average particle sizes, low impurity levels and while achieving dispersible particle with good uniformity. For the doping of semiconductor substrates, desirable dopants include, for example, B, P, Al, Ga, As, Sb and combinations thereof. The general use of laser pyrolysis for the formation of a range of materials is described in published U.S. Pat. No. 7,384,680 to Bi et al., entitled “Nanoparticle Production and Corresponding Structures,” incorporated herein by reference. The synthesis of highly doped silicon nanoparticles is described further in copending U.S. patent application 13/070,286 to Chiruvolu et al., entitled “Silicon/Germanium Nanoparticle Inks, Laser Pyrolysis Reactors For the Synthesis of Nanoparticles and Associated Methods,” incorporated herein by reference.

The silicon nanoparticle inks generally can be deposited using coating approaches that cover the surface of a substrate or printing approaches that may pattern the ink along the surface. Suitable coating techniques include, for example, spin coating, spray coating, knife-edge coating, extrusion, or the like. Printing techniques can be particularly desirable for the efficient patterning of the ink and resulting doped area of silicon if the nanoparticles are doped. Due to the enhanced ability to control the properties of the inks, the silicon nanoparticles can be printed rapidly and with relatively high resolution. In some embodiments, suitable printing techniques include, for example, inkjet printing, screen printing, gravure printing or other suitable printing process. The inks can be formulated for deposition by a selected deposition approach based on solvent selection, concentrations, additives and/or other compositions or processing parameters. Using the printing process, doped nanoparticles with different dopants can be selectively placed at different locations along the substrate surface. Similarly, the placement of doped nanoparticles along a substrate can provide a dopant source that can provide a dopant that can be driven into the adjacent substrate. Thus, for example, desired patterns of doped contacts can be formed for solar cell components, and patterned components for transistors can be formed.

Patterning of the deposited silicon nanoparticles can be used to introduce appropriate functionality. The silicon inks are suitable for various printing approaches to form desired patterns, which in some embodiments cover no more than about 75% of the substrate surface area. The printed pattern can comprise doped silicon, and the dopant type and/or concentration may or may not be uniform across the nanoparticle deposit. In particular, in some embodiments, an n-type dopant can be deposited in some locations, and a p-type dopant can be deposited at other locations. Using the techniques described herein, the patterned nanoparticle deposits can be densified in the pattern of deposited silicon nanoparticles. After densification, the silicon structures can be incorporated into a resulting device as a suitable component.

Nanoparticles can melt at lower temperatures than a bulk material of the same chemical composition. Nevertheless, for layers with a thickness of more than a few particles deep, the nanoparticles as-deposited may coalesce somewhat at temperatures significantly lower than the bulk melting temperature, but as-deposited nanoparticle structures generally do not densify a great degree at such temperatures. Thus, while some densified domains may be observed, a layer of as-deposited silicon nanoparticles generally does not densify into a structure with a thickness on the order of at least about 25 nm without significant porosity at temperatures of no more than about 1200° C. A nanoparticle ink after deposition and drying is generally not very dense even if the ink is relatively concentrated. As described herein, two effective approaches are described for the densification of silicon nanoparticle deposits. The procedures to densify a nanoparticle silicon deposit can be selected based on the nature of the deposit and the desired ultimate structure.

It has been discovered that mechanically applying pressure to densify the silicon nanoparticle deposit prior to and/or while performing a heating step can greatly enhance the densification upon applying a sintering temperature, well below the silicon melting temperature, to the silicon nanoparticles. While the silicon structure may not be fully densified, the resulting material can have a low level of visible porosity. Generally, the material can be formed with a density from about 1 g/cm³ to about 2.1 g/cm³. Generally, the resulting material is crystalline with crystallite sizes determined by x-ray crystallography from about 20 nm to about 200 nm. Thus, relatively dense layers of silicon can be formed from a deposited silicon ink over a wide range in thickness. In particular, thicknesses of the densified nanocrystalline material can be from about 100 nm to 2 millimeters. For densification of the silicon ink based on the application of force, the substrate can be selected so that the substrate is not likely to be damaged through the application of a force to densify an as-deposited silicon ink. Since thicker layers can be formed using the densification approach, a relatively broad range of structures can be formed. For example, a silicon foil can be formed from the powders, such as by passing a deposit of the silicon nanoparticles onto a moving structure that applied pressure and heat, such as heated rollers or the like, that can then form the foil at a selected thickness. In general, the consolidation of the silicon structure during or after the application of pressure is generally performed at temperatures of no more than about 1200° C. In contrast, the approaches described herein based on the deposition of amorphous silicon to fill in the pores of an as-deposited nanoparticle silicon are applicable to coatings formed on a broader range of substrates since forces are not applied to the substrate.

In alternative or additional embodiments, it has been discovered that amorphous elemental silicon can be deposited using chemical vapor deposition, such as low pressure chemical vapor deposition (LPCVD), on and within a thin layer of as-deposited ink to form a composite of nanocrystalline silicon particles embedded in an amorphous silicon matrix. The amorphous silicon deposition can be placed over the entire substrate surface, whether or not the silicon nanoparticles are patterned. If the silicon nanoparticles are patterned, the composite structures with an amorphous silicon layers between the patterned composite can undergo further processing to form an ultimately patterned processed material with different properties at different locations within the pattern. The amorphous silicon material deposited by vapor deposition may or may not be doped, and the silicon nanoparticle deposits may or may not be doped. Also, an amorphous layer of silicon can also be located on top of the composite at the completion of the deposition process. If the as-deposited silicon nanoparticles are in a sufficiently thin layer, the resulting composite can have a relatively low porosity. The composite material can be characterized through an examination of a cross section of the material to evaluate porosity in a scanning electron micrograph. Generally, the nanoparticle layer has a thickness of no more than about 5 microns. The resulting composite may be suitable for certain applications as formed. In particular, the composite of amorphous silicon and nanoparticle silicon can have desirable optical absorption properties suitable for a component of a thin film solar cell.

While the composite composition with silicon nanoparticles embedded within an amorphous silicon matrix can be a useful material as formed, the material can be heated to anneal the material to form a nanocrystalline material, which can be formed with relatively uniform crystallites distributed through the material. Under appropriate heating conditions, the resulting material has been found to be essentially uniformly nanocrystalline with no more than a low visible porosity. It is observed that the nanocrystalline material has an average crystallite size as determined from transition electron microscopy of no more than about 200 nm. Also, the crystallites embedded within the structure are observed to have a shape that is relatively isotropic and non-elongated. In other words, the crystals have diameters through the center of the particles that do not vary from each other by more than a factor of 3, in contract with microcrystalline silicon that is directly grown by chemical vapor deposition which have needle like shapes oriented orthogonal to the substrate surface. Thus, the resulting nanocrystalline material would seem to have unique material structure. The material can be highly doped to produce desirable electrical properties. In some embodiments, the consolidated material can have a dopant concentration of at least about 1×10¹⁹ atm/cm³.

While the composite of crystalline silicon nanoparticles and an amorphous silicon matrix can be used in principle as deposited, the composite can be annealed to form a nanocrystalline material. If the anneal process is performed on a ceramic substrate, dopant if present generally does not migrate significantly into the substrate. In some embodiments, the anneal process is performed with a semiconductor substrate, such as crystalline silicon or germanium. The anneal step can be performed to accomplish dopant drive-in into the substrate to form a desired dopant profile that can extend somewhat into the substrate. Alternatively, the conditions for the anneal step can be performed to limit any dopant migration into the substrate while still forming a nanocrystalline material from the composite material.

In general, the chemical vapor deposition conditions should be adjusted to provide for the fill in of the pores of the as-deposited silicon nanoparticles obtained form the silicon inks. For example, if the deposition rate is too great, the amorphous silicon is observed to deposit materials without full penetration through the nanoparticle silicon layer. While not wanting to be limited by theory, higher rate deposition processes may quickly deposit silicon along the pores near the surface of the nanoparticle deposit before deeper pores are filled so that deeper pores are not filed during the deposition. With a porous substrate material, such as the nanoparticulate layer from the deposited ink, the CVD reactants can penetrate the pores for reaction within the porous structure to fill in the porous structure when the deposition parameters are appropriately selected. The temperature, vapor pressures, and other deposition parameters can be appropriately adjusted for the desired deposition results. Similarly, the properties, such as the average primary particle size and average layer thickness, of the nanoparticle coating influence the corresponding suitable deposition conditions. In particular, thermally driven LPCVD can be a desirable deposition approach, although with appropriate adjustment of deposition parameters other CVD deposition approaches should provide desirable deposition results. The resulting composite material comprises a network of crystalline silicon nanoparticles surrounded in a matrix of amorphous elemental silicon.

In general, for the formation of the silicon composites, any suitable substrate can be selected. In some embodiments, it is desirable for the substrate to be a crystalline silicon wafer such that the substrate is an integral part of the ultimate devices, such as a solar cell, and the coatings can be used as a source of dopant elements. However, in further embodiments, other substrate materials can be desirable, such as an inorganic glass substrate, for the formation of a thin film solar cell or components of a display. The deposition of the ink generally can be done at ambient temperatures, although other temperatures can be used consistent with the solvents used for the silicon inks. The CVD deposition can be performed at relatively low temperatures, such as about 450° C. to 700° C. for LPCVD, although other CVD approaches may be possible at lower temperatures. If no further heat treatments are performed, the substrate can be selected based on stability at these temperatures.

If a compressed silicon deposit is heated to sinter the compressed silicon nanoparticles into a densified material or it a composite of silicon nanoparticles in an amorphous silicon matrix is annealed, the temperatures are generally below 1200° C., and the substrate can be appropriately selected. Heat processing of the composite can be performed in a suitable oven or the like. In additional or alternative embodiments, rapid thermal processing with a heat lamp or the like can be used to anneal the composite material.

In summary, approaches are described herein to form relatively dense silicon structures in which a silicon ink is at least a component of the densified structure. The densified structures can be doped, such as with an n-type dopant or a p-type dopant. In further embodiments, the densified silicon structure can be un-doped. For some embodiments, it can be desirable to have a low dopant concentration in contrast with higher p-doped and/or n-doped domains. Intrinsic silicon is used to refer to silicon that is either undoped or has a low added dopant concentration, concentration, for example, from 1×10¹⁴ to about 1×10¹⁸ atoms/cm³. Of course, undoped silicon has a background level of contaminants, which can be engineered to be at low levels.

The deposit of silicon ink and subsequent densification as described herein can be performed on a suitable substrate based on the target product as well as the process conditions. In general, a relatively wide range of substrates can be used, such as semiconductor substrates, metal substrates or ceramic substrates. For example, substrates can be silicon substrates for solar application or inorganic glass substrates for display applications or thin film solar applications.

In some embodiments, it can be desirable to form the silicon coatings described herein on a crystalline silicon wafer. The expression silicon wafer is used herein in a broad sense of a thin silicon structure without any implication on the particular shape or specific thickness. The crystalline silicon substrates can be single crystalline or highly crystalline with, for example, average crystallite sizes of at least a millimeter. While crystalline silicon substrates can be used for a range of semiconductor applications, these are particularly desirable for the formation of crystalline silicon based solar cells. It may be desirable to have light doping of the intrinsic base photoactive silicon layer to reduce electrical resistance.

Furthermore, the deposited silicon layer can be highly doped to serve as a dopant source such that a dopant can be driven into an underlying crystalline silicon substrate. It has been found that desirable dopant profiles within a silicon wafer can be produced using doped nanoparticle layer with an amorphous silicon matrix. The incorporation of suitable dopants can increase the charge carriers in the semiconducting silicon material and can correspondingly lower the electrical resistance of the material. As described herein, the doped silicon inks and corresponding densified structures can be used to form doped contacts for crystalline silicon wafer-based solar cells. The solar cells can have doped contacts of both polarities along the back surface of the solar cell, a back contact cell, or with contacts of opposite polarity along opposite surfaces of the solar cell. Also, the doped silicon inks and corresponding densified structures can be used to form components of thin film solar cells and thin film transistors.

In general, any source of the silicon substrate can be used. To reduce cost and use of resources, in some embodiments, the silicon substrate can be selected to be relatively thin, e.g. no more than about 250 microns average thickness, although the dopant drive-in process described herein can be effective also for thicker silicon substrates. Suitable substrates include, for example, wafers cut from single crystalline silicon ingots. Polycrystalline silicon can be formed as silicon ribbons pulled from a silicon melt. In general, the ribbons are grown from a structure pulled from the silicon melt. In further embodiments, silicon foils can be formed through reactive deposition onto a release layer such that the foils can then be released for further processing. Furthermore, as described herein, polycrystalline foils can be formed from densifying and heating silicon nanopowders.

Amorphous silicon has significantly greater absorption of visible light than crystalline silicon. Microcrystalline silicon and nanocrystalline silicon also have strong absorption of visible light, although the absorption is not as great as the absorption from amorphous silicon, and the absorption spectrum of microcrystalline silicon and nanocrystalline silicon is somewhat shifted from the absorption spectrum for amorphous silicon. Due to the greater absorption of visible light, solar cells formed from amorphous silicon and/or nanocrystalline silicon can have very thin structures and can be referred to as thin film solar cells. The thin film solar cells generally can be formed in a diode structure with stacked layers with a p-doped layer and an n-doped layer, which can desirably have an intrinsic layer between the doped layers to form a p-i-n structure. The p-i-n structure can be repeated in the overall structure. The composites described herein with a nanocrystalline silicon powder embedded in an amorphous silicon matrix can be well suited for the formation of a layer in a p-i-n thin film solar cell. The dopants can be introduced as desired into the nanocrystalline power and/or the amorphous silicon matrix. The combination of the nanocrystalline silicon and the amorphous silicon can provide desirable absorption of solar radiation across a desired spectral range.

The silicon structures described herein can also be effectively used for forming electronic components, such as thin film transistors or the like. Depending on the performance properties desired, various structures described herein can be used for a component of the electrical device. For example, the nanoparticle—amorphous silicon composite may be useable directly in the structure, which may be formed on relatively low temperature substrates especially if the layer is thin. Alternatively or additionally, a composite can be formed and then heated to form a uniform nanocrystalline material. Furthermore, physically compacted silicon nanoparticle deposits can be sintered to form a densified material. For example, if the deposits are formed directly or indirectly onto an inorganic glass sheet, such as a silica glass display material, or other ceramic material the sheet may be well tolerant of reasonable pressures to compact the silicon nanoparticle deposit, which can then be heated at moderate temperatures to consolidate the silicon into a densified pellet.

The high quality silicon nanoparticle inks provide desirable capability for the deposition of elemental silicon onto desired substrates for further processing. The approaches described herein provide considerable improved flexibility for consolidating the as-deposited nanoparticle deposits into densified structures. In particular, the densified silicon structures can be formed well below the melting point of silicon and can generally provide desirable properties for a range of applications. In particular, these densified silicon structures can be effectively used for solar cell applications, both crystalline silicon wafer based solar cells and thin film silicon solar cells, as well as for printed electronics applications.

### Silicon Inks

In some embodiments, inks of silicon nanoparticles can be deposited for the delivery of elemental silicon onto a substrate as a porous deposit. In some embodiments, the silicon nanoparticles can comprise a dopant that can effectively provide a dopant source, such as for the formation of doped contacts for solar cells, doped layers for thin film solar cells, and other doped semiconductor structures. The formulation of the silicon inks can be selected to provide for appropriate depositing, e.g., printing of the inks, as well as for the desired processing of the deposited silicon nanoparticles to form the desired structures from the deposits formed from the inks. Silicon inks of particular interest herein are formed from dispersions comprising a dispersing liquid and silicon nanoparticles dispersed within the liquid along with optional additives. Generally, silicon nanoparticles, e.g., doped silicon nanoparticles, generally are collected as a powder, which are then dispersed as a step in forming the ink. The dispersion can be stable with respect to avoidance of settling over a reasonable period of time, generally at least an hour or longer, without further mixing. The properties of the dispersion can then be adjusted to form a suitable ink, i.e. the dispersion is suitable for printing. More particularly, the properties of the ink can be adjusted for the particular printing method. For example, the viscosity of the ink can be adjusted for the particular use, such as inkjet printing or screen printing, and particle concentrations and additives provide some additional parameters to adjust the viscosity and other properties.

With respect to silicon inks, silicon nanoparticles may or may not be surface modified for the formation of an ink. Surface modification refers to chemical bonding of a composition to the surface of particles. While surface modification of the silicon particles may facilitate dispersion in some solvents, the ability to process the silicon nanoparticles without surface modification of the particle with an organic composition simplifies the processing and can result in reduced contamination of ultimate devices formed from the silicon inks. High concentration and good quality inks have been formed from silicon nanoparticles without surface modification. The particles can be transferred between solvents and/or formulated with solvent blends for production of desired ink formulations.

Silicon nanoparticles can be synthesized, for example, using laser pyrolysis, although other synthesis methods can be used if the satisfactory particle properties are obtained. It may be desirable for the silicon particles to be relatively uniform with respect to particle size and other properties. Specifically, it may desirable for the particles to have a uniform primary particle size, and processing may be significantly dependent on the average primary particle size. In some embodiments, it may be desirable for the primary particles to be reasonably unfused. Physical particles refer to particles accounting for any hard fusing that may be present. Processing of the particles can depend on both the primary particle size and the physical particle size. So some fusing of the primary particles can be acceptable to obtain a smaller average primary particle size. In general, if the degree of fusing can be controlled within acceptable parameters and if the primary particles are appropriately uniform with a desired small average diameter, the particles generally can be dispersed to yield a small and relatively uniform secondary particle size in the dispersion.

Primary particle size can be determined by examination of transmission electron micrographs (“TEM”) of the as-synthesized silicon nanoparticle powders. For silicon inks of interest herein, the inks can be desirably formed from a collection of silicon nanoparticles with an average primary particle diameter of no more than about 100 nm, in further embodiments no more than about 75 nm, in additional embodiments from about 1 nm to about 50 nm, and in other embodiments from about 2 nm to about 35 nm. A person of ordinary skill in the art will recognize that additional ranges of average primary particle diameter within the explicit ranges above are contemplated and are within the present disclosure. The primary particles can have very high uniformity with respect to having a narrow peak of the particle size distribution and lacking a tail in the particle size distribution. In general, high resolution TEM micrographs can also be used to evaluate physical particle sizes. Secondary particle size refers to measurements of particle size within a dispersion and is discussed in the context of dispersions below.

In some embodiments, one or more dopants can be introduced into the elemental silicon particles in concentrations from about 1.0×10⁻⁷ to about 15 atomic percent relative to the silicon atoms, in further embodiments from about 1.0×10⁻⁵ to about 5.0 atomic percent and in further embodiments from about 1×10⁻⁴ to about 1.0 atomic percent relative to the silicon atoms. Both the low dopant levels and the high dopant levels are of interest in appropriate contexts. For the low dopant levels to be of particular usefulness, the particle should be pure. For small particles, the low dopant levels essentially can correspond with less than one dopant atom per particle on average. In combination with the high purity that has been achieved for the particles, low dopant levels from about 1.0×10⁻⁷ to about 5.0×10⁻³ correspond with difficult to achieve yet potentially useful materials. In some embodiments, high dopant levels are of particular interest, and the highly doped particles can have a dopant concentration from about 0.25 atomic percent to about 15 atomic percent, in other embodiments from about 0.5 atomic percent to about 12 atomic percent, and in further embodiments from about 1 atomic percent to about 10 atomic percent. A person of ordinary skill in the art will recognize that additional ranges within the explicit dopant level ranges are contemplated and are within the present disclosure.

In general, it is desirable to form a good dispersion of particles from dry, as-synthesized powder, prior to subsequent processing steps employed to achieve desirable ink properties. Better dispersions are more stable and/or have a smaller secondary particle size indicating less agglomeration. The particles do not need to be stably dispersed initially if the particles are subsequently transferred to another liquid in which the particles form a good dispersion. Better dispersions generally can comprise a solvent that is relatively more compatible with the particles based on the particles' surface chemistry and interparticle interactions. In some embodiment, it can therefore be desirable to modify the surface chemistry of the particles to form better dispersions. Furthermore, surfactants can be used to form better dispersions, as described further below. However, while surface modification of particles and the use of surfactants can result in better dispersions, desirable inks can be formed without surface modification and without surfactants at high particle concentrations and with good deliverability. Furthermore, the ability to form desired inks without surface modification can be useful of the formation of desired devices with a lower level of contamination. Notwithstanding the composition of the initial dispersion, shear, stirring, sonication or other appropriate mixing conditions can be applied to facilitate the formation of the dispersion.

As used herein, stable dispersions have no settling after one hour without additional mixing, i.e., any initial mixing is stopped prior to timing the one hour or other selected time period. With respect to stability, in some embodiments, the dispersions exhibit no settling of particles without additional mixing after one day and in further embodiments after one week, and in additional embodiments after one month. In general, dispersions with well dispersed particles can be formed at concentrations of at least up to 30 weight percent inorganic particles. Generally, for some embodiments it is desirable to have dispersions with a particle concentration of at least about 0.05 weight percent, in other embodiments at least about 0.25 weight percent, in additional embodiments from about 0.5 weight percent to about 27.5 weight percent and in further embodiments from about 1 weight percent to about 25 weight percent. A person of ordinary skill in the art will recognize that additional ranges of stability times and concentrations within the explicit ranges above are contemplated and are within the present disclosure.

With respect to secondary particle size, size refers to measurements of particle size within a dispersion. In general, the secondary particles size can be expressed as a cumulant mean, or Z-average particle size as measured with dynamic light scattering (DLS). The Z-average particle size is based on a scattering intensity weighted distribution as a function of particle size. Evaluation of this distribution is prescribed in ISO International Standard 13321, Methods for Determination of Particle Size Distribution Part 8: Photon Correlation Spectroscopy, 1996, incorporated herein by reference.

In some embodiments, the Z-average particle size is no more than about 1 micron, in further embodiments no more than about 250 nm, in additional embodiments no more than about 100 nm, in other embodiments no more than about 75 nm and in some embodiments from about 5 nm to about 50 nm. With respect to the particle size distribution, in some embodiment, essentially all of the secondary particles can have a size no more than 5 times the Z-average secondary particle size, in further embodiments no more than about 4 times the Z-average particle size and in other embodiments no more than about 3 times the Z-average particle size. Furthermore, the DLS particle size distribution can have in some embodiments a full width at half-height of no more than about 50 percent of the Z-average particle size. Also, the secondary particles can have a distribution in sizes such that at least about 95 percent of the particles have a diameter greater than about 40 percent of the Z-average particle size and less than about 250 percent of the Z-average particle size. In further embodiments, the secondary particles can have a distribution of particle sizes such that at least about 95 percent of the particles have a particle size greater than about 60 percent of the Z-average particle size and less than about 200 percent of the Z-average particle size. A person of ordinary skill in the art will recognize that additional ranges of particle sizes and distributions within the explicit ranges above are contemplated and are within the present disclosure.

Furthermore, the formation of a good dispersion with a small secondary particle size can be facilitated through the matching of the surface chemistry of the particles with the properties of the dispersing liquid. The surface a crystalline silicon nanoparticle by its nature represents a termination of the underlying solid state structure of the particle and can comprise truncation of the silicon lattice. The termination of particular particles influences the surface chemistry of the particles. In particular, it is easier to disperse the particles to form smaller secondary particle sizes if the dispersing liquid and the particle surfaces are chemically compatible (e.g. the formation of dispersions with polar solvents is facilitated if the particles have polar groups on the particle surface), although other parameters such as density, particle surface charge, solvent molecular structure and the like also directly influence dispersability. In some embodiments, the liquid may be selected to be appropriate for the particular use of the dispersion, such as for a printing process. The surface properties of the particles can correspondingly be adjusted for the dispersions.

The surface chemistry of particles can be influenced during synthesis of the particles and/or following collection of the particles. For example, silicon synthesized using silanes generally is partially hydrogenated, i.e., the silicon includes some small amount of hydrogen in the material. It is generally unclear if this hydrogen or a portion of the hydrogen is at the surface as Si—H bonds. With respect to surface modification during synthesis, the nature of the reactants, reaction conditions, and by-products influences the surface chemistry of the particles collected as a powder during flow reactions. In some embodiments, the silicon particles can become surface oxidized, for example through exposure to air. For these embodiments, the surface can have bridging oxygen atoms in Si—O—Si structures or Si—O—H groups if hydrogen is available during the oxidation process.

With respect to surface modification after particle collection, desirable properties can be obtained through the use of surface modification agents that chemically bond to the particle surface. The surface chemistry of the particles influences the selection of desirable surface modification agents. For example, alkoxysilanes can bond with silicon oxides at the surface of silicon particles to form Si—O—Si bonds to form a stable surface coating that can improve the dispersability and other surface properties of the surface modified particles. Furthermore, it can also be desirable to functionalize the surface of the particles prior to using a surface modification agent to improve or facilitate bonding between the particle and the surface modification agent. Suitable surface modification agents and the use thereof are described in published U.S. patent application 2008/0160265 to Hieslmair et al., entitled “Silicon/Germanium Particle Inks, Doped Particles, Printing, and Processes for Semiconductor Applications,” incorporated herein by reference. While surface modified particles can be designed for use with particular solvents, desirable inks can be formed without surface modification at high particle concentrations and with good deliverability. The ability to form desired inks without surface modification can be useful for the formation of desired devices with a lower level of contamination.

Based on a particular deposition approach and use for a silicon ink, there may be fairly specific target properties of the inks as well as the corresponding liquids used in formulating the inks. Tailoring dispersion properties for a particular application or processing step can comprise changing solvent, using solvent blends, and/or evaporating solvent. With respect to changing solvents, the particles can be processed in a first solvent that facilitates processing and subsequently transferred to a second solvent with more desirable ink properties. With respect to solvent blends, a low boiling temperature solvent component can evaporate quickly after printing to stabilize the printed ink prior to further processing and curing. A higher temperature solvent component can be used to adjust the viscosity to limit spreading after printing. With respect to solvent evaporation, the particle concentration of the dispersion can be increased by evaporating solvent without destabilizing the dispersion. Methods for changing solvent, using solvent blends, and evaporating solvents are discussed in U.S. patent application Ser. No. 13/070,286 to Chiruvolu et al., entitled “Silicon/Germanium Nanoparticle Inks, Laser Pyrolysis Reactors for the Synthesis of Nanoparticles and Associated Methods,” incorporated herein by reference.

Furthermore, dispersions can comprise additional compositions besides the silicon particles and the dispersing liquid or liquid blend to modify the properties of the dispersion to facilitate the particular application. For example, property modifiers can be added to the dispersion to facilitate the deposition process. Surfactants can be effectively added to the dispersion to influence the properties of the dispersion.

In general, cationic, anionic, zwitter-ionic and nonionic surfactants can be helpful in particular applications. In some applications, the surfactant further stabilizes the particle dispersions. For these applications, the selection of the surfactant can be influenced by the particular dispersing liquid as well as the properties of the particle surfaces. Furthermore, the surfactants can be selected to influence the wetting or beading of the dispersion/ink onto the substrate surface following deposition of the dispersion. In some applications, it may be desirable for the dispersion to wet the surface, while in other applications it may be desirable for the dispersion to bead on the surface. The surface tension on the particular surface is influenced by the surfactant. Also, blends of surfactants can be helpful to combine the desired features of different surfactants, such as improve the dispersion stability and obtaining desired wetting properties following deposition. In some embodiments, the dispersions can have surfactant concentrations from about 0.01 to about 5 weight percent, and in further embodiments from about 0.02 to about 3 weight percent.

Viscosity modifiers can be added to alter the viscosity of the dispersions. Suitable viscosity modifiers include, for example soluble polymers, such as polyacrylic acid, polyvinyl pyrrolidone and polyvinyl alcohol. Other potential additives include, for example, pH adjusting agents, antioxidants, UV absorbers, antiseptic agents and the like. These additional additives are generally present in amounts of no more than about 5 weight percent. A person of ordinary skill in the art will recognize that additional ranges of surfactant and additive concentrations within the explicit ranges herein are contemplated and are within the present disclosure.

It can be desirable to remove components of the dispersion at appropriate times of the processing. For example, it can be desirable to remove organic components to the ink prior to or during certain processing steps such that the product materials are effectively free from carbon. In general, organic liquids can be evaporated to remove them from the deposited material. However, surfactants, surface modifying agents and other property modifiers may not be removable through evaporation, although they can be removed through heating at moderate temperature in an oxygen atmosphere to combust the organic materials.

The dispersions/inks can be formed using the application of appropriate mixing conditions. For example, mixers/blenders that apply shear can be used and/or sonication can be used to mix the dispersions. Furthermore, it can be desirable to increase the particle concentration of a dispersion/ink relative to an initial concentration used to form a good dispersion such as through evaporation of solvent. Similarly, solvent blends can be formed. A lower boiling solvent component can be removed preferentially through evaporation. Solvent blends can be useful for the formation of certain ink compositions since the blends can have a plurality of liquids that each contributes desirable properties to the ink. A low boiling temperature solvent component can evaporate relatively quickly after printing to stabilize the printed ink prior to further processing and curing. A higher temperature solvent component can be used to adjust the viscosity to limit spreading after printing.

With respect to inks desirable for inkjet printing, the viscosity is particularly relevant, although other printing and coating processes may have desired viscosity ranges. The viscosity of a dispersion/ink is dependent on the silicon particle concentration as well as the other additives, such as viscosity modifier. Thus, there are several parameters that provide for adjustment of the viscosity. For some embodiments, the viscosity can be from 0.1 mPa·s to about 100 mPa·s and in further embodiments from about 0.5 mPa·s to about 25 mPa·s. For some embodiments, the dispersions/inks can have a surface tension from about 2.0 to about 6.0 N/m² and in further embodiments from about 2.2 to about 5.0 N/m² and in additional embodiments form about 2.5 to about 4.5 N/m². A person of ordinary skill in the art will recognize that additional ranges of viscosity and surface tension within the explicit ranges above are contemplated and are within the present disclosure.

With respect to inks desirable for screen printing, the formulations are prepared as a paste that can be delivered through the screen. The screens generally are reused repeatedly. The solvent systems for the paste should be selected to both provide desired printing properties and to be compatible with the screens so that the screens are not damaged by the paste. The use of a solvent blend provides for the rapid evaporation of a low boiling temperature solvent while using a higher boiling solvent to control the viscosity. The high boiling solvent generally can be removed more slowly without excessive blurring of the printed image. After removal of the higher boiling temperature solvent, the printed silicon particles can be cured, or further processed into the desired device. Suitable lower boiling point solvents include, for example, isopropyl alcohol, propylene glycol or combinations thereof. Suitable higher boiling point solvents include, for examples, N-methyl pyrrolidone, dimethylformamide, terpineols, such as α-terpineol, Carbitol, butyl Cellosolve, or combinations thereof. The screen printing paste can further include a surfactant and/or a viscosity modifier.

In general, the screen printable ink or paste are very viscous and can be desired to have a viscosity from about 10 Pa·s to about 300 Pa·s, and in further embodiments from about 50 Pa·s to about 250 Pa·s. The screen printable inks can have a silicon particle concentration from about 5 weight percent to about 25 weight percent silicon particles. Also, the screen printable inks can have from 0 to about 10 weight percent lower boiling solvent, in further embodiments from about 0.5 to about 8 and in other embodiments from about 1 to about 7 weight percent lower boiling solvent. The description of screen printable pastes for the formation of electrical components is described further in U.S. Pat. No. 5,801,108 to Huang et al., entitled “Low Temperature Curable Dielectric Paste,” incorporated herein by reference, although the dielectric paste comprises additives that are not suitable for the semiconductor pastes/inks described herein.

The formation of doped silicon inks for various deposition approaches, including inkjet printing, spin coating and screen printing pastes, is described further in copending U.S. provisional patent application Ser. No. 13/070,286 to Chiruvolu et al., entitled “Silicon/Germanium Nanoparticle Inks, Laser Pyrolysis for the Synthesis of Nanoparticles and Associated Methods,” incorporated herein by reference.

### Deposition of Si Inks and Structure of Resulting Silicon Deposits

The silicon nanoparticle dispersions/inks generally can be deposited using a selected approach, such as a coating process or a printing process. The deposition approach can be selected to achieve a desired deposit of the doped ink on a substrate. In particular, coating techniques can be desirable for coating a substrate with a dispersion/ink, and printing techniques can be desirable in particular for depositing a dispersion/ink as a coating or in a pattern on a substrate. Following deposition, the ink is usually dried to form a porous elemental silicon deposit, and the deposited material can be further processed. For some applications, patterning of the silicon ink deposition is desirable to form corresponding pattern in a device incorporating the ink after further processing, such as processing to densify the silicon nanoparticle inks. Suitable printing approaches to form patterns of the inks include, for example, screen printing or inkjet printing.

The silicon nanoparticle deposits may or may not be doped. If the silicon nanoparticles used to form the deposits are doped, the corresponding silicon deposits are doped. If the silicon deposits are patterned, different locations in a pattern can be doped the same or differently. For example, some locations can be doped while other locations are not doped, i.e. are intrinsic. In some embodiments, it can be desirable to pattern p-doped silicon nanoparticles at some selected locations of the pattern and n-doped silicon nanoparticles at other locations. The different dopants at selected parts of the pattern can introduce desired functionality upon further processing.

In general, the silicon inks can be deposited on any suitable substrate, and the substrate can be selected to be suitable for the intended application. Suitable substrate surfaces can comprise, for example, elemental metal or metal alloy, semiconducting materials, dielectric ceramic materials, polymers or the like. In some embodiments, the substrate can be selected for integration as a functional component with the elemental silicon deposited with the inks to form the ultimate device while in other embodiments the substrate may form a passive support which may still be integrated into an ultimate device as a passive structural element. Integration of the substrate as a functional element of an ultimate device can involve, for example, the substrate as an electrical component of the device, such as with a crystalline silicon solar cell, or as a transparent surface, such as a glass substrate within a display.

Suitable coating approaches for the application of the doped nanoparticle inks include, for example, spin coatings, dip coating, spray coating, knife-edge coating, extrusion or the like. In particular, spin coating has been developed into a commercially reliable procedure in semiconductor applications for the formation of thin coatings and suitable processing equipment is commercially available. In general, any suitable coating thickness can be applied, although in embodiments of particular interest, the average coating thickness can range from about 10 nm to about 10 microns, in further embodiments from about 50 nm to about 7.5 microns and in other embodiments from about 100 nm to about 5 microns. A person of ordinary skill in the art will recognize that additional ranges of thicknesses within the particular ranges above are contemplated and are within the present disclosure. As described below, for the formation of silicon pellets and silicon structural elements from densified silicon inks, the thicknesses can be substantially greater than the explicit values in this paragraph.

Similarly, various printing techniques can be used to print the doped nanoparticle ink into a pattern on a substrate. Suitable printing techniques include, for example, screen printing, inkjet printing, lithographic printing, gravure printing and the like. Patterning generally comprises depositing an ink at particular locations on the surface of substrate. The selection of a pattern can be made with respect to the particular application. For some applications, a pattern can comprise a single continuous region of ink on the substrate surface, while for other applications a pattern can comprise a plurality of isolated regions of an ink on the substrate surface such that each ink region does not contact any other ink region. For some applications, it can be desirable to form a plurality of patterns, each pattern comprising a different ink composition, which may comprise different dopants, different dopant concentrations and/or other different silicon nanoparticle properties.

Also, a doped silicon ink can serve as a dopant source for dopant drive-in into an underlying silicon substrate. In some embodiments, an ink comprising doped nanoparticles can be first patterned onto a substrate surface, although coatings over the whole surface can also be used and are desirable for certain applications. Subsequently, some of the dopant can be diffused, e.g. by thermal processing, from the particles into the surface of the substrate, thereby creating a dopant profile extending into the substrate, which if the doped ink is deposited in a pattern, can have substantially the same pattern as the deposited ink. A plurality of doped regions can be created by repeating this procedure following a selected pattern. In some embodiments, at each iteration, a doped ink, comprising a different dopant, can be patterned on to the substrate surface and heated to perform dopant drive-in into the substrate, prior to forming another dopant pattern. Additionally or alternatively, a plurality of doped regions can be created by first forming a plurality of patterns on the substrate surface, each pattern formed from a doped silicon ink comprising a different dopant or dopant concentration. Subsequently, dopant can be simultaneously diffused from each doped ink location into the substrate.

Furthermore, patterning of the silicon inks can be performed onto other types for substrates for other purposes. For example, silicon inks for processing into components of display circuits can be printed in a desired pattern onto a glass sheet, such as a silica glass, other transparent material, other ceramic material or the like. Patterning with different silicon inks can be performed to pattern different components, which can have a selected structural and/or functional relationship with each other. Thus for forming thin film transistors, it may be desirable to sequentially pattern a n-doped silicon ink, a p-doped silicon ink and an intrinsic silicon ink in an appropriate order. A heat treatment for consolidation can be performed through one of the approaches described herein between patterning steps or at the end of the patterning process.

While various coating and printing approaches are suitable, inkjet printing offers desirable features for some applications with respect to speed, resolution and versatility with respect to real time selection of deposition patterning while maintaining speed and resolution. Practical deposition using inkjet printing with inorganic particles requires dispersion properties that involve both the techniques to form high quality silicon nanoparticles along with the improved ability to form high quality dispersions from these particles. Thus, the particles produced using laser pyrolysis combined with the dispersion techniques provides for the formation of inks that are amenable to inkjet deposition.

Similarly, screen printing can offer desirable features for printing silicon and/or silica inks for some applications. In particular, screen printing may already be tooled for a particular use. Thus, the substitution of the doped nanoparticle inks for other materials in a production line may be performed with reduced capital expenses. Also, the pastes for screen printing may have a greater doped nanoparticle concentration relative to concentrations suitable for other deposition approaches. In particular, the silicon particles and processes described herein are suitable for forming good quality pastes for screen printing. The successful spin coating, ink jet printing and screen printing of highly doped silicon inks is described in copending U.S. patent application Ser. No. 13/070,286 to Chiruvolu et al., entitled “Silicon/Germanium Nanoparticle Inks, Laser Pyrolysis for the Synthesis of Nanoparticles and Associated Methods,” incorporated herein by reference.

In general, following deposition, the liquid evaporates to leave the doped nanoparticles and any other non-volatile components of the inks remaining as a nanoparticle coating or layer. Heating to low temperatures can be used to accelerate the drying process, and venting or application of the reduced pressure can also facilitate the drying. Once the solvent and optional additives are removed, the resulting deposit of silicon nanoparticles can then be further processed as described herein for densifying the deposit. The nanoparticle silicon deposit forms a porous structure. After drying a deposited silicon ink, a porous silicon nanoparticle structure remains that generally has a significantly lower density relative to the bulk silicon density. In some embodiments, the density of the porous deposit may be no more than about 0.75 g/cm³, and the density may depend on the average nanoparticle size, the deposition technique and other process parameters.

The Si nanoparticle coating can also be characterized by a void volume, which can be estimated from the fraction of the area of pores in a cross section based on an observation of the pores in a micrograph of a cross section of the coating. For example, the void volume can be from about 25% to about 90% and in further embodiments from about 30% to about 85%. A person of ordinary skill in the art will recognize that additional ranges of thickness and void volume within the explicit ranges above are contemplated and are within the present disclosure.

As noted above, the silicon ink can be patterned during deposition to form a corresponding patterned porous deposit of silicon nanoparticles. In general the pattern can be selected based on the desired component formation for the particular product. Some particular patterns for selected applications are described further below. In some embodiments, to introduce patterns of particular functionality, it is generally desirable to form patterns that cover no more than about 80 percent of the substrate surface, in further embodiments no more than about 75 percent and in additional embodiments from about 10 to about 70 percent of the substrate surface. Similarly, the thickness of the silicon nanoparticle deposit can be selected for a particular application. For many applications, it is desirable for functionality to have a relatively thin silicon structure. For these embodiments, the porous silicon nanoparticle deposit generally has an average thickness of no more than about 10 microns, in further embodiments from about 50 nm to about 8 microns, in additional embodiments from about 75 nm to about 7.5 microns and in other embodiments from about 100 nm to about 6 microns. A person of ordinary skill in the art will recognize that additional ranges of pattern coverage and average thicknesses within the explicit ranges above are contemplated and are within the present disclosure.

As described herein, thick patterns or coatings can be processed into relatively dense structures or pellets through the application of pressure and heat. The densified silicon pellets can be desirable for forming silicon films, foils, strips or the like. While the silicon pellets can be processed into thin structures as described above, in some embodiments thicker structures can have thicknesses on the order of about a millimeter or more. For the formation of silicon foils or ribbons, it can be desirable to form deposits with average thicknesses from about 10 microns to about 500 microns, in further embodiments from about 20 microns to about 400 microns and in additional embodiments from about 25 microns to about 250 microns. A person of ordinary skill in the art will recognize that additional ranges of pellet thicknesses within the explicit ranges above are contemplated and are within the present disclosure. Patterned silicon pellets can have surface coverage as described above for thinner structures.

Depositing Amorphous Silicon onto a Nanocrystalline Silicon Ink Deposit to Form a Dense Composite

It has been discovered that amorphous silicon can be deposited onto and into a thin silicon nanoparticle coating to significantly fill in pores within the as-deposited nanoparticle coating structure from a dried nanoparticle silicon ink. Specifically, an amorphous silicon material can be deposited directly to substantially fill-in pores of a crystalline silicon nanoparticle coating to form a composite material with nanocrystallites embedded within an amorphous silicon matrix. For example, chemical vapor deposition can be used to deposit elemental amorphous silicon within the pores of a nanoparticle coating. The resulting composite material can be a relatively dense composite which may have some pores being visible in an appropriate micrograph. In general, the amorphous silicon may or may not be doped, and the nanocrystalline silicon independently may or may not be doped as well as optionally having a patterned structure. In some embodiments, the nanoparticle coating comprises highly doped crystalline silicon nanoparticles, and the deposited amorphous silicon material comprises intrinsic silicon. Thus, in some embodiments, the resulting composite comprises a mixture of doped and undoped elemental silicon. If the porous crystalline nanoparticle deposits are patterned, the amorphous silicon generally forms an amorphous silicon layer between locations of the composite structure formed at the corresponding locations of the initial porous nanocrystalline silicon structures. As described below, the coating material can be heat processed to form a nanocrystalline silicon material, which can be selectively doped.

The composite materials can be useful as deposited. For example, for thin film solar cells, the combination of nanocrystalline silicon and amorphous silicon can present desirable absorption properties for visible light. Thus, for thin film solar cell applications, it can be useful to form substantially complete layers of the composite for incorporation into an ultimate solar cell device, optionally without annealing the material. In thin film solar cells, the structuring is designed with stacked layers of varying dopant concentrations to form diode junctions. Also, if the composite can provide sufficient electrical conductivity for a particular application, the composite can be incorporated into a particular electronic application with relatively low temperature processing used to deposit the amorphous silicon.

As described further below, the composite can also be heat treated to convert the composite into a nanocrystalline material with relatively uniform crystallites distributed through the densified material. In this annealed material, it has been found that the nanocrystallites are generally non-rod shaped. Thus, the nanocrystalline silicon material with the non-rod shaped crystallites is observed to be different from material deposited by traditional amorphous silicon deposition techniques that are observed to deposit rod shaped crystallites roughly aligned orthogonal to the surface.

In some embodiments, it is desirable to form patterned layers of the composite. If the crystalline nanoparticles are patterned on a surface, after deposition of the amorphous silicon, the coating comprises domains with composites of nanocrystalline silicon in an amorphous silicon matrix surrounded by region of amorphous silicon. While such a structure can be desirable in a range of formats, this patterned structure can be particularly useful when the doping of the crystalline silicon is different from the doping of the amorphous silicon. For example, the crystalline silicon can be doped while the amorphous silicon is intrinsic so that the printed regions are ultimately doped with intrinsic silicon surrounding the doped regions. The patterning of doped and undoped silicon can be effective to introduce desired functionality to the resulting structure.

Since the amorphous silicon fills in the pores of the initial porous structure, the composite has a thickness roughly the same as the crystalline nanoparticle deposit except for an optional additional layer of amorphous silicon on top of the deposit. Thickness ranges for the porous silicon nanoparticle coatings are given above. The amorphous silicon capping layer can have any reasonable thickness. But for most applications, it is desirable for an amorphous silicon capping layer to be relatively thin, such as on the order of the thickness of the composite or less, and generally the amorphous silicon capping layer has a thickness of no more than about 5 microns. In general, the composite with any additional amorphous silicon capping layer can have an average total thickness of no more than about 15 microns, in further embodiments from about 50 nm to about 10 microns, in additional embodiments from about 75 nm to about 5 microns and in other embodiments from about 100 nm to about 3 microns. A person of ordinary skill in the art will recognize that additional ranges of thickness within the explicit ranges above are contemplated and are within the present disclosure.

Following the deposition of the amorphous silicon material, the resulting composite material can comprise nano-crystallites of silicon from the ink coating embedded within a matrix of amorphous silicon. The deposition conditions can generally be adjusted to produce a relatively low pore volume. In particular, the void volume can be no more than about 20%, in further embodiments, no more than about 12% and in other embodiments no more than about 8%. A person of ordinary skill in the art will recognize that additional ranges of void volume are contemplated and are within the present disclosure. Void volumes can be evaluated using scanning electron microscopy of a cross section of the material and examining the pores to assess the voids in the material and assuming spherical pores. The percentage of the cross section that is pores is a measure of the void volume. The composite has other properties that incorporate features from both materials as well as the interactions of the materials. Measurements have found no electrical conductivity through a composite formed with an intrinsic amorphous silicon matrix.

Appropriate vapor deposition of elemental silicon onto the silicon nanoparticulate layer can result in a relatively dense composite film in which the vapor deposited material can fill-in at least a significant fraction of the pores of the silicon nanoparticle layer. It is found that the conditions of the vapor deposition significantly influence the effectiveness of the deposition technique to fill-in the pores of the silicon nanoparticle layer. In particular, chemical vapor deposition (CVD) can be effective to deposit the amorphous silicon. The rate of deposition and other CVD parameters can be adjusted to form the composite with desirable properties, and suitable depositions conditions can depend on the parameters of the porous nanoparticle coating, such as thickness and porosity. In general, the rate of CVD deposition should not be too great, but reasonable rates have been achieved with desirable composite properties, as described in the Examples below. Appropriate CVD deposition approaches can be adapted for the composite formation, such as low pressure-CVD (LPCVD), plasma enhanced CVD (PECVD) and the like.

In particular, LPCVD is well suitable for composite formation. LPCVD is generally thermally driven in which heat and gaseous silane are supplied to the deposition chamber drives the reaction. While not wanting to be limited by theory, it is possible that silane gas adsorbs on the surface of the silicon nanoparticles in a particulate film. Adsorbed silane molecules can then undergo a dehydrogenation reaction to form silicon on the surface of the silicon nanoparticles. As the reactions proceed the gaps between the nanoparticles in the particulate film are filed with elemental silicon. The LPCVD deposition has been found to substantially fill-in the pores of the silicon nanoparticle layer under reasonable deposition conditions if the nanoparticle layer is sufficiently thin. Factors that affect silicon deposition are primarily the surface of the silicon nanoparticles and the temperature. The silane pressure has a smaller effect on the silicon deposition and fill in. The deposition conditions can be adjusted to provide a desired degree of pore fill-in for a particular thickness of silicon nanoparticle layer. In general, LPCVD can be used for thermally driven deposition to deposit amorphous silicon at moderate temperatures, generally from about 450° C. to about 700° C. and in further embodiments from about 500° C. to about 650° C. Generally silane (SiH₄) is the precursor for CVD silicon deposition. The pressure during the LPCVD process for amorphous silicon deposition into the porous silicon material is generally no more than about 3 Torr, in further embodiments from about 0.05 Torr to about 2.5 Torr and in additional embodiments from about 0.1 Torr to about 2 Torr. A person of ordinary skill in the art will recognize that additional ranges of deposition temperatures and pressures within the explicit ranges above are contemplated and are within the present disclosure. Furthermore, in some embodiments, a dopant can be introduced into the amorphous silicon through the introduction of a dopant source gas, such as PH₃ or B₂H₆, into the atmosphere during the CVD process. As noted above, some additional as deposited amorphous silicon can also be located over the silicon nanoparticle layer following the CVD process.

In other embodiments, germane and the like as well as blends with silane or other precursor gases can be introduced into the deposition chamber to deposit germanium, doped germanium or germanium alloys the silicon nanoparticle surfaces. Deposition of germanium and/or germanium alloys on silicon nanoparticle surfaces form bulk heterojunctions. Heterojunctions generally are believed to be particularly important for enhancing charge separation and charge transport in thin film photovoltaics. Also, alloys can be particularly useful for applications to bandgap engineering and stress management. In further embodiments, oxygen can be introduced in a mixture with silane to form a semi-insulating thin film for tuning electrical conductivity and forming surface passivation on a silicon wafer surface. The explicitly described gas precursor combinations are not intended to be exhaustive. Other gas precursor combinations are within the scope of what is disclosed in this application.

### Annealing and Dopant Drive-In of Dense Composite

The composite of crystalline silicon nanoparticles and amorphous silicon can be formed in a relatively dense structure. The composite, as deposited without further processing, is not electrically conductive and does not withstand some common wet cleaning processes. In some embodiments, it is desirable to anneal the composite with a heat treatment to more fully densify the material and to form a more durable layer or film with a homogenous crystal structure. After an anneal process, the resulting material can be a dense nanocrystalline silicon material. The nanocrystals are observed to be non-rod shaped so that the particles have relatively similar lengths along the principle axes of the particles. If the composite is deposited onto a silicon wafer or the like, it has been discovered that dopant from the composite can be driven effectively into an underlying silicon substrate. The annealed composite may have suitable electrical properties for suitable electronic components. Thus, the dopant drive-in can be effective to form a doped contact for a crystalline silicon solar cell. If the composite is patterned onto the silicon wafer, then the doped contacts can be similarly patterned along the surface of the solar cell. The annealed nanocrystalline silicon material with or without dopants can be useful for other applications, such as for the formation of electronic components.

The formation and properties of composites of crystalline nanoparticles and amorphous silicon is described in detail above. In the anneal process, while small changes may occur, the physical dimensions of the material generally may not change significantly with respect to average thickness since the composite is initially relatively dense and with a low porosity, and with respect to patterning since the material generally is not heated to a flow temperature. In some embodiments, the void volume of the annealed material is no more than about 5%, in further embodiments no more than 2.5% and in additional embodiments no more than about 1%. A person of ordinary skill in the art will recognize that additional ranges of void volume within the explicit ranges above are contemplated and are within the present disclosure. The physical dimensions described above for the composite can be effectively, equally applicable to the annealed material. However, with appropriate annealing, the material is observed to transform into a nanocrystalline material through the layer of the silicon structure. If the anneal process is performed with the composite on a highly crystalline silicon wafer, then at least a portion of the annealed material adjacent the highly crystalline silicon can crystallize epitaxially on the crystalline silicon to form an irregular epitaxial layer that transitions into the nanocrystalline layer. The amount of epitaxial silicon can depend on the precise processing conditions.

The annealing of the composite materials with a heat treatment can result in the conversion of the materials to effectively a fully nanocrystalline material. The resulting nanocrystalline silicon material has properties that are significantly different crystal structures from nanocrystalline materials formed from CVD deposition approaches in that the silicon crystallites can have average shapes that are not rod like. See, for example, Edelman et al., “Cross-section of Si:H solar cells prepared by PECVD at the edge of crystallization,” J. of Non-Crystalline Solids 299-302 (2002) pp. 1167-1172; and Micard et al., “Electrical and structural properties of p-type nanocrystalline silicon grown by LEPECVD for photovoltaic applications,” Physica status solidi C7 (2010) 3-4, pp. 712-715. Also, the annealing of a doped composite can be used to simultaneously drive dopant into an underlying crystalline silicon substrate. The dopant drive-in can result in a highly doped surface region on the silicon substrate. The dopant profile into the surface of the highly crystalline silicon substrate can have a desirable profile.

The crystallinity of the annealed material can be examined using high resolution transmission electron micrographs (TEM) of a cross section of the material. The high resolution TEMs can resolve the crystalline structure of the silicon. As observed in the TEM micrographs, the annealed nanocrystalline silicon is observed to have non-rod shaped crystals. Specifically, the crystals generally have dimensions along the principle axes of the crystal that have ratios of lengths of the longer dimension divided by the shorter dimension of no more than a factor of 3 for at least 90 percent of the particles and in further embodiments the crystals have ratios of the dimensions along the principle axes that are no more than a factor of 3 for 95 percent of the particles. In general, the average diameters of the crystallites can be no more than about 200 nm and in further embodiments from about 5 nm to about 150 nm, and in additional embodiments from about 10 nm to about 100 nm. Average diameters are obtained by averaging the lengths along the principle axes of the particle. A person of ordinary skill in the art will recognize that additional ranges of average diameters and ratios of dimensions within the explicit ranges above are contemplated and are within the present disclosure.

A capping layer has been described previously to cover a doped silicon nanoparticle ink to facilitate dopant drive-in. See, copending U.S. patent application Ser. No. 13/113,287 to Liu et al (“the '287 application”), entitled “Silicon Substrates With Doped Surface Contacts Formed From Doped Silicon Inks and Corresponding Processes,” incorporated herein by reference. The capping layer as described in the '287 application is a dielectric material that does not substantially penetrate into the silicon nanoparticle layer. For example, the capping layer can be formed from a spin-on glass. Thus, the capping layer of the '287 application is substantially different from the amorphous silicon deposition described herein to form a composite with the silicon nanoparticles with the amorphous silicon substantially filling-in the pores of the silicon nanoparticle layer. Surprisingly, the amorphous silicon matrix and a thin amorphous silicon capping layer are effective to support the dopant drive.

After the annealing process, the annealed silicon layer is presumed to have a relatively constant dopant concentration. Dopants carried from silicon nanoparticles are homogenized in the annealed silicon layer to reach approximately the average value of the dopant concentration. For embodiments with a silicon substrate, dopant concentrations remain relatively constant through the entire thickness of the nanocrystalline-Si layer and then elevated concentrations extend into the silicon substrate. The dopant profile indicates a dopant concentration in the nanocrystalline surface layer that transitions into a dopant profile extending into the silicon substrate. Annealing composites of doped silicon nanoparticles and amorphous silicon can create different types of dopant profiles compared with other drive-in methods. In some embodiments, dopant concentration decreases gradually with depth below the substrate surface. The dopant profile can have a shape approximating a Gaussian function indicating a decrease in dopant concentration extending into the silicon wafer surface until the background concentration is reached. In other embodiments, processing conditions can be selected to reduce dopant drive-in, the dopant concentration drops sharply from an elevated level to a background concentration at depths below the substrate surface at the interface between the nanocrystalline layer and the substrate. The dopant profile then has an approximately rectangular shape forming a sharp junction. Assuming that the substrate has a set low dopant concentration, the sharp junction can be a p/n junction or a high/low dopant concentration junction depending on whether opposite types or alike types of dopants are introduced into the substrate and the nanocrystalline layer. Sharp junctions have an electric field of relatively greater strength in comparison with diffusion-derived junctions having Gaussian type profiles. The characteristics of the dopant profiles described herein and achieved in the examples are suitable for the formation of efficient solar cells.

The characteristics of the dopant profile generally depend on the characteristics of the silicon nanoparticle layer and the amorphous silicon capping layer, as deposited, as well as the processing conditions. The dopant profile can be measured using Secondary Ion Mass Spectrometry (SIMS) to evaluate the elemental composition along with sputtering or other etching to sample different depths from the surface. During a thermal dopant drive in a doped nanocrystalline layer is formed. Due to the approach for forming the surface structure, there can be a surface effect from the initial a-Si deposit. If good ohmic contact is desired at the surface such as with a metal current collector, it can be desirable for the surface doping to be relatively large, such as from about 5×10¹⁹ to about 5×10²¹ and in some embodiment from 7×10¹⁹ to about 2×10²¹ to provide for good ohmic contact while maintaining low surface recombination. A plateau region in the dopant profile generally can be observed with a relatively flat slope of log concentration as a function of depth below the surface and generally no more than about log(concentration)/depth of no more than about 0.5 [log(atm/cc)/micron] and in some embodiments no more than about 0.5 [log(atm/cc)/micron] and a depth of the plateau from about 0.1 to about 0.8 microns and in further embodiments from about 0.15 to about 0.6 microns. A person of ordinary skill in the art will recognize that additional ranges within the explicit ranges above of surface dopant characteristics are contemplated and are within the present disclosure. These surface dopant parameters are generally applicable whether or not there is good dopant drive in into the silicon substrate.

To characterize the overall dopant profile into the silicon substrate following dopant drive-in used to drive dopant into the silicon substrate surface, we use an additional parameter, the depth at a dopant concentration of 1×10¹⁹ dopant atoms per cubic centimeter (atoms/cm³). With respect to depth, the dopant profile can have a depth at a dopant concentration of 1×10¹⁹ from about 0.5 microns to about 2.5 microns, in further embodiments from about 0.6 microns to about 2 microns and in other embodiments from about 0.7 microns to about 1.8 microns. For embodiments with limited dopant drive in, the depth from the edge of the surface plateau region to a dopant concentration of 1×10¹⁸ atoms/cc can be no more than about 0.3 microns. A person of ordinary skill in the art will recognize that additional ranges of dopant profile parameters within the explicit ranges above are contemplated and are within the present disclosure.

Following dopant drive-in, the resulting silicon sheet can be characterized with a sheet resistance. The sheet resistance can be measured with a 4-point probe. Measurements with the 4-point probe can then be scaled according to the geometric parameters to obtain the sheet resistance. Based on the doping using doped silicon nanoparticles and the dopant drive-in process as described herein, sheet resistances can be obtained of no more than about 120Ω/□, in further embodiments from about 100Ω/□ to about 1Ω/□, in additional embodiments from about 60Ω/□ to about 1.5Ω/□, and in other embodiments from about 50Ω/□ to about 2Ω/□. A person of ordinary skill in the art will recognize that additional ranges of sheet resistance within the explicit ranges above are contemplated and are within the present disclosure.

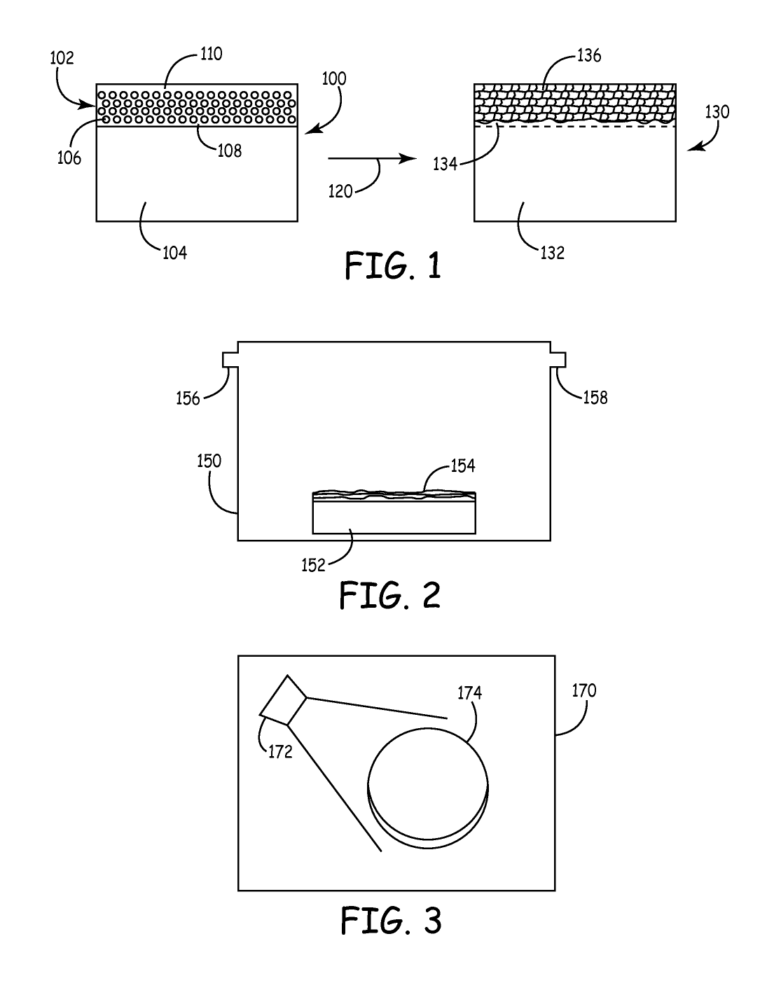

The annealing step is shown schematically in FIG. 1 for the processing of a silicon composite on a silicon wafer. The initial material 100 comprises composite 102 on substrate 104. Composite 102 comprises silicon nanoparticles 106 originating from the silicon nanoparticle ink, an amorphous silicon matrix 108 surrounding the silicon nanoparticles and an amorphous silicon layer 110 extending from the amorphous silicon matrix to cap the structure. Heat is applied to perform the anneal step as indicated by arrow 120 in FIG. 1. The resulting annealed material 130 is shown schematically in the right view of FIG. 1. Assuming that the substrate is a silicon wafer, the silicon substrate 132 includes an irregular epitaxial addition 134 extending beyond the initial surface of the substrate indicated with a phantom line in the figure. A nanocrystalline material 136 extends from the epitaxial material 134.

The dopant drive-in can be performed in an oven or the like to heat the substrate with the deposit of dopant source material to drive the dopant elements into the substrate surface. A schematic view of an oven to perform the drive-in process is shown in FIG. 2. Oven 150 holds substrate 152 that has a composite layer 154 on the surface of substrate 152. Oven 150 can comprise an inlet 156 and an outlet 158 or the like to provide for control of the atmosphere in the oven, the pressure and/or for maintaining a continuous flow through at least a portion of process. For example, a substantially oxygen free atmosphere, such as a nitrogen atmosphere or other inert atmosphere, may be used during the anneal and dopant drive-in step for embodiments with an elemental silicon substrate. The heating can be performed at ambient pressure or under reduced pressure with successful results. In general, the inert gas can be flowed through the chamber during heat processing.

The dopant drive-in generally can be performed at a temperature from about 700° C. to about 1400° C., in further embodiments from about 725° C. to about 1200° C., and in other embodiments from about 750° C. to about 1100° C. The dopant drive-in can be performed for about 5 minutes to about 6 hours, in further embodiments for about 10 minutes to about 3 hours and in additional embodiments for about 15 minutes to about 2 hours. A person of ordinary skill in the art will recognize that additional ranges of dopant processing temperatures and times within the explicit ranges above are contemplated and are within the present disclosure. If desired, an initial heating step at a lower temperature can be used to stabilize the composite prior to performing the anneal step. The dopant profile within the substrate surface may depend to some degree on the dopant drive-in parameters and the selection of the processing parameters may be influenced by the target dopant profile after the dopant drive-in.

In additional or alternative embodiments, the silicon composite with an amorphous silicon matrix around the silicon nanoparticles can be effectively and rapidly annealed with a rapid thermal process. For example, the annealing of the silicon composite can be accomplished with a heat lamp, such as a xenon heat lamp. The radiation from the heat lamp can be irradiated over the surface of in other embodiments scanned relatively rapidly across the substrate surface to anneal the silicon. The intensity and irradiation times can be selected to anneal the silicon deposits and in appropriate embodiments to drive the dopant into a silicon substrate, without otherwise significantly affecting the silicon substrate. A schematic diagram of a processing apparatus for rapid thermal heating is shown in FIG. 3, although other designs can be used as desired. Processing apparatus 170 comprises a heat lamp 172 that is designed to irradiate a coated wafer 174 or the like. In other embodiments, a conveyor or the like can be moved to scan the heat lamp 282 and/or substrate 286 to achieve their relative motion.

It may be desirable to perform a silicon oxide etch after the annealing and/or dopant drive-in to remove any silicon oxide that may have formed along the surface of the material during processing and prior to further processing to form a product. If oxygen is aggressively kept from the material through the entire process, the silicon oxide etch may not be used. Silicon oxide etch can be performed with a buffered hydrogen fluoride solution or other appropriate solution. Similarly, a plasma etch or other dry etching process can be similarly used. A buffered oxide etch, can be performed for a few minutes to several hours, although a person of ordinary skill in the art will appreciate that all subranges within this range of times are contemplated.

After performing the dopant drive-in and any densification and/or etching steps, the substrate with the annealed silicon coating can be assembled into a desired device, such as a solar cell, thin film transistor or other device. Representative application devices are described further below.

### Densification and Sintering to Form Si Pellets

In order to form a densified silicon material from the nanoparticle silicon deposit formed from an ink, the use of mechanical pressure and heat to form a densified silicon pellet can provide an alternative that can be desirable process approach in certain contexts. The application of physical pressure to mechanically densify the silicon nanoparticle deposit can be applied prior to and/or simultaneously with the application of heat to consolidate or further densify the material. In general, the pellet is formed on a selected surface. The ink can be patterned along the surface, if desired, or coated over the whole surface. This approach for pellet formation in general can be used for a wide range of silicon pellet thicknesses. Following processing, the resulting silicon material generally is nanocrystalline with a density that is moderately high but somewhat less than the density of bulk silicon. The silicon pellet may or may not be doped. In general, the pressure applied to the initial porous nanoparticle deposit can be applied using any reasonable means.

The formation of silicon pellets through the application of pressure and heat provides for formation of thin or thick silicon structures, which can form full layers or various patterns, as desired for a particular application. The formation of silicon pellets as described herein can be constrained based on the substrate. In particular, fragile substrates may be damaged by the application of excessive pressure. Thus, in some embodiments, desirable substrates can include, for example, flexible substrates, which can be appropriately supported, and durable rigid substrates, such as ceramic substrates with sufficient thickness, for example, transparent glasses, thick silicon wafers and/or dielectric sheets. The formation of silicon pellets on crystalline silicon wafers without damaging the wafer can depend on the thickness of the silicon wafer, the thickness of the silicon ink deposit and the processing approach used to form the pellet.

After the densification of a deposited nanoparticle silicon ink, the resulting silicon pellet can have a reduced thickness relative to the porous nanoparticle deposit, corresponding to the densification. As noted above, the silicon pellets can have a wide range of thicknesses. In particular, after densification the silicon pellet can have a thickness from about 250 nm to about 2 millimeter, in further embodiments, from about 500 nm to about 1 millimeter, and in additional embodiments from about 1 micron to about 500 microns. The pellet can be essentially free from visible pores, although some remaining pores can be present. The resulting pellet generally has an intermediate density that is somewhat lower than fully dense silicon but significantly denser than the initially deposited silicon nanoparticles. Thus, the silicon pellet can have a density from about 1 g/cm³ to about 2.1 g/cm³, in other embodiments from about 1.2 g/cm³ to about 2.0 g/cm³ and in further embodiments from about 1.4 g/cm³ to about 1.9 g/cm³. A person of ordinary skill in the art will recognize that additional ranges of thicknesses and density within the explicit ranges above are contemplated and are within the present disclosure.

To form the silicon pellets, generally the pressure can be applied using any reasonable approach. Nanoparticle silicon coatings have been heat treated with capping structures provided with a wafer or quartz plate over the printed substrate. See copending U.S. patent application Ser. No. 13/113,287 to Liu et al., entitled “Silicon Substrates With Doped Surface Contacts Formed From Doped Silicon Inks and Corresponding Processes,” incorporated herein by reference. With a capping wafer, the silicon ink did not densify during heating to the extent described herein, and this evidently was a result of an inadequate amount of pressure. With the system as described in the '287 application, the underlying crystalline silicon wafer may have cracked with the addition of significantly greater pressure due to the thin silicon deposits and the thinness of the wafer. Appropriate adjustment of the system provides for the application of a suitable amount of pressure to accomplish the desired degree of densification of the silicon nanoparticle deposit.

The appropriate amount of pressure generally depends on the nature of the nanoparticle silicon deposit, and this pressure can be determined empirically based on the teachings herein. Working embodiments are described in the Examples below. The pressure can be applied generally using pairs of rollers, a mechanical press, or any other convenient approach for the application of mechanical pressure. In some embodiments, rollers, a press or the like can be heated to simultaneously apply heat with the pressure. Similarly, the pressure can be applied within an oven or other heated enclosure to simultaneously apply heat and pressure. Alternatively or additionally, pressure can be applied first to achieve some initial partial densification of the nanoparticle silicon deposit prior to the application of heat, although the application of pressure can also continue after the application of heat. As shown in the Examples, the initial application of pressure facilitates the densification upon the application of heat at a temperature well below the melting point of silicon. In general, the heat is applied at a temperature from about 650° C. to about 1200° C., in further embodiments from about 700° C. to about 1150° C. and in additional embodiments from about 750° C. to about 1100° C. In general, the heat can be applied for 1 minute to about 5 hours, in further embodiments from about 5 minutes to about 3 hours and in other embodiments from about 10 minutes to about 2 hours. It can be anticipated that shorter heating times may be suitable if pressure is applied during the heating time, and the appropriate heating time may be influenced by the degree of pressure applied to the nanoparticle silicon deposit. A person of ordinary skill in the art will recognize that additional ranges of temperature and time within the explicit ranges above are contemplated and are within the present disclosure. In alternative or additional embodiments, rapid thermal annealing can be performed with a heat lamp or the like as described above in the context of FIG. 3 and alternative scanning embodiments.

### Silicon Wafer Based Solar Cell Applications

In some embodiments, solar cells comprise a crystalline silicon light absorbing layer. Doped contacts extend along the surface of the silicon substrate to provide for collection of a photocurrent. The doped contacts can be along both the front and back surfaces of the solar cell or only along the back surface of the solar cell. The formation of the doped contacts using doped silicon inks and dopant drive-in methods described herein can be adapted for the desired placement of the doped contacts. Inorganic dielectric materials generally are placed along the surfaces of the silicon substrate as a passivation layer to reduce recombination events that can result in a decrease of efficiency of the solar cell operation. Electrically conductive current collectors are appropriately placed to provide for connection of the solar cell at the doped contacts to an external circuit. Portions of the current collector generally penetrate the respective dielectric layer to make an electrical connection to the doped silicon contact. A transparent front protective layer generally is used to protect the front, light receiving surface. The remaining portion of the solar cell can be encapsulated in a polymer or the like to protect the solar cell from environmental assaults with appropriate allowance for connecting the cell to an external circuit through connection of an electrically conductive leads to the respective opposite polarity current collectors. For assembly of solar cells into a module, it is generally desired to connect a plurality of cell in a series connection to increase the voltage output, although parallel connections can also be included in addition or as an alternative to increase current.

The silicon crystalline light absorbing layer can be formed from any reasonable source. To help reduce costs, it can be desirable to use thin silicon substrates for forming the absorbing layer to reduce use of material. Suitable crystalline silicon substrates can comprise, for example, a silicon wafer cut from an ingot of single crystal silicon, a silicon ribbon, or a silicon foil. Doped and non-doped crystalline silicon wafers are commercially available generally having a diameter of about 50 mm to about 300 mm. For example, commercial wafers can be obtained, for example, from Silicon Valley Microelectronics Incorporated (CA. U.S.A.). Wafers can be etched to reduce their thickness to a desired value, although the etching process does not result in a material savings since the loss of silicon in the etching process essentially wastes the crystalline silicon.

Similarly, crystalline silicon ribbons can be formed by pulling a pair of filaments through a crucible containing molten silicon optionally comprising a dopant. As the filaments pass through the melt, a thin film of silicon forms between the filaments and quickly solidifies as it cools. Polycrystalline silicon ribbons comprising crystallite sizes of up to 25 mm×25 mm have been produced with the appropriate selection of processing parameters. With respect to dimensions, silicon ribbons can have a thickness of about 60 μm to about 1 mm and a width of about 1 cm to about 30 cm. The formation of silicon ribbons with a width of up to 50 mm and with a thickness from about 120 μm to about 1 mm is described in published U.S. patent application 2009/0025787 A to Gabor (“the '787 patent”), entitled “Wafer/Ribbon Crystal Method and Apparatus,” incorporated herein by reference.

Crystalline silicon foils can be formed by reactive deposition processes involving a release layer. A release layer is a layer with low mechanical integrity or a layer susceptible to selective removal. Thus, an overlayer can be separated from an underlying substrate through the fracture or removal of the release layer. In particular, a release layer can be effectively formed using light reactive deposition. Light reactive deposition involves a chemical reaction within a flow having suitable precursor reactants in which the reaction is driven by an intense light beam. The silicon foil layer can be formed through silicon deposition using chemical vapor deposition (CVD) or light reactive deposition onto the release layer. The as-deposited silicon layer can be recrystalized, for example, using zone melt recrystallization, to increase the crystal size in the resulting silicon foil. The separation of the silicon overlayer at the release layer results in a silicon foil, which may or may not be always supported on one surface or another. The silicon foils can be made large, and appropriate crystallite sizes have been obtained. A method for forming silicon foils using light reactive deposition is discussed in U.S. published patent application publication 2007/0212510A1 to Hieslmair et al., entitled “Thin Silicon or Germanium Sheets and Photovoltaics Formed From Thin Sheets,” incorporated herein by reference. The formation of silicon foils using CVD onto a release layer is described in U.S. published patent application 2009/0017292A1 to Hieslmair et al., entitled “Reactive Flow Deposition and Synthesis of Inorganic Foils,” incorporated herein by reference.

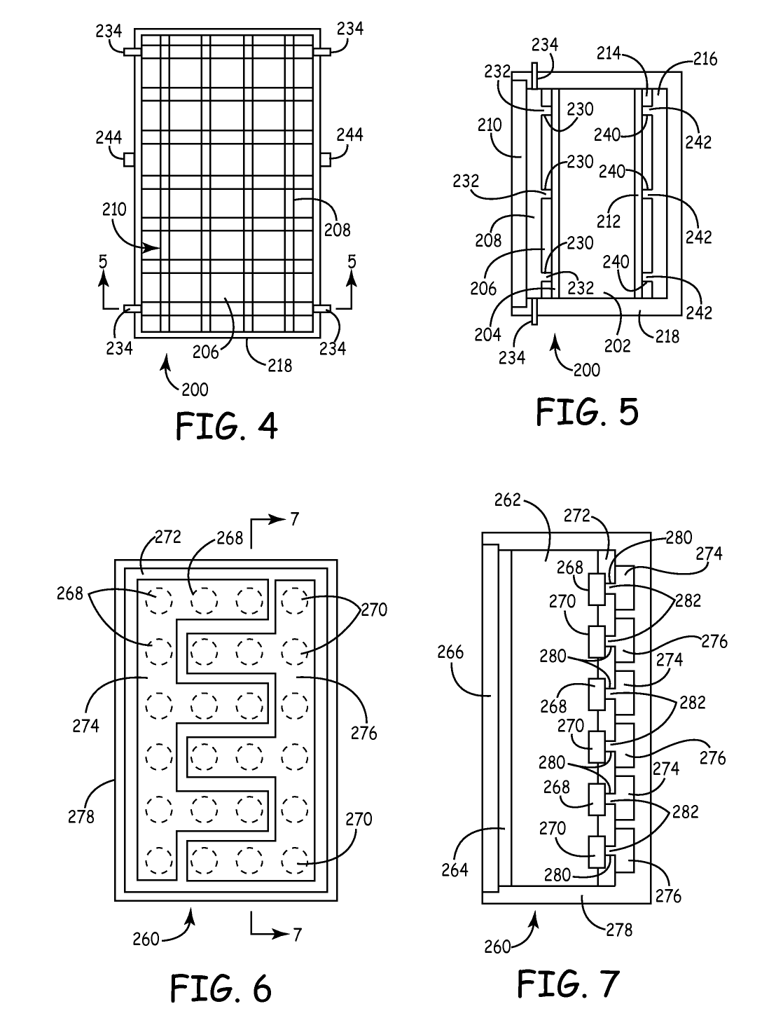

An embodiment of a photovoltaic cell with both front and rear contacts is shown schematically in FIGS. 4 and 5. Referring to FIGS. 4 and 5, photovoltaic cell 200 comprises silicon substrate 202, a front patterned doped contact 204, a front passivation layer 206, front current collector 208, front protective layer 210, back doped contact 212, back passivation layer 214, back current collector 216 and polymer encapsulant 218. In some embodiments, the silicon substrate comprises a dopant element at a relatively low dopant level, such as an n-type dopant, to increase the electrical conductivity of the silicon substrate, i.e., core silicon light absorbing layer. In general, the silicon substrate can have an average dopant concentration of about 1.0×10¹⁴ to about 1.0×10¹⁶ atoms per cubic centimeter (cc) of boron, phosphorous or other similar dopant. A person or ordinary skill in the art will recognize that additional ranges of light dopant levels within the explicit ranges above are contemplated and are within the present disclosure.

Front doped contact 204 and back doped contact 212 are generally highly doped region penetrating into the silicon substrate and may or may not comprise doped silicon extending from the substrate. Front doped contact 204 and back doped contact 212 can each comprise a selected dopant. Front doped contact 204 and back doped contact 212 can comprise independently a plurality of disconnected locations along the respective surface of the silicon substrate. In some embodiments, front doped contact 204 or back doped contact 212 can extend essentially over the entire surface of the silicon substrate. In some embodiments, it is desirable for the front doped contact to comprise an n-type dopant and for the back doped contact to comprise a p-type dopant, such that minority carriers or electrons formed by the absorption of light migrate to the front surface while oppositely charged carriers or holes migrate to the back surface. The migration of the electrons and holes results in the collecting of useful current that can be directed to an outside circuit. Suitable n-type dopants include, for example, P, Sb and/or As, and suitable p-type dopants include, for example, B, Al, Ga and/or In. Generally, the average dopant levels within the doped contacts can be from about 1.0×10¹⁸ to about 5×10²⁰, in further embodiments 2.5×10¹⁸ to about 1.0×10²⁰ and in other embodiments form 5.0×10¹⁸ to about 5.0×10¹⁹ atoms per cubic centimeter (cc). A person of ordinary skill in the art will recognize that additional ranges of average dopant levels within these explicit ranges are contemplated and are within the present disclosure. Furthermore, the dopant concentration in the doped contact has a profile with respect to the depth that more specifically characterizes the doped contact. The dopant profile generally can be a function of the approach used to drive the dopant into the substrate from the ink. The dopant delivery and dopant drive-in can be accomplished using the dopant inks as described herein, and the corresponding dopant profiles can be obtained.

Front passivation layer 206 can comprise an inorganic dielectric material. Suitable inorganic materials to form passivation layers include, for example, stoichiometric and non-stoichiometric silicon oxides, silicon nitrides, and silicon oxynitrides, silicon carbides, silicon carbonitrides, dielectric metal oxides, such as aluminum oxide, dielectric metal nitrides, such as aluminum nitride, metal oxynitrides, combinations thereof or mixtures thereof, with or without hydrogen additions or other transparent dielectric materials. In some embodiments, passivation layers can comprise, for example, SiNₓO_{y}, x≦4/3 and y≦2, silicon oxide (SiO₂), silicon nitride (Si₃N₄), silicon rich oxide (SiOₓ, x<2), or silicon rich nitride (SiNₓ, x<4/3). Holes 230 through front passivation layer 206 provide for electrical contact between front current collector 208 and front doped contact 204.

The passivation layers generally can have a thickness generally from about 10 nanometers (nm) to 800 nm and in further embodiments from 30 nm to 600 nm and in further embodiments from 50 nm to 500 nm. A person of ordinary skill in the art will recognize that additional ranges of thicknesses within the explicit ranges above are contemplated and are within the present disclosure. The passivation layers, which are generally chemically inert, can protect the semiconductor material from environmental degradation, reduce surface recombination of holes and electrons, and/or provide structural design features, as well as provide anti-reflecting properties for front surfaces. The surface can have some non-planarity to help scatter light through the silicon to achieve a greater absorption of the light.

Front current collector 208 can comprise a patterned grid of electrical conductor that provides for transmission of light past the current collector through the gaps in the electrically conductive material. Front current collector 208 comprises extensions 232 that extend through holes 230 to establish electrical conductivity between front current collector 208 and front doped contact 204. Front current collector 208 can connect a plurality of separate locations of front doped contact 204. Also, front current collector 208 generally can comprise one or more electrically conductive tabs 234 that are designed to provide electrical connections with current collector 208. If encapsulant 218 covers individual cells, tabs 234 generally are configured to extend through encapsulant 218, and if encapsulant 218 is used to enclose a plurality of cells within a module, tabs 234 can be used to connect adjacent cells, for example, in a series or in a parallel connection or to connect to an external circuit. A grid configuration of current collector 208 is depicted in FIG. 4, although other grid patterns can be used as desired. The front current collector comprises a grid of electrically conductive material, such as elemental metal or metal alloys. In general, the dimensions of the electrically conductive grid are balanced to provide a desired level of contact with the front doped layer while avoiding an undesirable amount of light blockage.

Front transparent layer 210 can comprise a transparent polymer sheet, a glass sheet, a combination thereof or the like. Suitable polymers include, for example, polycarbonates. Polymer layers can be laminated to the base cell structure. If the front transparent layer also comprises glass, an adhesive, such as silicone adhesives or EVA adhesives (ethylene vinyl acetate polymers/copolymers), can be used to secure the glass to a transparent polymer sheet or directly to the current collector surface.

Back passivation layer 214 can essentially mirror front passivation layer 206, although holes 240 through back passivation layer 214 may or may not have the same configuration and sizes as holes 230 through front passivation layer 206, although the ranges of suitable hole parameters can be equivalent for holes 240 and holes 230. Back passivation layer 214 can comprise equivalent compositions as front passivation layer 206. Similarly, back passivation layer 214 can have thickness over equivalent ranges as for front passivation layer 206. Back current collector 216 generally can be selected to reflect visible light back through silicon substrate 202 where the light can be absorbed by the semiconductor for the generation of additional photocurrent. Back current collector 216 can comprise electrically conductive metal, such as aluminum, although any suitable electrically conductive material can be used. Back current collector 216 can comprise electrically conductive tabs 244 or the like that extend to provide for electrical connection with the current collector. If encapsulant 218 covers individual cells, tabs 244 generally are configured to extend through encapsulant 218, and if encapsulant 218 is used to enclose a plurality of cells within a module, tabs 244 can be used to connect adjacent cells or to make a connection to an external circuit.

A representative embodiment of a back contact photovoltaic cell is shown in FIGS. 6 and 7. Referring to FIGS. 6 and 7, back contact photovoltaic cell 260 comprises silicon substrate 262, front passivation layer 264, front transparent protective layer 266, back p-doped contacts 268, back n-doped contacts 270, back passivation layer 272, first back current collector 274, second back current collector 276 and encapsulant 278. Silicon substrate 262 can generally have equivalent characteristics of silicon substrate 202 discussed above. The front surface of the solar cell can also have a highly doped layer with an n-type dopant to provide a front surface field that can improve the efficiency of the cell. Front passivation layer 264 can comprise suitable inorganic dielectric materials and dimensions discussed above in the context of dielectric layers 206 and 214. However, in the back contact embodiments, front passivation layer 264 generally does not have holes to provide access to underlying semiconducting material. Also, transparent front protective layer can similarly comprise a polymer, a glass, combinations thereof or the like. Encapsulant 278 can enclose an individual cell or a plurality of cells in a module with appropriate electrical interconnections, as discussed above for encapsulant 218.

The back side of photovoltaic cell 260 has a patterned structure to provide for separate locations for the opposite poles of the cell. Various patterns and structures are known in the art for forming back contacts, and any reasonable back contact structure generally can be used. The processes for patterning the back contacts are discussed below in the context of silicon inks.

Referring to FIGS. 6 and 7, doped contacts 268, 270 are arranged in a pattern that provides for connection to appropriate current collectors. For back contacts, it is desirable to have a distribution of domains of each dopant type across the surface of the semiconductor so that photocurrent can be efficiently collected. However, the domains of each dopant type should be patterned to provide for placement of a current collector interfaced appropriately with the respective dopant type. Back passivation layer 272 generally comprises holes 280 to provide for contact between the respective current collector and the corresponding doped contact. Doped contacts 268, 270 generally extend into the back surface of silicon substrate 262 and may both extend into silicon substrate 262 as well as extend outward from the back surface of silicon substrate 262. Doped contacts for back contact solar cells can be formed with silicon nanoparticle inks and dopant drive-in as described herein.

Current collectors 274, 276 are correspondingly patterned to provide electrodes of opposite polarity for the cell. Thus, first current collector 274 makes contact with p-doped contacts 268 through extensions 282 that pass through holes 280. Similarly, second current collector 276 makes contact with n-doped contacts 270 through corresponding holes 280. Current collectors 274, 276 can be formed from a suitable electrically conductive material, such as elemental metal or alloy. Metal current collectors can also function as reflectors to reflect light that passes through the semiconductor material to strike the current collector.

The formation of back contact solar cells is described further in published U.S. patent applications 2008/103293 to Hieslmair et al, entitled “Solar Cell Structures, Photovoltaic Panels and Corresponding Processes,” and 2010/0294349 to Srinivasan et al., entitled “Back Contact Solar Cells With Effective and Efficient Designs and Corresponding Patterning Processes,” both of which are incorporated herein by reference. The formation of doped contacts with silicon inks for solar cells is described further in copending U.S. patent application Ser. No. 13/113,287 to Liu et al., entitled “Silicon Substrates With Doped Surface Contacts Formed From Doped Silicon Inks and Corresponding Processes,” incorporated herein by reference.

### Thin Film Solar Cell

In the thin film solar cells, absorption of light by the semiconductor results in the transfer of an electron from a valance band to a conduction band, and a diode junction creates an electric field in the structure that results in a net flow of current following absorption of light. In particular, doped layers of opposite polarity forming a diode p-n junction can be used for harvesting the photocurrent. To achieve improved harvesting of the photocurrent and a corresponding increase in photoelectric conversion efficiency, the doped layers extend across the light absorbing structure with adjacent electrodes as current collectors. The electrode on the light receiving side generally is a transparent conductive material, such as a conductive metal oxide, so that light can reach the semiconducting materials. The electrode contacting the semiconducting material on the back side of the cell can also be a transparent electrode with an adjacent reflective conductor, although on the back side optionally a reflective conductive electrode can be used directly on the semiconductor material without a transparent conductive oxide.

A layer of intrinsic, i.e., non-doped or very low doped silicon can be placed between the p-doped and n-doped layers. The intrinsic layer generally is formed with a greater average thickness to provide for absorbing desired amount of light. Design parameters for the cell generally balance absorption of light to increase the current and efficiency with respect to harvesting the current. The p-n junction generates an electric field that drives the current harvesting. Amorphous silicon has a high optical absorption coefficient for solar radiation relative to microcrystalline, and microcrystalline silicon has a correspondingly higher optical absorption coefficient than crystalline silicon. Nanocrystalline silicon is expected to have light absorption intermediate between microcrystalline silicon and amorphous silicon. If an intrinsic layer is used, the overall structure then can be referred to as a p-i-n junction, where the letters refer to the p-doped, intrinsic and n-doped layers respectively. Generally, within a p-n junction the p-doped layer is placed toward the light receiving surface with the n-doped layer being further from the light receiving surface.

Amorphous silicon has a relatively large band gap of 1.7 eV, so that amorphous silicon generally does not efficiently absorb light with a wavelength of 700 nm or longer. Therefore, amorphous silicon may not effectively absorb a portion of the visible spectrum and correspondingly a significant portion of the solar radiation spectrum. In alternative or additional embodiments, one or more layers of the thin film solar cell can comprise nanocrystalline silicon such that desired absorption properties are obtained. As described herein, layers of the thin film solar cell can comprise a composite of amorphous silicon and nanocrystalline silicon. The doping of the composite layer can be appropriately selected.

Stacked cell have been developed in which separate stacks of absorbing semiconductors in p-n junctions are used to more fully exploit the incident light. Each p-n junction within the stack can have an intrinsic silicon absorbing layer to form a p-i-n junction. The p-n junctions within the stack are generally connected in series. In general, one or more layers within the p-i-n junctions can be formed with composites of amorphous silicon and nanocrystalline silicon. Thus, one layer within the stack or sets of stacks can be formed with the composite, or each layer with different dopants within the stack can be formed with the silicon composites, or any desired combination of layers. To obtain better efficiencies in a series connected stack, each p-n junction can be designed to generate roughly the same photocurrent as each other. The voltages generated by each p-n junction is additive. Optional dielectric buffer layers can be placed adjacent doped layers to reduce surface recombination of electrons and holes.

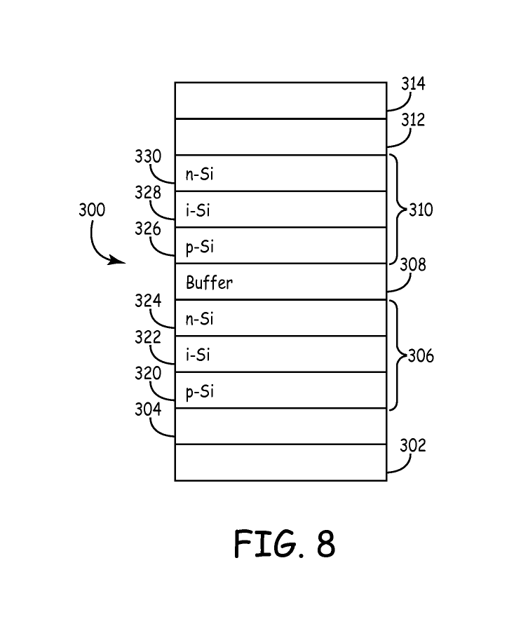

As noted above, a thin film solar cell can comprise one or a plurality of p-i-n junctions. Referring to FIG. 8, an example of a stacked silicon-based solar cell 200 comprises two p-i-n photovoltaic elements. In further embodiments, a solar cell can comprise a single p-i-n junction, or three p-i-n junctions or more than three p-i-n junctions, with corresponding changes to the structure in the figure. Specifically for the embodiment with the two junction structure, solar cell 300 comprises a front transparent layer 302, a front electrode 304, a first photovoltaic element 306, a buffer layer 308, a second photovoltaic element 310, a back transparent electrode 312, and a reflecting layer/current collector 314. Solar cell 300 can be formed without buffer layer 308. Also, solar cell 300 can be formed without back transparent electrode 312, in which case current collector 314 functions as a reflective back electrode.

In general, a variety of structures can be used for photovoltaic elements 306, 310. The use of a plurality of photovoltaic elements can be used to provide for absorption of a greater amount of the incident light. Elements 306 and 310 may or may not have equivalent structures. For example, photovoltaic element 310 can comprise a specific structure of a photovoltaic element such as shown in FIG. 8.

Referring to FIG. 8, photovoltaic elements 306 and 310 comprises three layers of polycrystalline silicon. In particular, in the specific embodiment of FIG. 8, photovoltaic element 306 comprises p-doped silicon layer 320, intrinsic silicon layer 322, n-doped silicon layer 324. Photovoltaic element 310 comprises p-doped silicon layer 326, intrinsic silicon layer 328 and n-doped silicon layer 330. One or more of silicon layers 320, 322, 324, 326, 328, 330 can comprise composites of crystalline silicon nanoparticles embedded in an amorphous silicon matrix, as described herein. Additionally or alternatively, one or more silicon layers 320, 322, 324, 326, 328, 330 can comprise nanocrystalline silicon such as formed from a silicon pellet or an annealed composite of silicon nanoparticles embedded in amorphous silicon matrix.

It can be desirable to form photovoltaic elements of a stacked solar cell such that the current through each photovoltaic element is substantially the same within desired bounds. The voltage of a stacked solar cell formed from a plurality of photovoltaic elements connected in series is substantially the sum of the voltages across each photovoltaic element. The current through a stacked solar cell formed from a plurality of photovoltaic elements connected in series is generally a value that is substantially the current of the photovoltaic element generating the smallest current. The thickness of the thin films which forms each photovoltaic element can be adjusted based on the target of matching the current through each respective photovoltaic element.

### Electronic Applications

The silicon materials derived from silicon nanoparticle inks described herein can also be used for the formation of integrated circuits for certain applications. For example, thin film transistors (TFTs) can be used to gate new display structures including, for example, active matrix liquid crystal displays, electrophoretic displays, and organic light emitting diode displays (OLED). Appropriate elements of the transistors can be printed with silicon inks using conventional photolithographic approaches or for moderate resolution using inkjet printing or other suitable printing techniques. The substrates can be selected to be compatible with the processing temperatures for the ink. Appropriate components can be formed, for example, from composites of crystalline silicon nanoparticles embedded in an amorphous silicon matrix, nanocrystalline silicon, such as formed form annealing the silicon composites, and/or nanocrystalline silicon pellets.

The TFTs generally comprise doped semiconductor elements and corresponding interfaces. Thin film transistors used as electronic gates for a range of active matrix displays are described further in Published U.S. Patent Application number 2003/0222315A to Amundson et al., entitled “Backplanes for Display Applications, and Components for use Therein,” incorporated herein by reference. An n-type doped silicon TFT active element with an anode common structure with an organic LED element is described further in U.S. Pat. No. 6,727,645 to Tsjimura et al., entitled “Organic LED Device,” incorporated herein by reference. OLED display structures are described further, for example, in published U.S. Patent Application 2003/0190763 to Cok et al., entitled “Method of Manufacturing a Top-Emitting OLED Display Device With Desiccant Structures,” incorporated herein by reference. Conventional photolithography techniques for the formation of TFTs is described further in U.S. Pat. No. 6,759,711 to Powell, entitled “Method of Manufacturing a Transistor,” incorporated herein by reference. These conventional photolithography approaches can be replaced with the printing approaches described herein. U.S. Pat. No. 6,759,711 further describes integration of TFTs with an active matrix liquid crystal display. The silicon nanoparticle inks and corresponding silicon materials herein can be effectively used to print elements of a TFT with selected dopants.

Biochips are growing in use for diagnostic medical purposes. See, for example, U.S. Pat. No. 6,761,816 to Blackburn et al., entitled “Printed Circuit Boards With Monolayers and Capture Ligands,” incorporated herein by reference. The biochip arrays can have electrical circuits integrated with biological components so that automatic evaluations can be performed. The patternable silicon materials described herein can be used to form electrical components for these devices while biological liquids can be printed or otherwise deposited for the other components.

Radio-Frequency Identification (RFID) tags are gaining widespread use for loss prevention. These devices are desired to be small for less obtrusiveness and low cost. The silicon inks and corresponding silicon materials described herein can be used effectively to print RFIDs or components thereof. Systems for printing RFIDs on a roll-to-roll configuration are described further in published U.S. Patent Application serial number 2006/0267776A to Taki et al., entitled “RFID-Tag Fabricating Apparatus and Cartridge,” incorporated herein by reference.

### EXAMPLES

The examples below demonstrate the formation and performance silicon substrates with a silicon layer processed on a silicon wafer in which the silicon layer is formed form a composite of crystalline silicon nanoparticles within an amorphous silicon matrix as well as the formation and performance of silicon nanoparticle pellets. Each of the samples in the following examples was prepared from crystalline silicon nanoparticles deposited from an ink. Crystalline silicon particles were formed with and without high levels of doping using laser pyrolysis as described in Example 2 of copending U.S. patent application Ser. No. 13/070,286 to Chiruvolu et al., entitled “Silicon/Germanium Nanoparticle Inks, Laser Pyrolysis Reactors for the Synthesis of Nanoparticles and Associated Methods,” incorporated herein by reference. In particular, doped particles were formed with 2-4 atomic percent phosphorous or boron (n++ doped and p++ doped, respectively) or 0.2-0.5 atomic percent phosphorous or boron (n+ doped and p+ doped, respectively). Non-doped (“intrinsic”) silicon particles were also formed. The nanoparticles were formed alternatively with an average primary particle size of about 7 nm or about 20 nm, and corresponding inks are referenced with respect to the nanoparticle average diameters.

Examples 1-3, below, are directed to structures formed from ink coated substrates. The substrates in Examples 1-3 comprised either an n-type or p-type crystalline silicon wafer which was obtained from a commercial source. N-type and p-type silicon wafers comprised ≦3×10¹⁵ atm/cc phosphorous and 4.6×10¹⁵ atm/cc boron, respectively, as dopants.

### Example 1

### Characterization of Amorphous Silicon Matrices and Polycrystalline Layers

This example demonstrates deposition of amorphous silicon matrices onto and into porous silicon nanoparticle coated substrates. The example also demonstrates the annealing of resulting composite silicon layers during dopant drive-in into the underlying silicon substrate.

To demonstrate deposition, 4 samples were prepared. Each sample was formed by depositing amorphous silicon onto a porous silicon nanoparticle coated silicon substrate. Porous silicon nanoparticle coated substrates were prepared by spin coating an ink comprising doped or intrinsic silicon particles onto a silicon wafer substrate. Spin-coating inks were formed from dispersions of crystalline silicon particles, synthesized as described above. In particular, crystalline silicon particles were blended with an appropriate amount of a low molecular weight alcohol, such as isopropanol, to form a dispersion. The resulting mixture was then sonicated and centrifuged to form a stable dispersion that was used as an ink for spin coating. The spin-coating inks thus formed had a silicon particle concentration of about 3-7 weight percent (“wt %”).

Prior to spin-coating, the wafer substrates were cleaned in Piranha solution (which contains concentrated H₂SO₄ and 30% H₂O₂ in 40 to 1 volume ratio) at 120° C. for 15 minutes to remove organic contaminants, then rinsed using deionized water. The cleaned substrates were then etched in 20% KOH in water at 85° C. for 15 minutes to remove saw damage on the wafer surface and rinsed thoroughly using deionized water. The surface of a substrate was cleaned by placing it in a buffered oxide etch (“BOE”) solution for about 0.5 min. to about 1 min and rinsed using deionized water. The BOE solution comprised 34.86% ammonium fluoride and 6.6% hydrofluoric acid in water. The ink was then deposited on the cleaned substrate by spin-coating in a glove-box environment substantially free from contaminating sources. The ink was spin-coated on the wafer substrate at 1000 rpm-1500 rpm for about 10 seconds to about 15 seconds. The ink coated substrate was then dried by heating them at about 85° C. for about 5 minutes on a hotplate to remove the solvent from the inks to form a porous silicon nanoparticle coating.

The dried ink layer had an average thickness of about 0.2 μm to about 2.1 μm. The thickness of the dried ink layer was measured using a profilometer (α-Step™ 300, KLA Tencore). In order to obtain thickness measurements, a given spin recipe was used to form a dried ink layer on a polished wafer substrate. A stylus in contact with the dried ink layer was then scanned horizontally over a distance of about 0.5 mm to about 1 mm on the dried ink layer and the vertical displacement of the stylus was recorded. A scribe was performed to create a step.

The ink coated substrates were pre-annealed prior to LPCVD. Pre-annealing comprised placing an ink coated substrate in a quartz tube furnace. After three rounds of cycle purge with N₂, the furnace was set at 10 standard liters per minute (SLM) N₂ continuous flow and 60 Torr vacuum pressure as heating it to 600° C. at 10° C./minute and soaked at 600° C. for 30 min. After ink deposition and the pre-anneal step if used, low pressure chemical vapor deposition (“LPCVD”) was used to deposit an amorphous silicon matrix around the particles in the ink layers of ink coated substrates. The LPCVD process was performed at a commercial vendor and comprised depositing amorphous silicon on the surface of the ink coated substrate under an atmosphere of silane at flow rate of 150 standard cubic centimeters per minute (sccm) and 200 mTorr pressure in a horizontal quartz tube furnace at a temperature of 525° C. for 90 min. Growth rate of amorphous silicon in these conditions is approximately 1 nm/min, corresponding to 90 nm of amorphous silicon on polished wafers and 80-100 nm on top of spin-on ink layer based on cross section SEM.

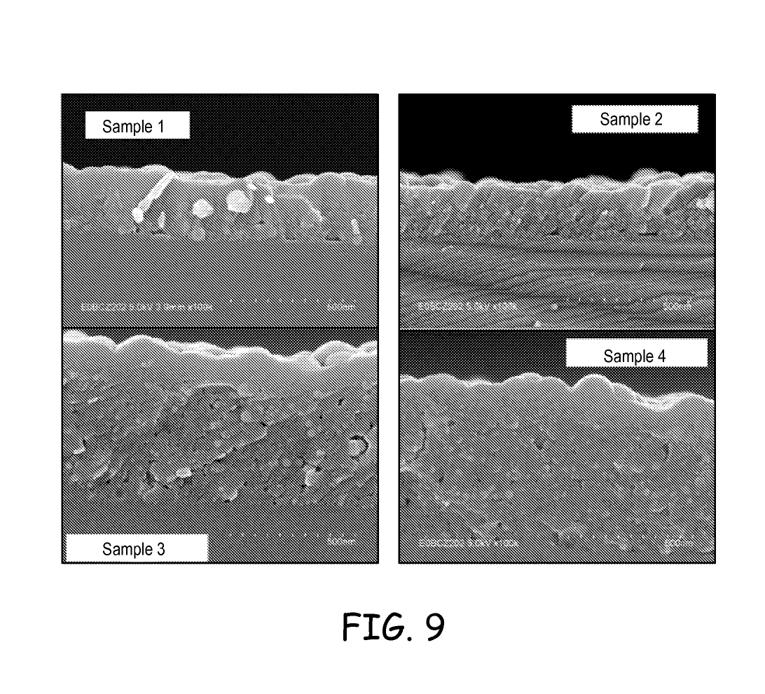

Parameters for each sample are displayed in Table 1, below. FIG. 9 is a composite of SEM images of cross-sections of samples 1-4, obtained after deposition of the amorphous silicon matrix and prior to dopant drive-in. FIG. 9 reveals an ink layer comprising silicon particles surrounded by an amorphous silicon matrix and an amorphous silicon layer on top of the ink layer. The structure of composite layers had silvery grey appearance. It did not withstand wet cleaning and was not electrically conductive.

TABLE 1

| | | | Average | | | |
|---|---|---|---|---|---|---|
| | | | Primary | Target Spin-On | Pre-anneal | a-Si |
| Sample | Particle | | Particle | Thickness | at 600° C. | deposition |
| No. | Doping | Substrate | Size(nm) | (μm) | for 30 minutes | conditions |
| 1 | intrinsic | p-type | 20 | 0.25 | Yes | 525° C. |
| | | Si wafer | | | | 90 minutes |
| 2 | n++ | p-type | 20 | 0.25 | Yes | 525° C. |
| | | Si wafer | | | | 90 minutes |
| 3 | p+ | p-type | 20 | 0.5 | Yes | 525° C. |
| | | Si wafer | | | | 90 minutes |
| 4 | n+ | p-type | 20 | 0.5 | Yes | 525° C. |
| | | Si wafer | | | | 90 minutes |

To demonstrate formation of annealed nanocrystalline silicon layers from the composite, composite coated wafers comprising coatings of crystalline silicon nanoparticles embedded in amorphous silicon matrices were subjected to thermal dopant drive-in (“dopant drive-in”). In particular, 4 additional samples were formed. Three samples were formed from composite coated wafers, and the fourth sample was a p-type silicon wafer substrate without any further a-Si deposition nor drive-in which was used as a reference for Raman spectroscopy. Each composite coated substrate was formed by spin-coating an ink comprising n++ doped silicon particles onto a p-type silicon wafer substrate. LPCVD was performed at 525° C. for 90 min. Dopant drive-in was performed on all of samples 5-7 and comprised heating them in a furnace for 1 hour at 950° C. or 1050° C. Sample parameters for each sample are displayed in Table 2 below. In Table 2, “v” is the frequency of the Raman spectral peak and “FWHH” is the full width at half height of the Raman spectral peak.

TABLE 2

| | | Sample No. | | | | |
|---|---|---|---|---|---|---|
| | p-type | | | | 6 | |
| | Si wafer | 5 | 6 | 7 | (prior to drive-in) | |
| Particle | N/A | n++ | n++ | n++ | n++ | |
| Doping | | | | | | |
| Average | N/A | 20 | 7 | 7 | 7 | |
| Primary | | | | | | |
| Particle | | | | | | |
| Size (nm) | | | | | | |
| Ink Layer | N/A | 0.5 | 0.5 | 0.5 | 0.5 | |
| Thickness | | | | | | |
| (μm) | | | | | | |
| Pre-Anneal | N/A | Yes | Yes | Yes | Yes | |
| Dopant | N/A | 1050 | 1050 | 950 | N/A | |
| Drive-In | | | | | | |
| Furnace | | | | | | |
| Temperature | | | | | | |
| (° C) | | | | | | |
| Raman peak | 520.1 | 519.7 | 519.8 | 519.0 | 513.4 | 480 |
| position, | | | | | | |
| v (cm⁻¹) | | | | | | |
| Raman Peak | 4.2 | 6.0 | 5.6 | 6.8 | Narrow | Broad |
| Width, | | | | | | |
| FWHH (cm⁻¹) | | | | | | |
| Raman Peak | c-Si | c-Si | c-Si | c-Si | Si NPs | a-Si |
| Assignment | | | | | | |

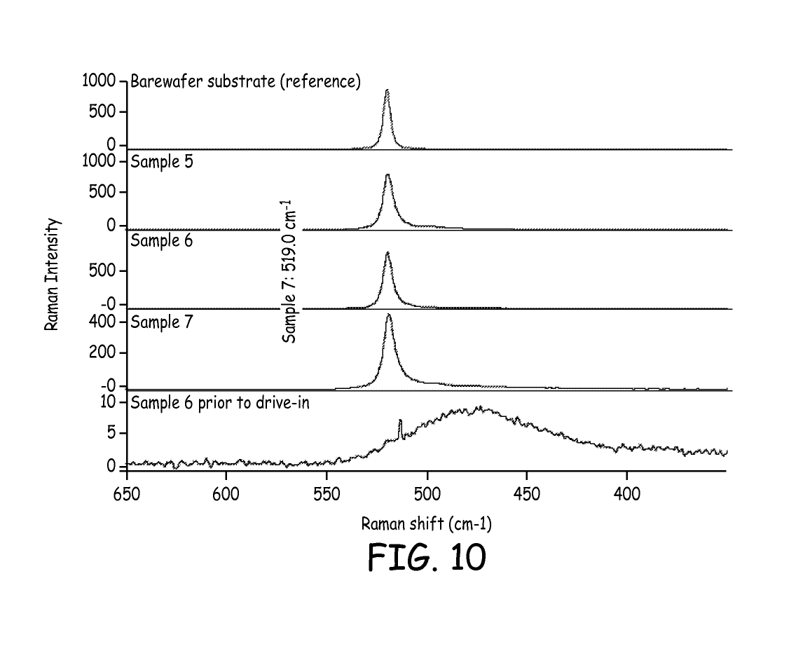

The coated samples comprised after annealing a nanocrystalline layer. The presence of the crystallized layer was confirmed by vibrational Raman spectroscopy performed on the ink coated samples. FIG. 10 is a graph containing vibrational Raman spectra (i.e. intensity vs. shift) for samples 5-7 and the bare wafer. Raman peak frequency (“v” in cm⁻¹) and peak width at full width half height (“FWHH”) are listed in Table 2. To demonstrate crystallization, Raman spectra of sample 6 before and after dopant drive-in are compared. Referring to Table 2 and FIG. 10, before drive-in, Sample 6 had peaks at ˜480 cm⁻¹ and 513.4 cm⁻¹, respectively, corresponding to amorphous silicon (“a-Si”) and silicon nanoparticles (“Si NPs”), indicating that the composite comprised silicon nanoparticles embedded in an amorphous silicon matrix. After drive-in, both a-Si and Si NP peaks disappeared and a crystalline silicon (“c-Si”) peak appears at ˜519 cm⁻¹ indicating silicon nanoparticles were substantially re-crystallized. The c-Si peaks associated with nanocrystalline silicon layer of sample 5-7 had lower frequencies and broader widths relative to the c-Si peak of the bare monocrystalline silicon wafer, indicating lesser crystal quality in samples 5-7.

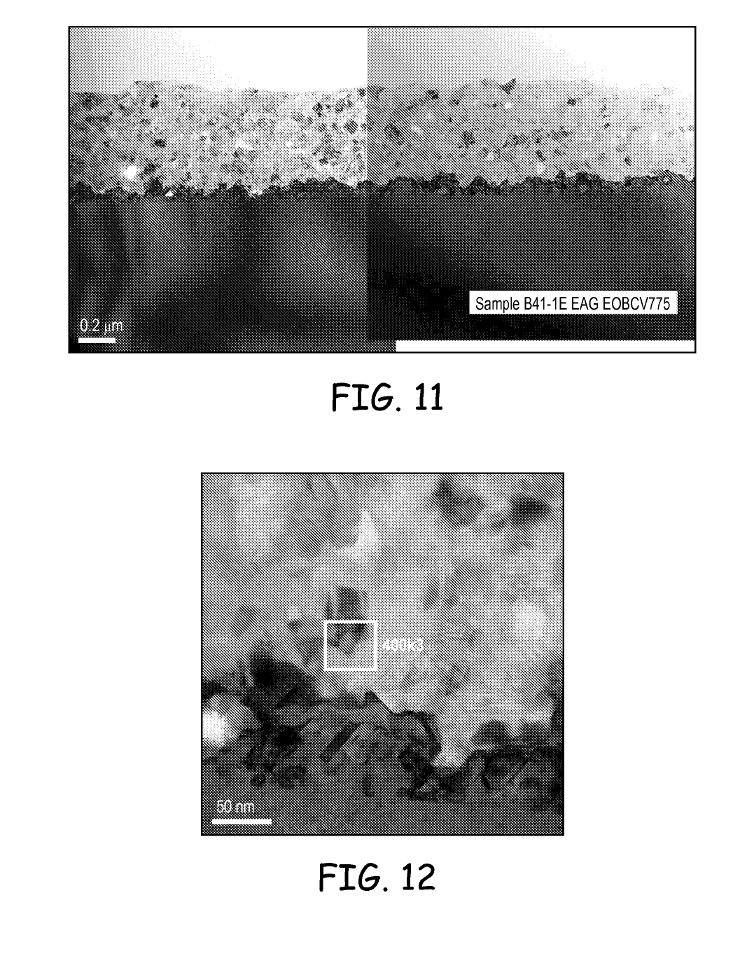

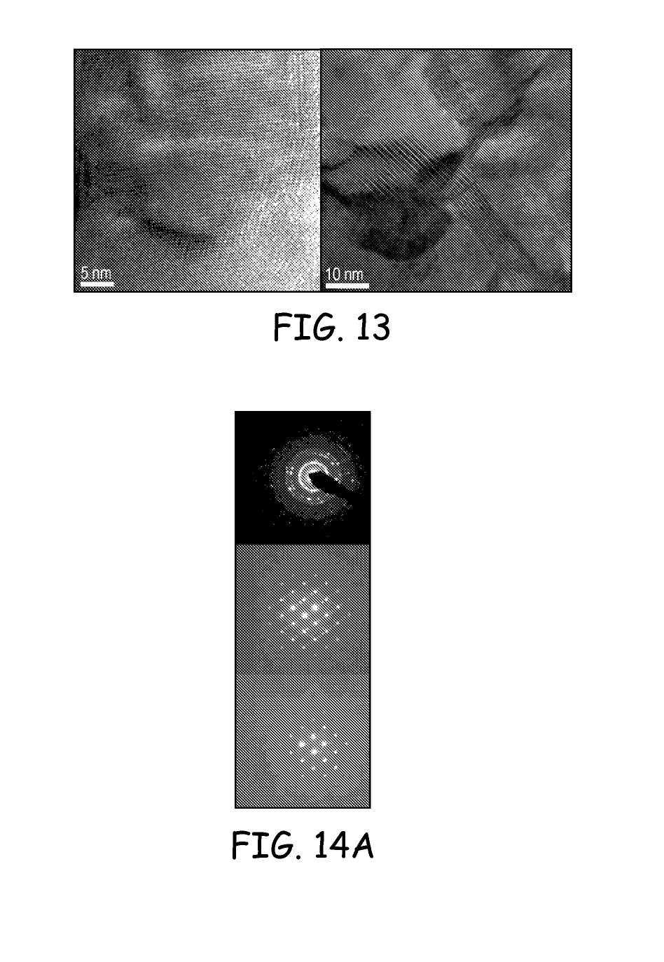

In particular, the samples comprised a nanocrystalline layer on top of an irregular epitaxially layer that forms from the deposited silicon along the crystalline silicon surface of the wafer. FIGS. 11 and 12 are high resolution transmission electron microscopy (“TEM”) images of a cross section of sample 5, taken at different magnifications. FIGS. 11 and 12 demonstrate that after formation, the samples comprised a rough epitaxial layer contiguous with the substrate and a nanocrystalline silicon layer disposed on top of the epitaxial layer. FIG. 13 is a composite of TEM images of a cross-section of the nanocrystalline layer (left panel) and epitaxial layer (right panel) of sample 5. In particular, the left panel of FIG. 13 is a TEM image of the cross-sectional area of sample 5 denoted by the bounding box displayed in FIG. 12. FIG. 13 reveals that sample 5 comprised a substantially crystalline epitaxial layer and a nanocrystalline layer comprising randomly oriented grains. The dark field TEM reveals crystallite size is about 60 nm in sample 5.

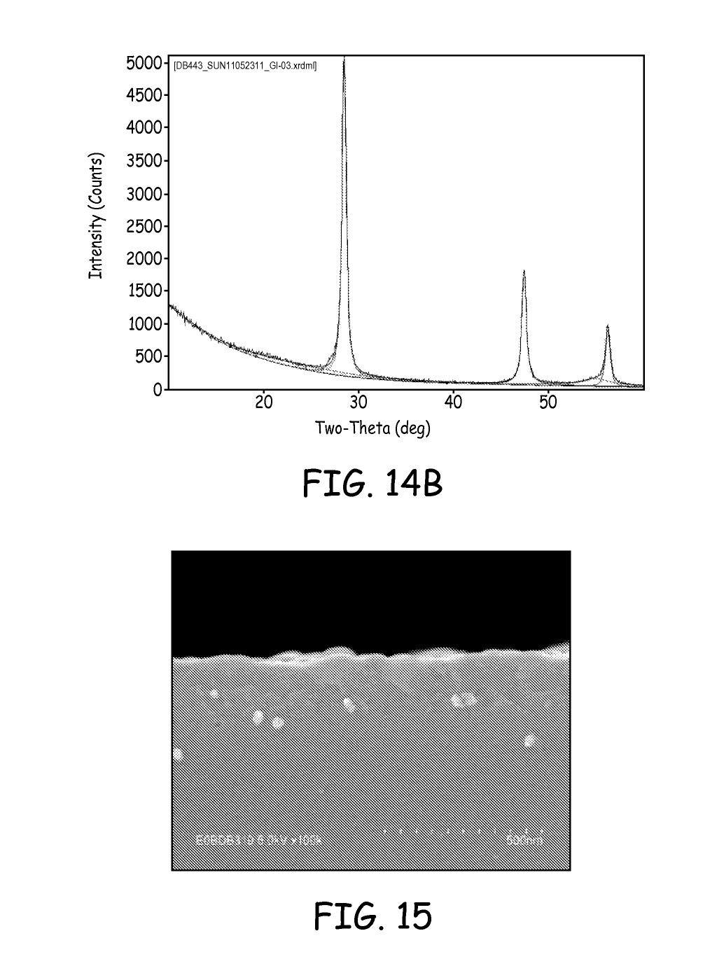

These results are confirmed by the diffractograms in FIGS. 14A and B. FIG. 14A is a composite of Selected Area Electron Diffraction (“SAED”) patterns obtained from TEM analysis on the nanocrystalline layer (top panel), the epitaxial layer (middle panel), and the wafer substrate (bottom panel) of sample 5. The top panel of FIG. 14A shows rings of bright dots confirming randomly oriented crystalline structure of the nanocrystalline layer. The middle and bottom panels of FIG. 14A confirms the highly crystalline structure with long range order of the epitaxial layer aligned with substrate, although the epitaxial layer contains microtwin defects. FIG. 14B is a diffractogram of Grazing Incidence X-Ray Diffraction (“GI XRD”) analysis on a nanocrystalline layer formed by depositing 75 nm LPCVD a-Si on a 0.25 μm spin-on of 20 nm n++ Si ink on n-type Si wafer, then subjected to dopant drive-in at 950° C. for one hour, as described above. The dark trace in FIG. 14B is the measured diffractogram which plots the diffraction intensity as a function of angle 2 theta. The diffractogram consists of three crystal peaks, i.e., <111>, <220>, and <311>, in ascending angle 2 theta. The overlapping traces are from curve fitting analysis to produce peak area and peak width for estimation of crystallinity and crystallite size. Crystallinity is about 80% and crystallite size is on average 30 nm.

### Example 2

### Dopant Drive-In

This example demonstrates dopant drive-in by thermal dopant diffusion from silicon composites formed from highly doped crystalline silicon nanoparticles embedded in an un-doped amorphous silicon matrix.

To demonstrate dopant drive-in, 11 samples were prepared, and some of the samples from Example 1 are further included in the group of samples for the analysis of dopant drive-in. All samples comprised a composite coated wafer comprising an amorphous silicon matrix with embedded crystalline silicon nanoparticle, formed as described in Example 1. For each sample, the ink coated substrate for further processing was formed by spin coating an ink comprising n++ doped silicon particles on a p-type silicon wafer substrate except for sample 12 which was on a n-type silicon substrate. The dried ink layer had an average target thickness of 0.25 μm, or 0.5 μm, or 1 μm. LPCVD was performed at 525° C. for 90 min, for samples 5, 8-10, 12 and 13, and at 540° C. for 30 min, for sample 11. For each sample comprising an annealed nanocrystalline layer, the ink coated substrate with the amorphous silicon matrix was subjected to dopant drive-in, which comprised heating it in a furnace at 950° C. or at 1050° C. for 1 hr. After formation, some of the samples were stain-etched by placing them in a commercially obtained solution comprising hydrofluoric acid, nitric acid, and acetic acid (“HNA”). Stain etching selectively removed highly doped regions in which a-Si has highest etch rate, followed by heavily doped silicon, and then substrate silicon, and the stain etching provided a visual boundary between regions of the crystalline portions of the samples. In addition to stained visual changes to the structure, etching uniformity also serves as a visual evaluation on crystal quality of the nanocrystalline silicon layer.

Sample and process parameters for each sample are displayed in Tables 3 and 4. FIG. 15 is a scanning electron microscopy image (“SEM”) of a cross-section of sample 12 showing the polycrystalline layer formed during dopant drive-in.

TABLE 3
SIMS Results of 20 nm n++ Si NPs/a-Si on Si Wafers

| Sample and Process | | | | SIMS and Diffusion | | |
|---|---|---|---|---|---|---|
| | | Target Ink | Dopant | BOE | | |
| Sample | Wafer | Thickness | Drive-in | Treat- | [P] | Rs_diff |
| Number | Type | (μm) | (° C.) | ment | (atm/cc) | (Ω/sq.) |
| 8 | P-type | 1 | 1050 | After | 3.0E+20 | 39 |
| 5 | P-type | 0.5 | 1050 | After | 2.0E+20 | 22 |
| 9 | P-type | 0.5 | 1050 | After | 2.0E+20 | 20 |
| 10 | P-type | 0.5 | No | Before | 3.0E+20 | N/A |
| 11 | N-type | 0.25 | 950 | Before | 1.5E+20 | 740 |
| 12 | P-type | 0.25 | 1050 | Before | 3.0E+20 | 44 |
| 13 | P-type | 0.25 | 1050 | After | 1.0E+20 | 51 |

TABLE 4
SIMS Results of 7 nm n++ Si NPs/a-Si on Si Wafers

| Sample and Process | | | | | | |
|---|---|---|---|---|---|---|
| | | Target Ink | Dopant | SIMS and Dopant Diffusion | | |
| Sample | Wafer | Thickness | Drive-in | BOE | [P] | Rs_diff |
| Number | Type | (μm) | (° C.) | Treatment | (atm/cc) | (Ω/sq.) |
| 14 | P-type | 0.5 | 1050° C. | After | 1.0E+21 | 10 |
| 15 | P-type | 0.5 | 950° C. | After | 2.0E+21 | 173 |
| 16 | P-type | 0.25 | 1050° C. | Before | 9.0E+20 | 7 |
| 17 | P-type | 0.25 | No | Before | 2.0E+21 | N/A |
| (sample 16 prior | | | | | | |
| to drive-in) | | | | | | |

After dopant drive-in, dopant profiles were measured by secondary-ion mass spectrometry (“SIMS”) in which etching was used to access different depths within the sample. Dopant profiles of samples were obtained after BOE treatment. Tables 3 and 4 list the average phosphorous concentration (“[P]”) in the nanocrystalline/composite layers. Sample 17 is sample 16 prior to dopant drive-in and has been listed as a separate sample for clarity. Upon drive-in, [P] decreases slightly from 2.0×10²¹ to 9.0×10²⁰ atm/cc indicating phosphorus diffused out of the composite layer into silicon wafer substrate.

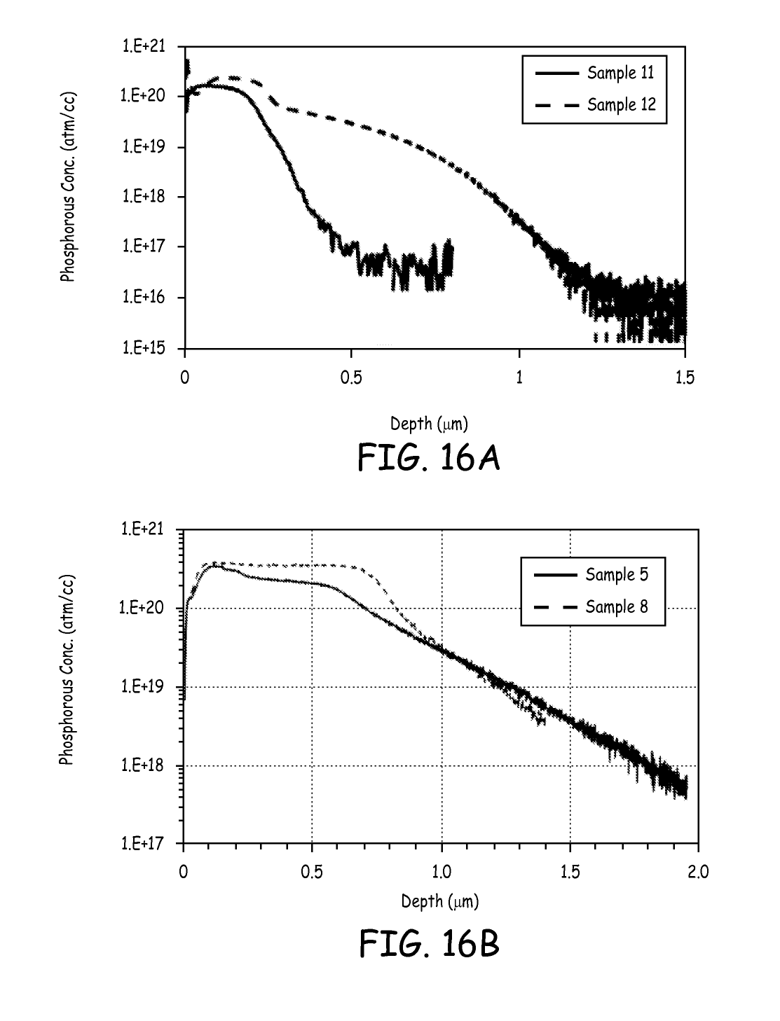

Selected examples of dopant profiles after drive-in (i.e. dopant concentration as function of distance from the sample surface) are presented in FIG. 16A and FIG. 16B. FIG. 16A is a graph containing dopant profiles of samples 11 and 12 and FIG. 16B is a graph containing dopant profiles of samples 5 and 8. FIG. 16A shows two types of profiles. The dopant profile of sample 11 represents a rectangular profile. [P] remains constant at 1.5×10²⁰ atm/cc through the polycrystalline layer approximately 0.3 μm in thickness followed by a sharp decrease to the substrate level. The dopant profile of sample 12 presents a composite profile. It reveals an initial surface depletion layer where [P] is 1×10⁺²⁰ atm/cc at small distances at ˜0.1 μm before rapidly increasing with depth into the material towards a plateau region where [P] is 3×10⁺²⁰ atm/cc followed by a monotonic decrease into wafer substrate. At depth of approximately 0.3 μm, an abrupt change in SIMS trace is indicative of boundary between nanocrystalline silicon layer and wafer surface. In general, location of the boundary is confirmed from phosphorus atoms out-diffused from the nanocrystalline silicon layer and in-diffused to wafer substrates. At wafer surface, phosphorus concentration is 6×10⁺¹⁹ atm/cc. At depth about 0.7 μm, [P] is 1×10⁺¹⁹ atm/cc. Beyond 1.3 μm. [P] virtually drops to substrate level.

FIG. 16B contains two composite profiles, as mentioned above. This set of samples indicates minor changes in [P] in the plateau region. Different from the composite profile described in FIG. 16A, the dopant profiles of samples 5 and 8 reveal that the plateau region contains an initial step-decrease in [P] followed by an extended region of relatively constant [P] in the nanocrystalline silicon layer before monotonically decreasing to substrate level [P].

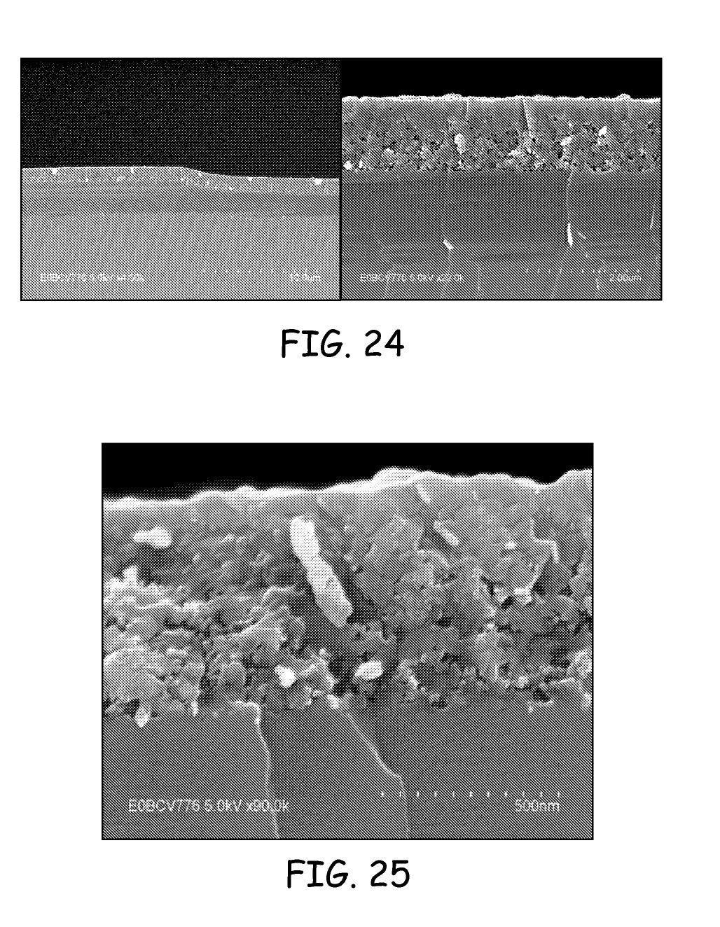

To further quantify dopant drive-in, the sheet resistance of the diffusion layers (“Rs_diff”) were calculated by integrating corresponding dopant profiles (i.e. phosphorus dopant atoms) over the region defined by distance between the wafer surface to where the phosphorus concentration reached substrate level. The conductivity of monocrystalline silicon was used in the calculation. Tables 3 and 4 list Rs_diff values for the samples. The Rs_diff values displayed in Tables 3 and 4 range from 7 Ω/sq. to 740 Ω/sq. Primary factors that effected Rs_diff were dopant drive-in temperature and time. Samples subjected to higher drive-in temperatures and the longer drive-in times, had a lower Rs_diff, relative to analogous samples subjected to lower drive-in temperatures and shorter drive-in times. Secondary factors that effected Rs_diff included type of silicon inks and the ink layer thickness. Comparing Rs_diff values displayed in Tables 3 and 4, phosphorus concentration in the nanocrystalline layer formed from 7 nm Si inks was about 5 times higher, on average, than analogous nanocrystalline layers formed from 20 nm inks. Accordingly, Rs_diff from 7 nm Si ink was several times lower than that of 20 nm Si ink at the same drive-in and process conditions. In general, Rs_diff decreased with increasing ink layer thickness, particularly for 20 nm Si inks, as evidenced by comparing samples 5 and 9 (0.5 μm ink layer thickness) with samples 12 and 13 (0.25 μm ink thickness). For 7 nm Si inks, on the other hand, dependence of Rs_diff on thickness was less apparent probably due to greater phosphorus concentration in 7 nm Si inks. Sample 8 is an exception. It had the thickest spin-on (>1 μm) and the highest Rs_diff. As shown in FIG. 24, nanocrystalline layer of this sample is porous. Dopant diffusion is limited through such porous structure, leading to high Rs_diff. Also, a relatively large error may have introduced in estimating its Rs_diff because the dopant profile of sample 8 did not show the abrupt change indicative of the wafer surface in the boundary between the nanocrystalline silicon layer and substrate.

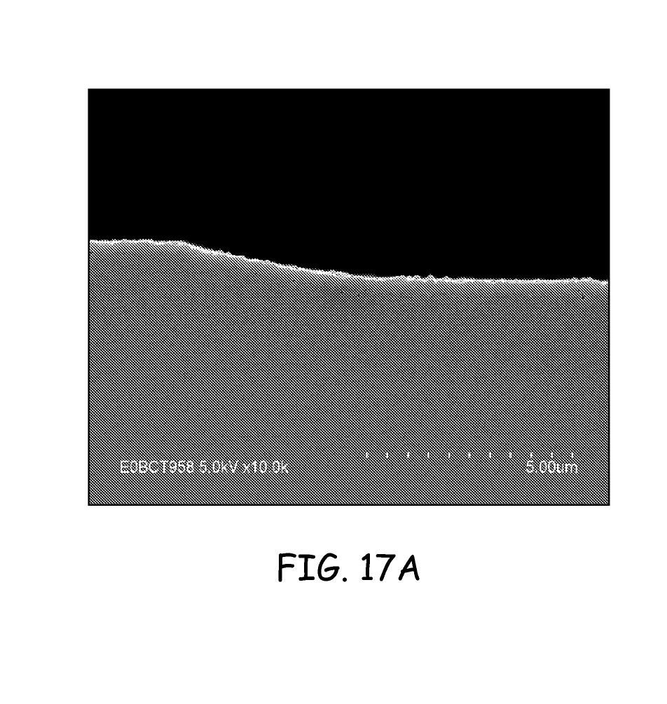

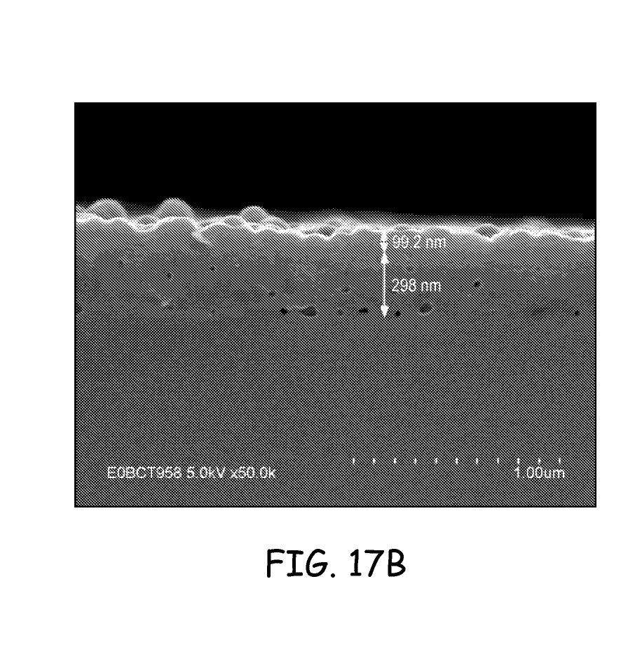

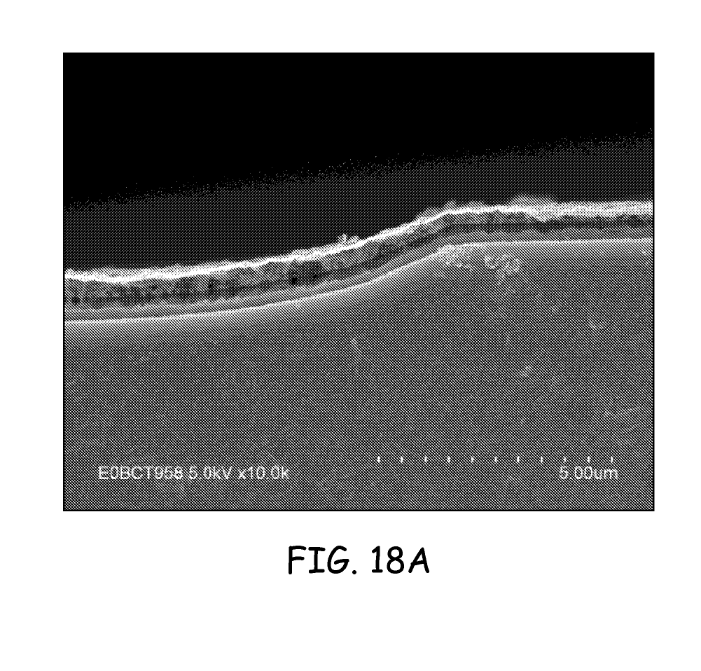

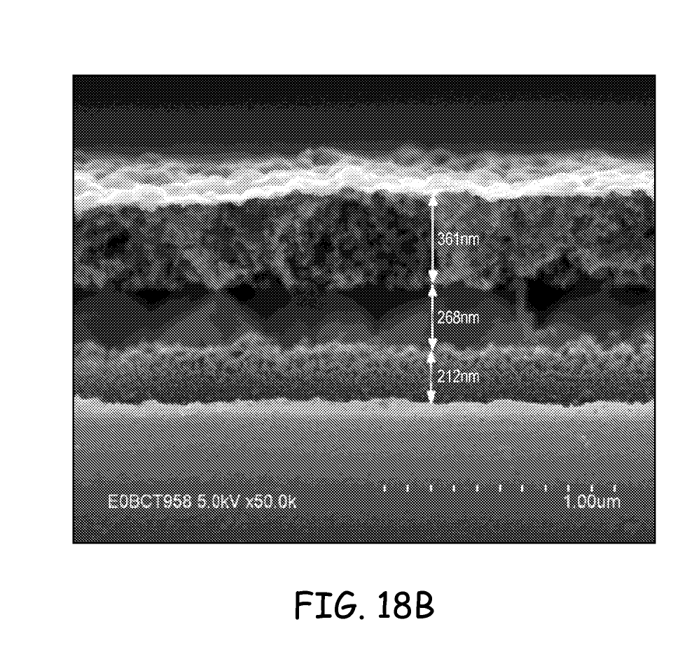

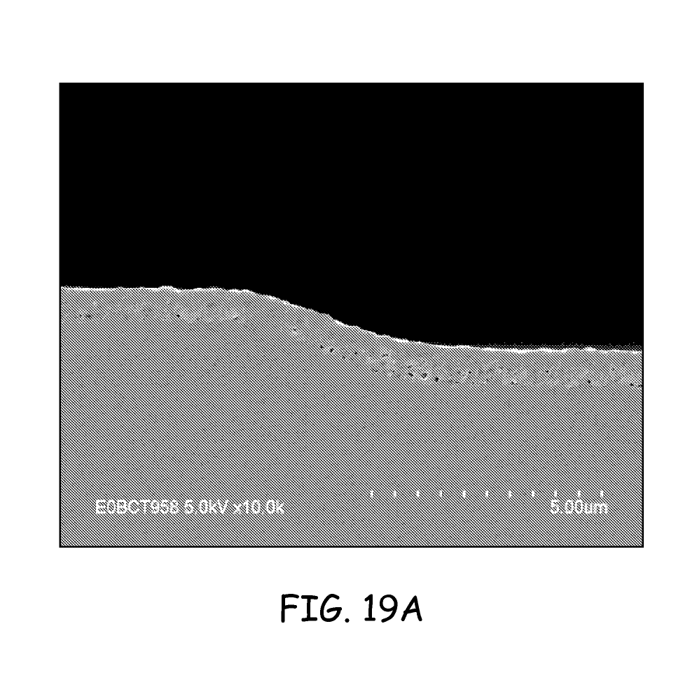

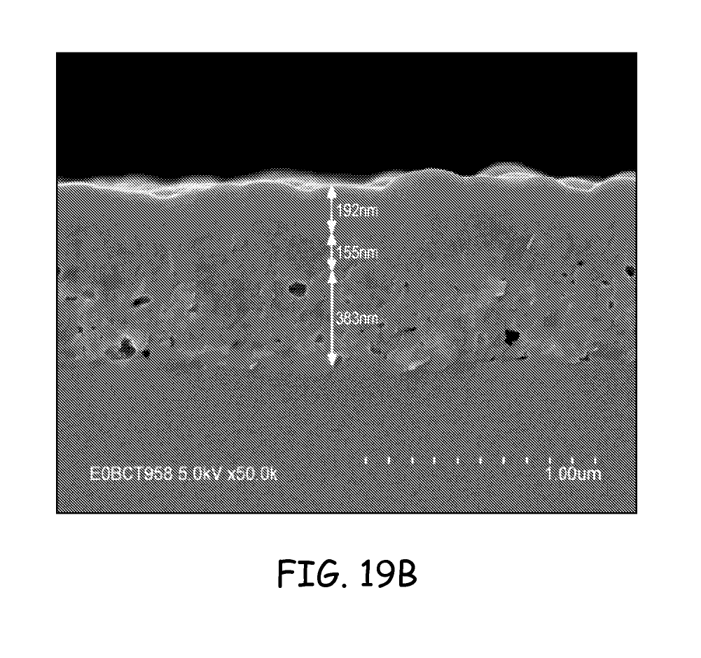

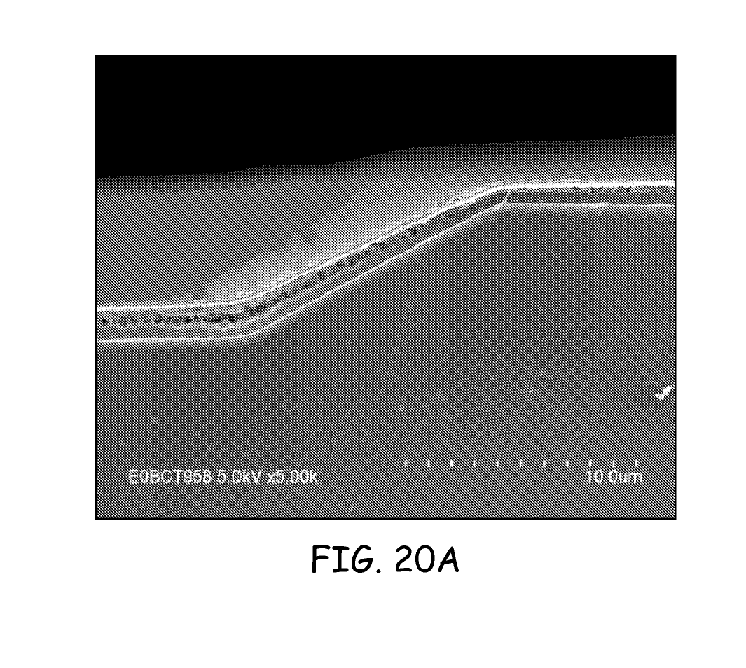

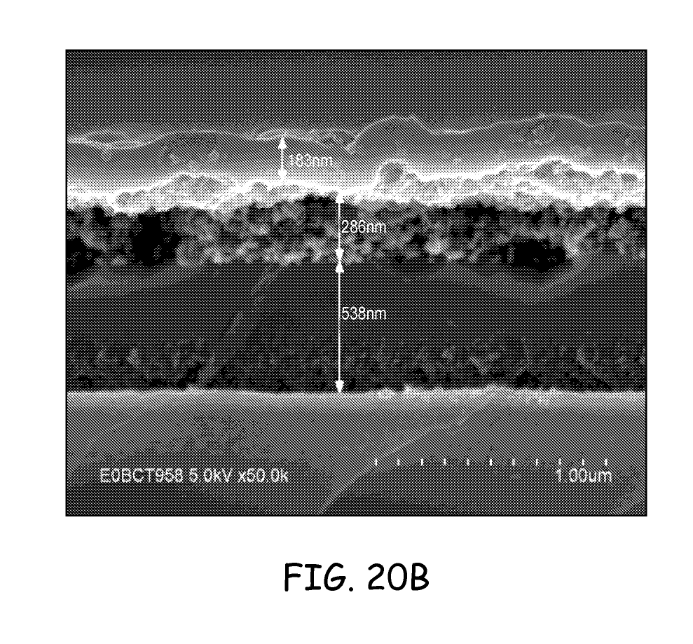

The presence of dopant in the substrates was confirmed by stain-etching. FIGS. 17A and 17B are SEM images of cross-sections of sample 5, taken at different magnifications. FIGS. 18A and 18B are analogous to FIGS. 17A and 17B, respectively, and show cross-sections of sample 5 after stain-etching. Referring to FIGS. 17A and 17B, the substrate of sample 5 was uniformly doped, even along curvatures of the substrate surface. Furthermore, as shown in FIGS. 18A and 18B, stain-etching revealed uniform substrate doping to at least about 212 nm from the substrate surface. FIGS. 19A and 19B are SEM images of cross-sections of sample 9, taken at different magnifications. FIGS. 20A and 20B are analogous to FIGS. 19A and 19B, respectively, and show cross-sections of sample 9 after stain-etching. FIGS. 20A and 20B revealed relatively uniform substrate doping.

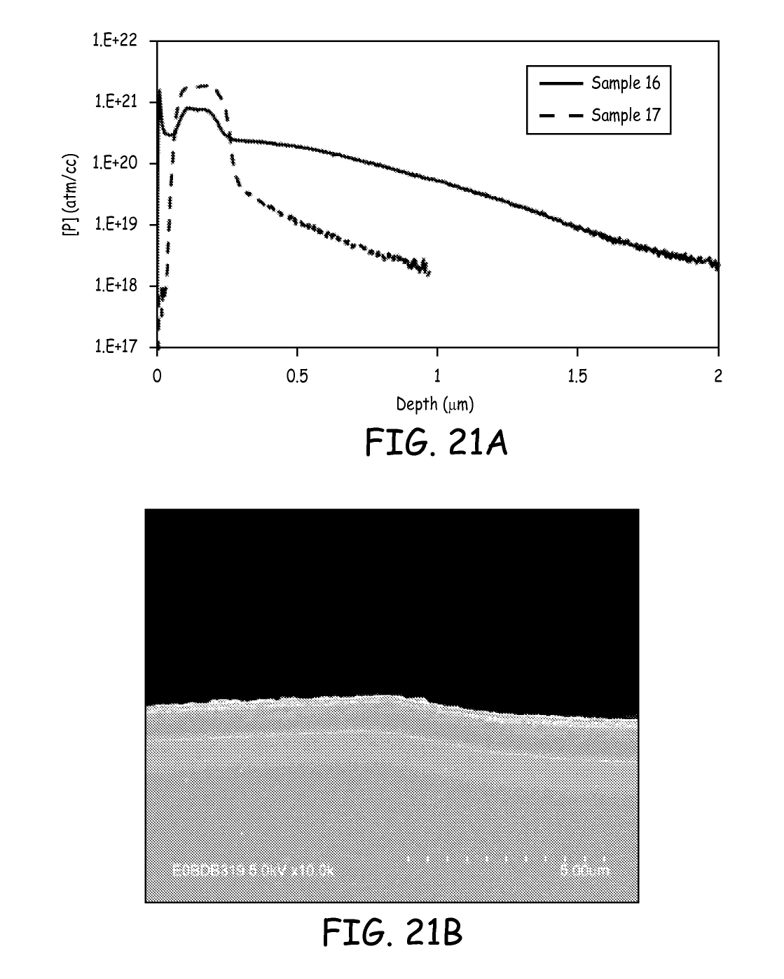

Sample 16 is used to further demonstrate dopant diffusion after drive-in based on SIMS profiles and junction stained SEMs. FIG. 21A is a graph containing dopant profiles of samples 16 and 17. The dopant profiles of samples 17 and 16 reflect dopant distribution before and after dopant drive-in, respectively. Before drive-in, represented by the dashed trace in the graph, all phosphorus atoms are contained in the ink layer. There is no detectable phosphorus in the top skin layer of a-Si up to a depth of 0.1 μm. Beyond 0.3 μm depth, phosphorus is likely the result of residual ink, namely, tailing effect from uneven substrate surface. After drive-in, represented by the solid trace in the graph, dopant redistribution is evident from a decrease in plateau [P] from 2.0×10⁺21 atm/cc, before drive-in, to 9.0×10⁺²⁰ atm/cc, after drive-in, resulted from phosphorus diffusion into the top skin layer of a-Si and into the wafer substrate as deep as 2 μm. FIG. 21B is an SEM image of cross section of sample 16, after stain etch. FIG. 15 is an SEM image of a cross-section of sample 16, obtained before stain etching. Comparing FIGS. 15 and 21B reveals phosphorus doping in silicon substrate in two layers, each of about 0.8 μm in thickness, relatively consistent with its SIMS profile represented by the solid trace in FIG. 21A.

### Example 3

### Sheet Resistance

This example demonstrates the sheet resistance of samples comprising a polycrystalline layer on p-type wafer substrate.

To demonstrate sheet resistance, 8 samples were prepared, which include samples discussed in the previous two Examples for other properties. All samples were prepared in the similar way to Example 2. The dried ink layer having an average target thickness of 0.25 μm, or 0.5 μm, or 1 μm on p-type silicon substrate was pre-annealed at 600° C. for 30 minutes. LPCVD was performed at 525° C. for 90 min. Drive-in was performed at either 1050° C. or 950° C. for one hour. Following dopant drive-in, the sheet resistance of each sample was measured using a four-point probe (“4PP”), before or after BOE treatment. BOE does not change 4PP values and sheet resistance before BOE is listed in Table 5 and 6 along with parameters for each sample, below.

TABLE 5

| Sample No. | 5 | 18 | 12 | 19 | 8 |
|---|---|---|---|---|---|
| Average Primary | 20 | 20 | 20 | 20 | 20 |
| Particle Size (nm) | | | | | |
| Target Ink Layer | 0.5 | 0.5 | 0.25 | 0.5 | 1.0 |
| Thickness (μm) | | | | | |
| Ink Type | n++ | n++ | n++ | n++ | n++ |
| Substrate type | P | P | P | P | P |
| Before or After | Before | Before | Before | Before | Before |
| BOE | | | | | |
| Pre-Anneal | Yes | Yes | Yes | Yes | Yes |
| Dopant Drive-In | 1050 | 1050 | 1050 | 1050 | 1050 |
| Furnace | | | | | |
| Temperature (° C.) | | | | | |
| Measured Sheet | 17.9 | 16.3 | 8.8 | 30.0 | 27.8 |
| Resistance, Rs_M, | | | | | |
| (Ω/sq.) | | | | | |
| Rs_poly (Ω/sq.) | High | N/A | Low | N/A | High |

TABLE 6

| Sample No. | 20 | 13 | 21 | 15 | 22 | 23 | 24 | 25 |
|---|---|---|---|---|---|---|---|---|
| Average Primary | 20 | 20 | 20 | 7 | 7 | 7 | 7 | 7 |
| Particle Size (nm) | | | | | | | | |
| Target Ink Layer | 0.5 | 0.25 | 1.0 | 0.5 | 2.1 | 0.5 | 0.25 | 0.25 |
| Thickness (μm) | | | | | | | | |
| Ink Type | n++ | n++ | n++ | n++ | n++ | n++ | n++ | n++ |
| Substrate type | P | P | P | P | P | P | P | P |
| Before or After BOE | Before | Before | Before | Before | Before | Before | Before | Before |
| Pre-Anneal | Yes | Yes | Yes | Yes | Yes | Yes | Yes | Yes |
| Dopant Drive-In | 950 | 1050 | 1050 | 950 | 1050 | 1050 | 1050 | 1050 |
| Furnace Temperature | | | | | | | | |
| (° C.) | | | | | | | | |
| Measured Sheet | 80.5 | 35.70 | 25.9 | 37.0 | 5.8 | 4.0 | 17.3 | 11.0 |
| Resistance, Rs_M, | | | | | | | | |
| (Ω/sq.) | | | | | | | | |
| Rs_poly (Ω/sq.) | N/A | High | N/A | N/A | N/A | Low | N/A | Low |

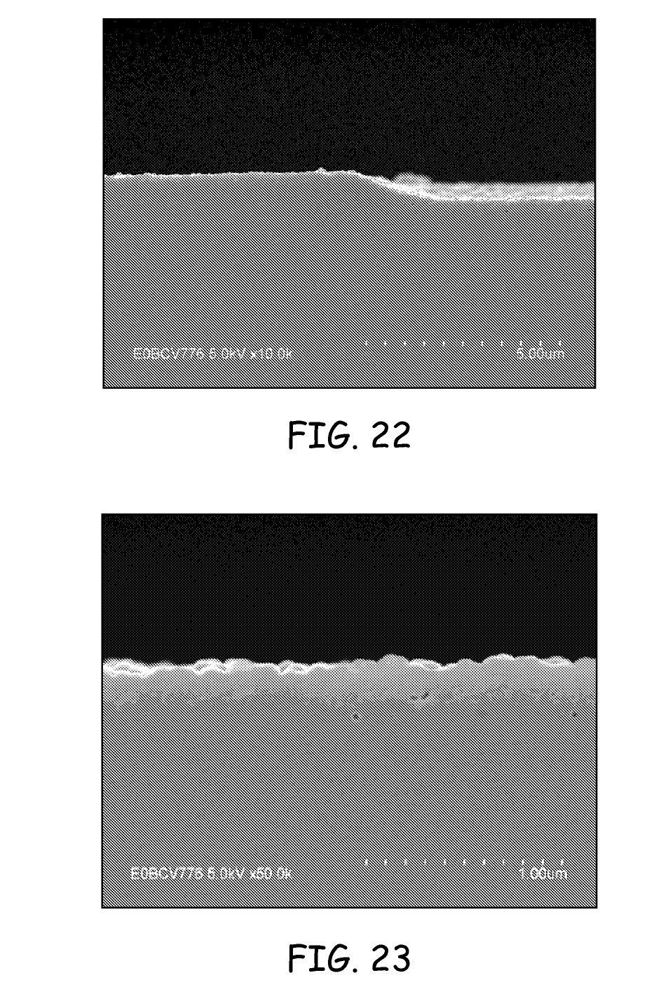

The measured sheet resistance (“Rs_M”) using a 4PP reflects the electrical conductivity of the structure comprising the nanocrystalline silicon layer, the diffusion layer, and the substrate. Because silicon substrate dopant level is relatively low (≦3.5×10¹⁵ atm/cc for the p-type substrate used in this set of samples), the substrate contribution to Rs_M is small and ignored. The silicon layer and the diffusion layer were modeled as two resistors in parallel, i.e., the nanocrystalline silicon layer having a sheet resistance Rs_poly, and the diffusion layer having a sheet resistance Rs_diff. Using this model, Rs_poly was calculated as Rs_poly=(Rs_M×Rs_diff)/(Rs_diff−Rs_M), where Rs_diff was obtained from Table 3 and 4. In Table 5 and 6, Rs_poly is ranked as either “high” or “low”. Samples 12 and 25 have low Rs_poly and samples 5, 8 and 13 have high Rs_poly. Within the thickness ranges of interest, crystal quality or porosity of the nanocrystalline silicon layer dominated Rs_poly. FIGS. 22 and 23 are SEM images of a cross-section of sample 12, taken at different magnifications and demonstrate that sample 12 had a substantially densified nanocrystalline silicon layer with very little porosity. FIG. 15 is an SEM image of a cross-section of sample 25 and demonstrates that sample 25 had a layer of completely densified and highly crystalline silicon. Because of their high crystal quality and low porosity, Samples 12 and 25 have relatively low R_poly. On the other hand, FIG. 24 is an composite of SEM images of sample 8, taken at different magnifications and shows the annealed nanocrystalline layer of sample 8 is not fully densified, resulting high porosity and poor crystal quality. FIG. 17B is a SEM image of a cross-section of sample 5 and demonstrates the annealed nanocrystalline layer of sample 5 was substantially densified, having moderate porosity. Because of their higher porosity and moderate crystal quality. Samples 5 and 8 have high Rs_poly. Sample 23 is an exception. FIG. 25 is an SEM image of a cross-section of sample 23. Sample 23 had low Rs_poly and, as shown in FIG. 25, also had poor crystal quality, suggesting there may be other factors not considered.

Crystal quality or porosity of the nanocrystalline silicon layer after drive-in plays an important role in dopant diffusion and thus sheet resistance. It is important to control growth rate of LPCVD amorphous silicon onto silicon nanoparticles to obtain high quality crystalline layer. Current recipes may not be suitable for thicker films at a desired level of layer quality. Sample 8, for example, had high porosity and over 1 μm thickness. The growth rate of LPCVD can be reduced to less than 1 nm/min for reduced porosity and improved crystal quality for thicker films. At reduced thickness at about 0.5 μm, current recipes produce nanocrystalline layer of moderate porosity. Further decreasing thickness to 0.3 μm or thinner further improves crystal quality and eliminates porosity. This may not benefit sheet resistance because of reduced layer thickness and reduced dopant source, and is particularly true for samples made from 20 nm silicon nanoparticles.

Porosity in nanocrystalline silicon layer after drive-in was correlated with spin-on thickness. At the same process conditions, in general, thicker spin-on ink layers produced more porous nanocrystalline layer after drive-in. This result is further discussed with respect to composites made from 20 nm and 7 nm silicon nanoparticles. Referring to Table 3, samples 12 and 5, both made from 20 nm silicon nanoparticles, had a 0.25 μm and 0.5 μm ink layer, respectively. FIGS. 17A and 17B are SEM images showing cross-sections of sample 5, taken prior to BOE treatment and at different magnifications. FIGS. 22 and 23 show analogous SEM images of sample 12, also taken prior to BOE treatment and at different magnifications. A comparison of FIGS. 17A and 17B with FIGS. 22 and 23 reveals that the polycrystalline layer formed from a 0.5 μm ink layer (sample 5) was generally more porous that that formed from the 0.25 μm ink layer (sample 12). Referring to sample 8 listed in Table 5, it has about 1.2 μm thickness (targeted for 1 μm) of a spin-on from 20 nm silicon nanoparticles. It has a substantially porous silicon layer following dopant drive-in at similar condition. This is shown in FIG. 24 which is a composite of SEM images of cross-sections of sample 8, taken after BOE treatment and at different magnifications. Similarly for spin-on samples from 7 nm silicon nanoparticles, samples 25 and 23 in Table 6, respectively, have spin-on thickness of 0.25 and 0.5 μm. FIG. 15 and FIG. 25 show SEM image of a cross-section of sample 25 and 23, respectively. Comparison of FIG. 15 (sample 25) with FIG. 25 (sample 23) confirms that sample 23 had a more porous (i.e. less densified) nanocrystalline layer.

### Example 4

### Screen Printed Ink Layers

This example demonstrates of the formation of patterned nanocrystalline silicon structures on silicon wafers by deposition of an amorphous silicon layer onto and into a porous silicon nanoparticle coated substrate. In contrast to Example 1, the porous silicon nanoparticle coatings of this Example were deposited by screen printing to form a pattern.

A silicon nanoparticle ink was patterned onto a crystalline silicon wafer by screen-printing The screen printing ink was prepared from a concentrated dispersion of silicon nanoparticles. In particular, a powder comprising phosphorus doped silicon nanoparticles having an average primary particle diameter of about 20 nm was synthesized as described above. An appropriate amount of the powder was blended with a solvent comprising isopropyl alcohol (“IPA”) and sonicated. The resulting dispersion comprised about 6.3 weight percent (“wt %”) silicon particles. An equal volume of propylene glycol was then added to the dispersion and the mixture was again sonicated. After sonication, the dispersion was transferred to a rotovap to concentrate the dispersion by substantially removing the IPA component of the solvent. The resulting screen-printing ink comprised 12.8 wt % silicon particles in propylene glycol.

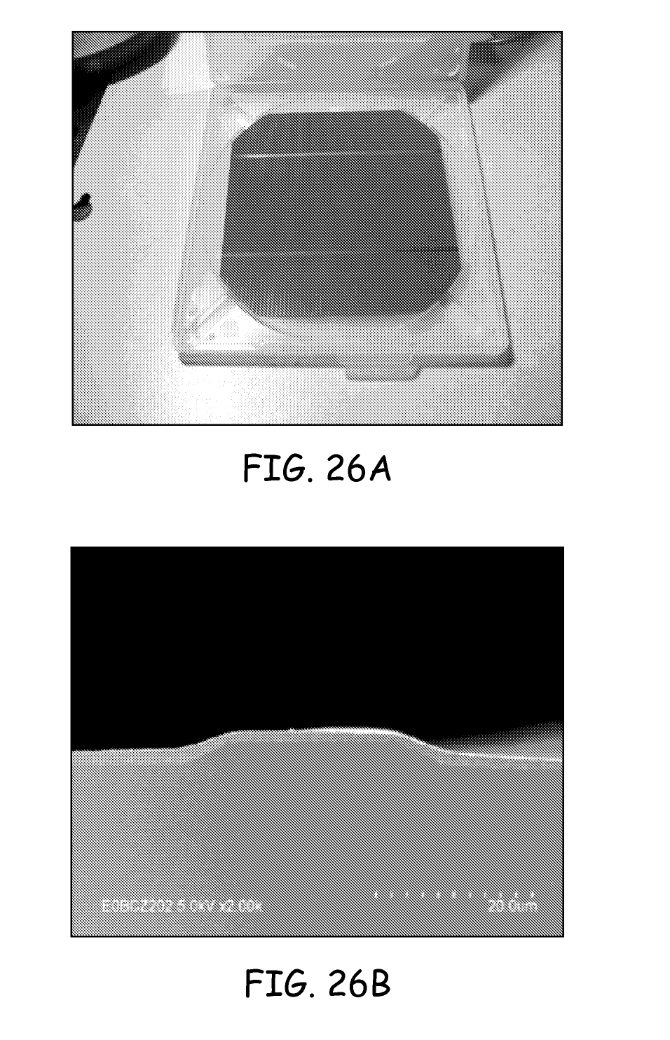

The paste was then screen printed onto a p-type crystalline silicon wafer to form a grid pattern shown in FIG. 26A. The patterns comprise two bus bars of 2 mm in width and multiple finger of 180 μm in width and 2 mm apart between two adjacent fingers. The printed wafer substrates were baked at 200° C. for 10 mins on a hotplate.

The printed wafer substrate was then pre-annealed in a quartz tube furnace at 600° C. for 30 mins at 10 SLM N₂ flow and 60 Torr pressure and an amorphous silicon matrix was deposited on entire substrate with LPCVD. LPCVD was performed at 525° C. for 1.5 hrs. Dopant drive-in was performed on the ink coated substrate with the amorphous silicon matrix and comprised heating it in a furnace under a N₂ atmosphere at 1050° C. for 1 hr. A 4PP was used to measure the resistance of the formed sample by aligning the probes along the bus bars. The sample had an average 4PP resistance of about 90.

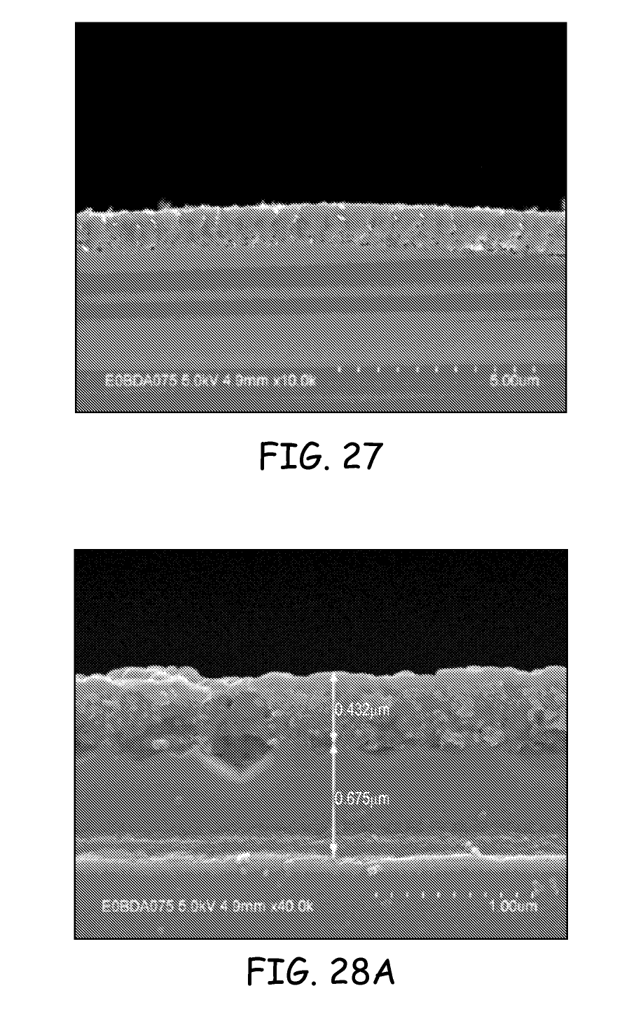

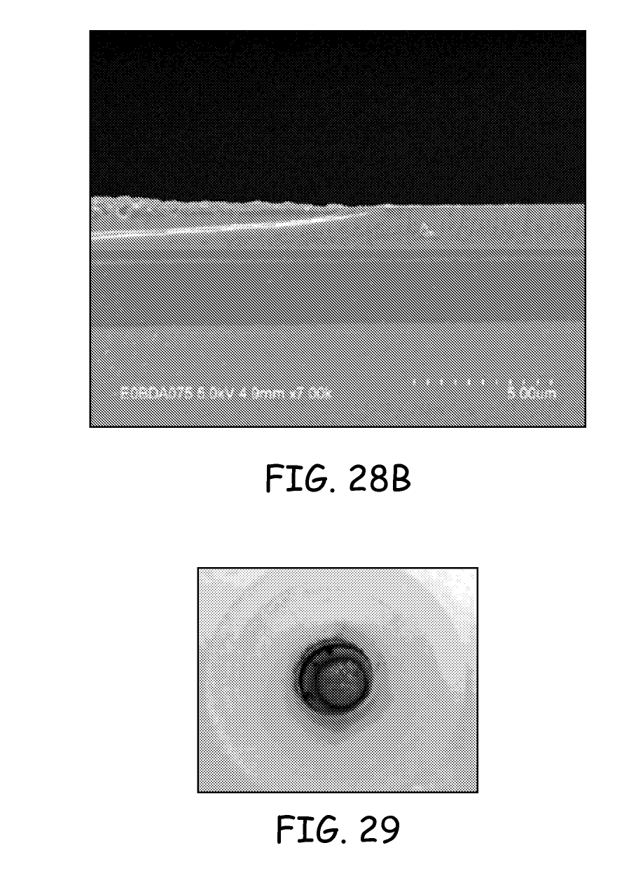

FIG. 26B is an SEM image of a cross-section of one selected finger shown in FIG. 26A and reveals uniform coverage over the contour of uneven wafer surface, although appreciable variations in layer thickness were observed in some areas of bus bars. FIG. 27 is an SEM image in a portion of the cross-section depicted in FIG. 26B, obtained at a higher magnification. It shows a fair amount of voids. The voids-volume is consistent with those obtained for spin-on ink layers of thickness exceeding 1 μm, described in Example 3. FIGS. 28A and 28B are SEM images after stain etched. FIG. 28A shows a uniform layer of diffusion underneath printed fingers. FIG. 28B, on the other hand, reveals a gradual decrease in depth of phosphorus diffusion underneath the tapered off edge of printed fingers, showing unobservable lateral spreading. With regarding to dopant diffusion depth, FIG. 28B confirms that diffusion depth increases with increasing ink layer thickness, consistent with results from spin-on samples.

### Example 5

### Nanocrystalline Silicon Pellets

The example demonstrates the formation and performance of nanoparticle pellets formed from the application of pressure prior to performance of a heat treatment.

To demonstrate formation and performance, each sample was prepared from a powder comprising n++ or intrinsic (“i”) silicon nanoparticles with an average primary particle diameter of about 7 nm or about 20 nm, as described above. For each sample, a substantially cylindrical die was custom-made from quartz and which has an opening of 7.2 mm diameter and 2 mm height. In preparing samples listed in Table 8 and 9, the die was filled with silicon nanoparticle powder and was then pressed for 15 seconds or so with hand pressure using a hand press (KBr Quick Press from International Crystal Laboratory) to densify the nanoparticle deposit. The above sequence was then repeated three times (for a total of 4 deposition and presses) to reach the final thickness. Each compressed silicon structure had a diameter of about 7.2 mm and a thickness between 1 and 2 mm. Pellet formation was completed by heating the compressed silicon structure in a furnace at about 1050° C. for about 60 min. Sample 31A, B, and C were repeats and Sample 32 was not furnace treated. Sample and process parameters for all samples are displayed in Tables 8 and 9, below. FIG. 29 is a photographic image of a representative pellet after furnace treatment associated with the die.

TABLE 8

| | | | Pellet before | | | | Pellet after | | | | Properties of | |
|---|---|---|---|---|---|---|---|---|---|---|---|---|
| | | | Furnace Treatment | | | | Furnace Treatment | | | | Sintered Pellet | |
| Sample | Dopant | Particle | Weight | Dia. | Thk. | | Weight | Dia. | Thk. | | 4PP | Density |
| Number | Type | Size (nm) | (mg) | (mm) | (mm) | Color | (mg) | (mm) | (mm.) | Color | (ohm) | (g/cc) |
| 27 | n++ | 7 | ~30 | 7.2 | 1-2 | Dark | 30.2 | 5.15 | 0.79 | Silvery | 0.11 | 1.84 |
| 28 | n++ | 20 | ~60 | 7.2 | 1-2 | Dark | 47.9 | 5.38 | 1.06 | Silvery | 0.07 | 1.99 |

TABLE 9

| | | | Pellet before | Pellet after | |
|---|---|---|---|---|---|
| | | | Furnace Treatment | Furnace Treatment | |
| Sample | Dopant | Particle | Diameter | Diameter | Density |
| Number | Type | Size (nm) | (mm) | (mm) | (g/cm³) |
| 29 | i | 20 | 7.2 | 7.23 | 0.87 |
| 31A | n++ | 20 | 7.2 | 5.76 | 1.55 |
| 31B | n++ | 20 | 7.2 | 5.71 | 1.38 |
| 31C | n++ | 20 | 7.2 | 5.89 | 1.31 |
| 32 | n++ | 20 | 7.2 | 7.2 | N/A |

### Structural Characteristics of Pellets

There was a reduction in pellet size with furnace treatment, and pellets formed from intrinsic silicon particles had a smaller size reduction relative to pellets formed from n++ silicon particles. The size reduction is presumed to correspond with densification of the silicon from the heat treatment. Referring to Tables 8 and 9, the samples prepared from intrinsic silicon particles (29) had a diameter of about 7.23 mm while the samples prepared from n++ doped silicon particles (samples 27, 28, and 31A-C) had a diameter of between about 5.15 mm-5.76 mm.

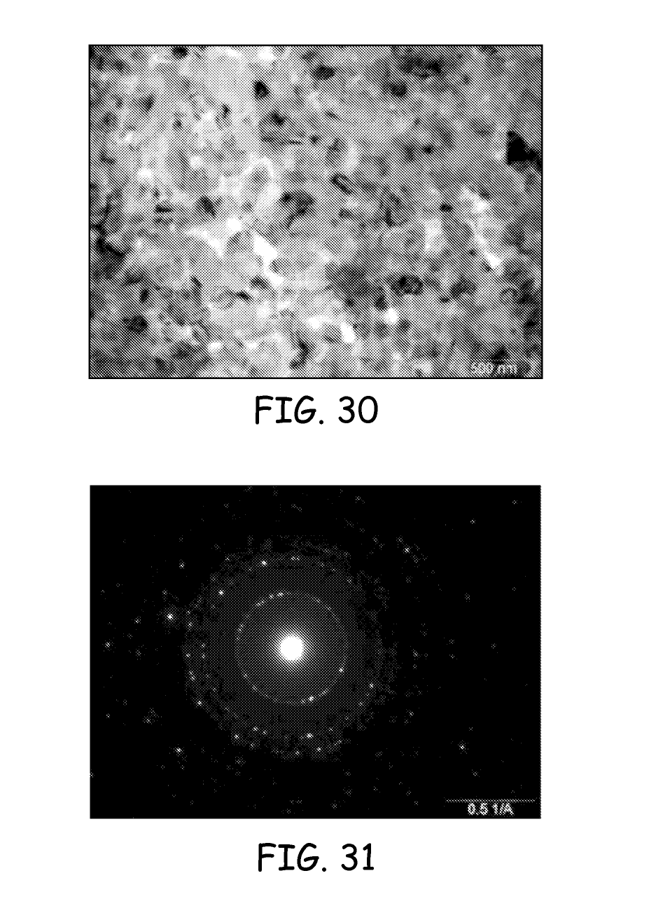

The samples comprised relatively dense nanocrystalline silicon material after the heat treatment. FIG. 30 is a TEM image of a cross-section of Sample 31B and reveals that the pellet comprised nanocrystalline silicon. FIG. 31 is an SAED diffractogram obtained by TEM analysis on sample 13B. The ring pattern consisting bright dots confirms the nanocrystalline structure displayed in FIG. 30.

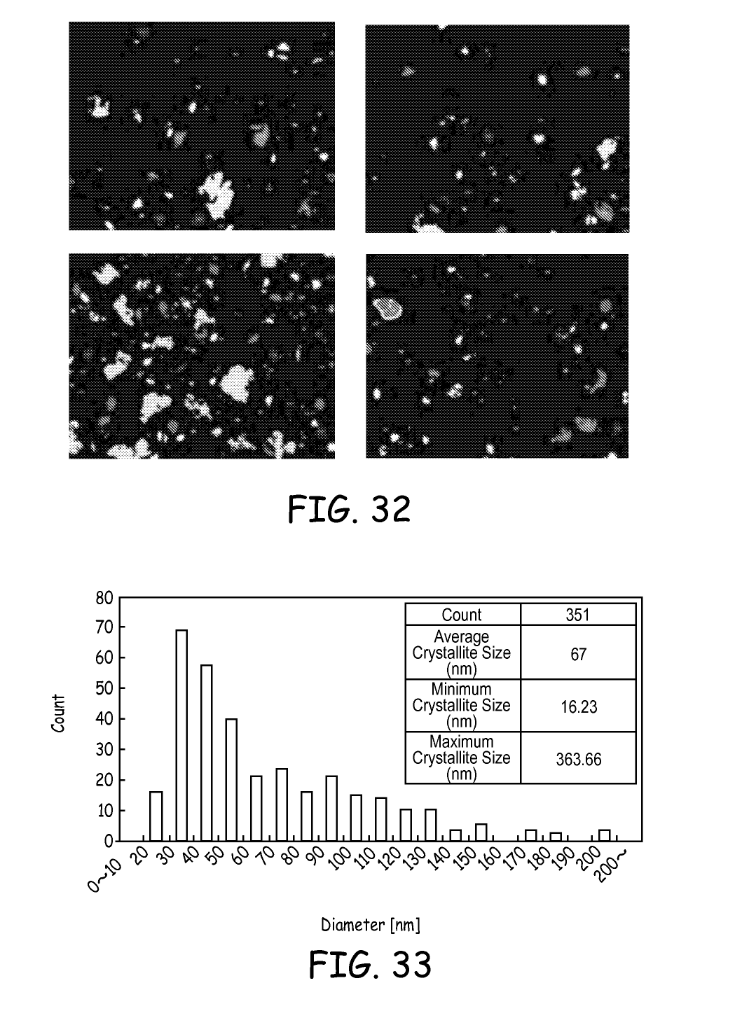

Samples formed from intrinsic silicon particles had a smaller average crystallite size relative to samples formed from n++ silicon particles. FIG. 32 is a composite of images obtained by dynamic frame integration (“DFI”) analysis performed on sample 13B (n++ silicon particles). FIG. 33 shows the distribution of crystallite sites obtained from DFI analysis. In particular, FIG. 33 reveals that sample 13B comprised crystallites with an average crystallite size of about 67 nm, with the largest and smallest observed crystallites having a size of about 364 nm and about 16 nm, respectively. The DFI analysis results were confirmed with XRD measurements. The results of XRD analysis of samples 29-32 are displayed in Table 10. Table 10 reveals that the average crystallite size for sample 13B was about 54.4 nm, similar, although not substantially identical, the crystallite size measured by DFI analysis. Table 10 further reveals that the average crystallite size for samples 29 was about 31 nm while the average crystallite size for samples 31A-C (prepared from n++ silicon particles) was between about 54 nm and about 60 nm. Sample 32 (no furnace treatment) had the smallest average crystallite size of about 15 nm, reflecting the crystallite size in the nanoparticles deposited with the ink.

TABLE 10

| Sample Parameters | | | | | | |
|---|---|---|---|---|---|---|
| | | Si Nano- | XRD Results | | | |
| Sample | Dopant | particle | 111 peak | D | FWHH | Crystal |
| Number | Type | Size (nm) | (deg) | (nm) | (deg) | Size (nm) |
| 29 | i | 20 | 28.422 | 3.1376 | 0.305 | 31.6 |
| 31A | n++ | 20 | 28.436 | 3.1362 | 0.21 | 60.4 |
| 31B | n++ | 20 | 28.433 | 3.1365 | 0.22 | 54.4 |
| 31C | n++ | 20 | 28.429 | 3.1369 | 0.22 | 54.4 |
| 32 | n++ | 20 | 28.43 | 3.1368 | 0.563 | 15.2 |

### Effect of Substrate on Pellet Crystallization

To demonstrate the effects of a substrate on pellet crystallization, a pellet was formed around a portion of silicon wafer. The pellet was formed substantially as describe above in reference to sample 28 except for the insertion of the silicon wafer fragment. In particular, a first portion of the silicon particle powder was first transferred to the die. A fragment of a p-type crystalline silicon wafer was then placed on the first portion of the silicon particle powder in the die. Subsequently, a second portion of silicon particle powder was deposited in the die and the contents of the die were pressed as described above in this Example. After pressing, the pellet was furnace treated as describe above.

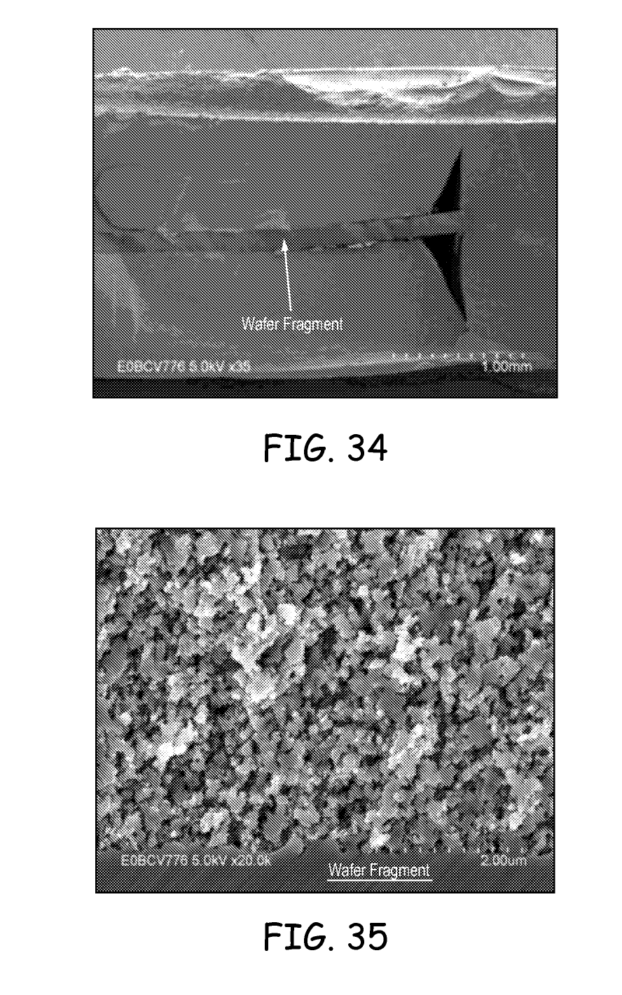

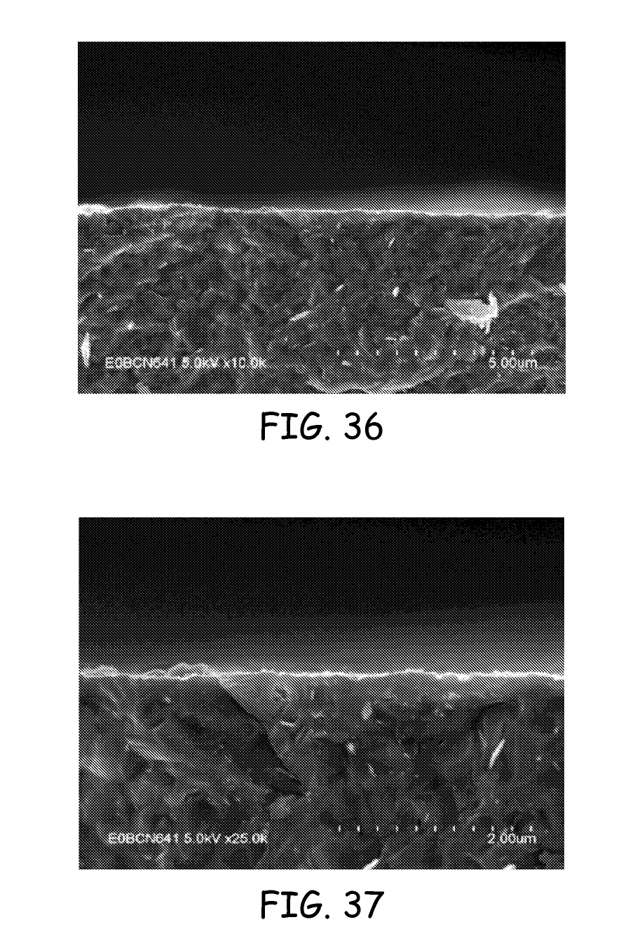

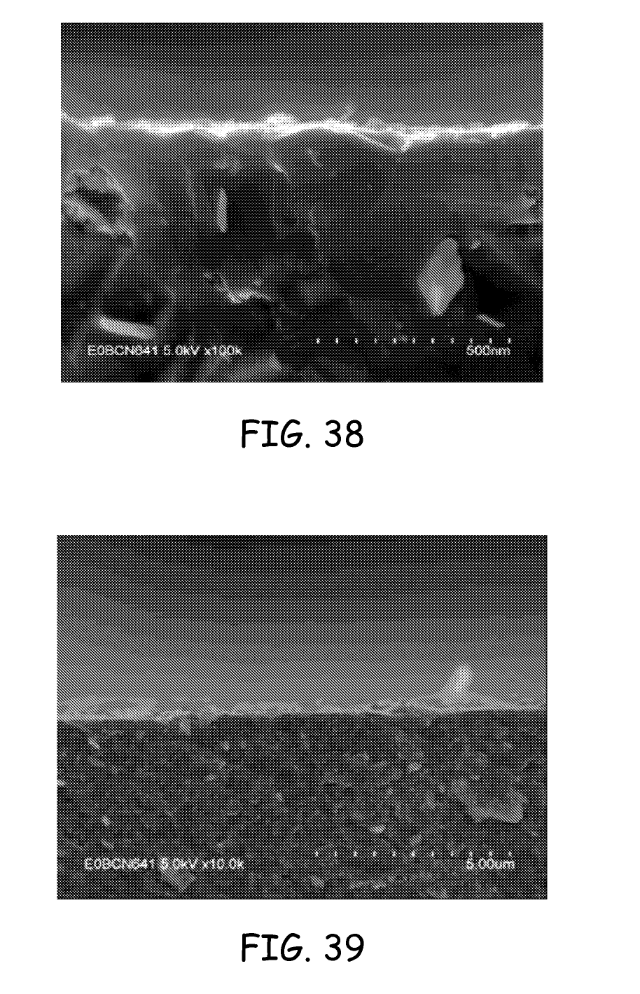

The presence of the substrate fragment inhibited pellet crystallization. FIGS. 34 and 35 are SEM images of cross-sections of the sample comprising the wafer fragment, taken at different magnifications. FIGS. 36-38 are SEM images of cross-sections of sample 28 taken at different magnifications. Comparison of the FIGS. 34 and 35 with FIGS. 36-38 reveals that while sample 28 comprised a crystallized structure, the structure of the pellet comprising the wafer fragment was substantially particulate, comprising fused particles.

### 4PP Resistance

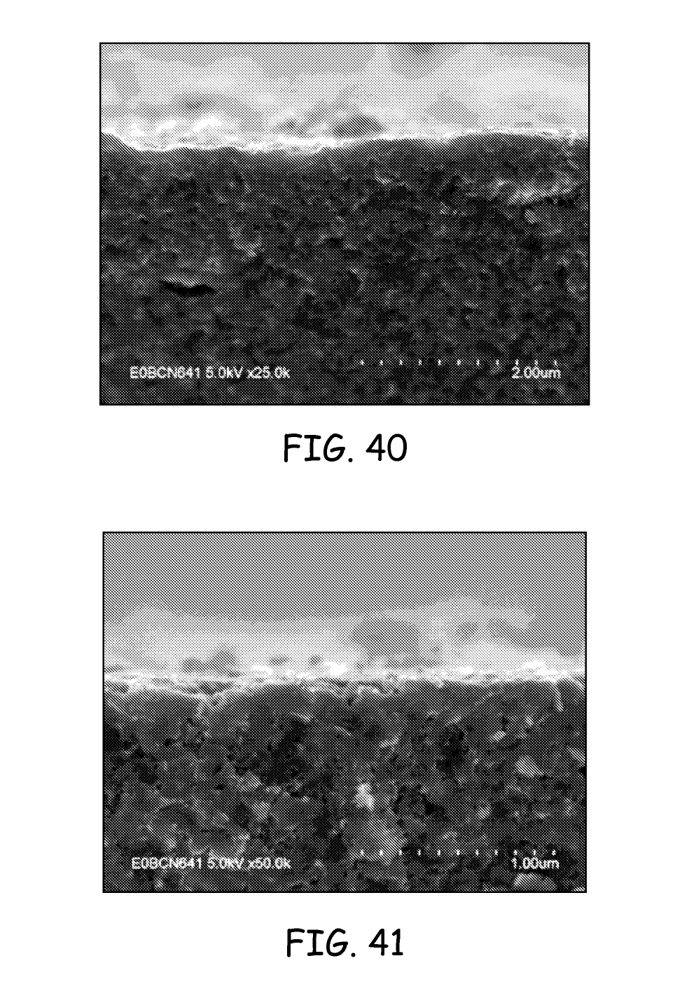

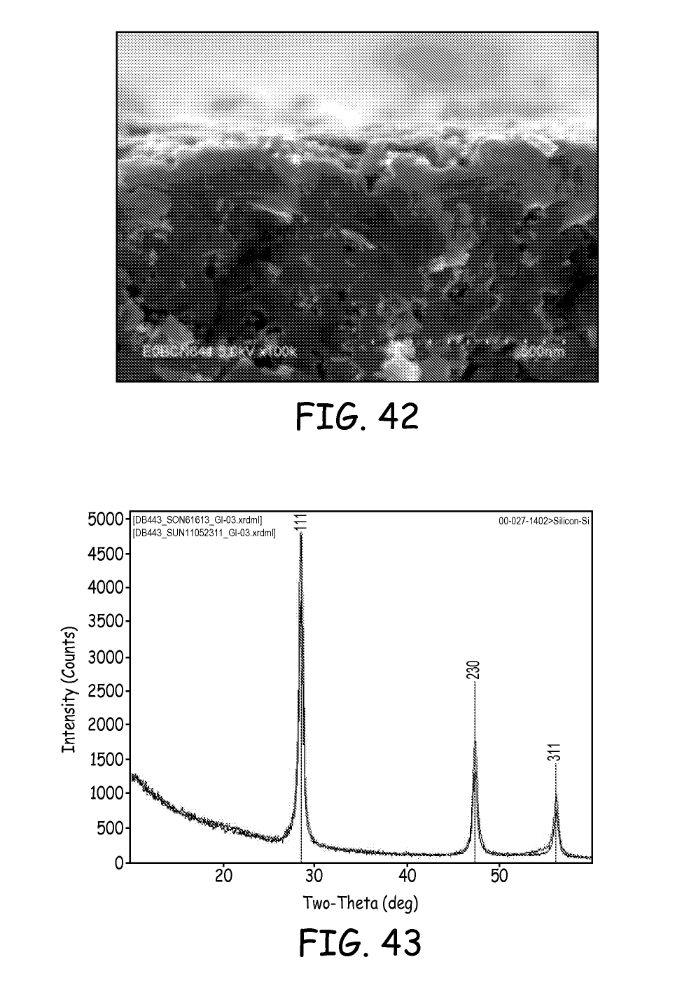

To demonstrate resistance, a four point probe was used to measure the resistance of samples 27 and 28 and the results are displayed in Table 8. Table 8 reveals that while both samples had very low 4PP resistances, sample 28 (average primary particle diameter of about 20 nm) had a lower 4PP resistance relative to sample 27 (average primary particle diameter of about 7 nm). The magnitude of the sheet resistances displayed in Table 8 correlated with the density values listed in the last column and the porosity of the polycrystalline pellet, similar to what was seen in Example 3. FIGS. 39-42 are SEM images of a cross-section of sample 27 taken at different magnifications. Comparison of FIGS. 39-42 with FIGS. 36-38 shows that sample 27 had a more porous (i.e. less densified) structure than sample 28.

### Example 6

### Crystallinity of Annealed Ink Layers

This example describes further analysis of the crystallinity of annealed nanocrystalline ink layers formed during dopant drive-in.

To analyze the crystallinity, 2 samples (samples 34 and 35) were prepared from composite coated wafers comprising an amorphous silicon matrix with embedded crystalline silicon nanoparticles, formed as described in Example 2. In particular, for each sample, the ink coated substrate for further processing was formed by spin coating an ink comprising 20 nm, n++ doped silicon particles on a crystalline silicon wafer substrate. The dried ink layer had an average target thickness of 0.25 μm. LPCVD was performed at 950° C. for 60 min to deposit a 75 nm thick coating of amorphous silicon on the ink coated substrate. For each sample, the ink coated substrate with the amorphous silicon matrix was subjected to dopant drive-in at 950° C. for 60 min to form the annealed nanocrystalline layer.

FIG. 43 and Table 11 display the results of GI XRD analysis on the annealed nanocrystalline layer of both samples. FIG. 43 is a graph containing plots of GI XRD diffractograms of samples 33 and 34. The diffractograms both consist of three crystal peaks, i.e., <111>, <220>, and <311>, in ascending angle 2 theta and demonstrate that subsequent to dopant drive-in, the ink layers with the amorphous silicon matrix were converted into nanocrystalline layers. As estimated from the peak broadening in the GI XRD diffractograms, the annealed nanocrystalline layers of both samples comprised crystallites with and average size of about 30 nm, based on evaluation of the Scherrer equation.

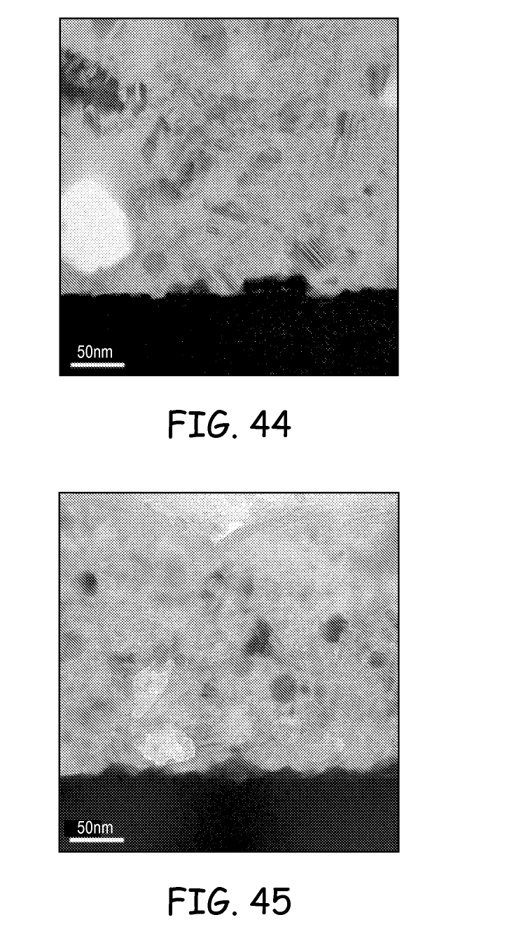

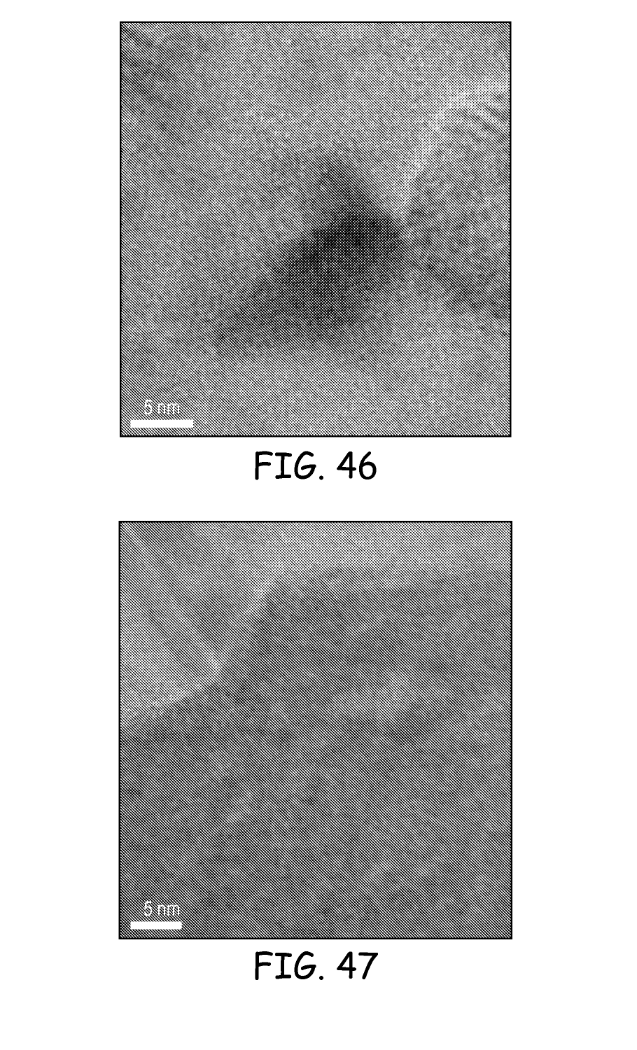

FIGS. 44 and 45 are high resolution TEM images showing different portions of a cross-section of sample 34 and confirm that average crystallite size in the annealed nanocrstyalline layer of sample 34 was about 30 nm. Table 11 shows the annealed layer thickness normalized peak intensities and reveals that while both samples comprised an annealed nanocrystalline layer, the annealed layer of sample 33 was more crystalline than that of sample 34. FIGS. 46 and 47 are high resolution TEM images of an annealed nanocrystalline layer portion (FIG. 46) and a substrate portion (FIG. 47) of a cross-section of sample 34. FIGS. 46 and 47 demonstrate that the annealed nanocrystalline layer is made-up of randomly oriented crystallites. The visible crystallites were consistent with the average particle sizes from the XRD particle size analysis.

TABLE 11

| | | | Thickness-Normalized | | |
|---|---|---|---|---|---|
| | Thickness (nm) | | Intensity | | |
| Sample ID | t | St. Dev. | <111>/t | <220>/t | <311>/t |
| 33 | 378 | 85 | 129.93 | 53.52 | 22.71 |
| 34 | 400 | 125 | 93.33 | 38.64 | 17.87 |

| | | | |
|---|---|---|---|
| Crystallinity Ratio of Sample 2/Sample 1 | 0.72 | 0.72 | 0.79 |

| | |
|---|---|
| Average | 0.74 |
| St. Dev. | 0.04 |

The specific embodiments above are intended to be illustrative and not limiting. Additional embodiments are within the broad concepts described herein. In addition, although the present invention has been described with reference to particular embodiments, those skilled in the art will recognize that changes can be made in form and detail without departing from the spirit and scope of the invention. Any incorporation by reference of documents above is limited such that no subject matter is incorporated that is contrary to the explicit disclosure herein.

What we claim is:

1. A structure comprising a substrate having a surface and a composite coating on at least a portion of the surface with an average thickness of no more than about 5 microns and comprising crystalline silicon nanoparticles with an average primary particle size of no more than about 100 nm and an amorphous silicon matrix around the crystalline silicon particles.

2. The structure of claim 1 wherein the coating has a void volume of no more than about 20%.

3. The structure of claim 1 wherein the thickness of the composite coating is no more than about 3 microns.

4. The structure of claim 1 further comprises a top coat of amorphous silicon on the composite coating, the top coat having an average thickness no more than about 5 microns.

5. The structure of claim 1 wherein the crystalline silicon nanoparticles have an average particle size of no more than about 75 nm.

6. The structure of claim 1 wherein the crystalline silicon nanoparticles comprise a dopant with a concentration of at least about 1×10²⁰ atoms/cm³.

7. The structure of claim 6 wherein the amorphous silicon is intrinsic.

8. The structure of claim 1 wherein the composite coating is patterned covering no more than about 75 percent of the substrate surface.

9. The structure of claim 1 wherein the substrate comprises highly crystalline elemental silicon along the surface.

10. The structure of claim 1 wherein the crystalline silicon nanoparticles are doped with phosphorous.

11. The structure of claim 1 wherein the crystalline silicon nanoparticles are doped with boron.

12. A method for application of a silicon coating on a substrate, the method comprising:
depositing an amorphous silicon matrix onto and into a particulate coating of crystalline silicon nanoparticles having an average primary particle size of no more than about 200 nm to form a composite with crystalline silicon nanoparticles embedded in an amorphous matrix, wherein the particulate coating has an average thickness of no more than about 5 microns.

13. The method of claim 12 wherein the application of the amorphous silicon is performed using LP-CVD.

14. The method of claim 12 wherein the crystalline silicon nanoparticles were deposited using an ink.

15. The method of claim 12 wherein the resulting coating has a void volume of no more than about 20%.

16. The method of claim 12 wherein the deposited amorphous coating forms a top coat over a composite of the amorphous elemental silicon and the crystalline silicon nanoparticle and wherein the top coat has an average thickness of no more than about 5 microns.

17. The method of claim 12 wherein the crystalline silicon nanoparticles are doped and the amorphous elemental silicon is intrinsic.

18. The method of claim 17 wherein crystalline silicon nanoparticles have a phosphorous dopant or a boron dopant with a dopant concentration from about 0.25 atomic percent to about 15 atomic percent.

19. The method of claim 12 further comprising annealing the composite comprising heating the composite at a temperature from abut 700° C. to about 1400° C. to form a nanocrystalline material.

20. The method of claim 19 wherein the nanocrystalline material has a void volume of no more than about 5% and a sheet resistance of no more than about 120 ohms/square.
